(19) United States
(12) Patent Application Publication
(10) Pub. No.: US 2026/0173274 A1
(43) Pub. Date: Jun. 18, 2026

(54) INDUCTOR-EMBEDDED CIRCUIT BOARD AND VOLTAGE REGULATION MODULE

(71) Applicant: Murata Manufacturing Co., Ltd., Nagaokakyo-shi (JP)

(72) Inventors: Nobuyoshi ADACHI, Nagaokakyo-shi (JP); Kenji Nishiyama, Nagaokakyo-shi (JP); Yoshimitsu Ushimi, Nagaokakyo-shi (JP); Hidehiko Sasaki, Nagaokakyo-shi (JP); Koshi Himeda, Nagaokakyo-shi (JP)

(21) Appl. No.: 19/530,744

(22) Filed: Feb. 5, 2026

Related U.S. Application Data
(63) Continuation of application No. PCT/JP2024/028783, filed on Aug. 9, 2024.

(30) Foreign Application Priority Data
Aug. 10, 2023 (JP) 2023-130819

(51) Int. Cl. H05K 1/183; H01F 27/24; H02M 1/14; H02M 3/00; H02M 3/07; H05K 1/185

(52) U.S. Cl. CPC H05K 1/183; H01F 27/24; H02M 1/14; H02M 3/003; H02M 3/072; H05K 1/185; H05K 2201/10015; H05K 2201/1003; H05K 2201/10522

(57) ABSTRACT

An inductor-embedded circuit board includes: a substrate; a first wiring layer on a first surface of the substrate with a first insulation section between the first wiring layer and the first surface; a second wiring layer on a second surface of the substrate with a second insulation section between the second wiring layer and the second surface; and an inductor embedded inside the substrate. The inductor includes: a plurality of conductors that extend in a thickness direction; a plurality of magnetic bodies respectively surrounding respective peripheral surface of the plurality of conductors. The plurality of conductors are electrically connected in series by via conductors in the first insulation section and the second insulation section and connection electrodes in the first wiring layer and the second wiring layer.

### CROSS REFERENCE TO RELATED APPLICATIONS

This application is a continuation of International Application No. PCT/JP2024/028783, filed Aug. 9, 2024, which claims priority to Japanese Patent Application No. 2023-130819, filed on Aug. 10, 2023, the entire contents of each of which are hereby incorporated by reference in their entirety.

### TECHNICAL FIELD

The present disclosure relates to inductor-embedded circuit boards and voltage regulation modules using inductor-embedded circuit boards.

### BACKGROUND

A voltage regulation module is used for supplying electric power to an arithmetic processing device, such as a CPU or a GPU. A step-down switching regulator module having a combination of functional components, such as a switch element, an inductor, and a capacitor, is known as a voltage regulation module.

Such a voltage regulation module is normally disposed in parallel with the arithmetic processing device on one of principal surfaces of a system board (motherboard). In contrast, U.S. Patent Application Publication No. 2020/0111597 discloses a voltage regulation module disposed on a principal surface, of the system board, opposite the principal surface where the arithmetic processing device is disposed.

The U.S. Patent Application Publication No. 2020/0111597 discloses a three-layer voltage regulation module in which a magnetic core assembly is disposed between two circuit board assemblies. The magnetic core assembly has an inductor embedded therein.

### SUMMARY OF INVENTION

In the voltage regulation module according U.S. Patent Application Publication No. 2020/0111597, the magnetic core assembly having the inductor embedded therein tends to be tall (thick). Therefore, there is room for improvement from the standpoint of making the voltage regulation module thinner.

Accordingly, an object of the present disclosure is to solve the aforementioned problem by providing an inductor-embedded circuit board that enables a thinner voltage regulation module.

According to an exemplary aspect, an inductor-embedded circuit board according to an aspect of the present disclosure includes a substrate having a first surface and a second surface that is opposite the first surface in a thickness direction; a first wiring layer on the first surface of the substrate with a first insulation section between the first wiring layer and the first surface; a second wiring layer on the second surface of the substrate with a second insulation section between the second wiring layer and the second surface; and an inductor located inside the substrate.

In an exemplary aspect, the inductor includes a first conductor, a second conductor, and a third conductor that are disposed within the substrate, the first conductor, the second conductor, and the third conductor being spaced apart from one another in a plan view that is viewed in the thickness direction and each extending in the thickness direction, a first magnetic body surrounding a peripheral surface of the first conductor, a second magnetic body surrounding a peripheral surface of the second conductor, and a third magnetic body located surrounding a peripheral surface of the third conductor.

In an exemplary aspect, the first conductor, the second conductor, and the third conductor each have a first end portion, which is located toward the first surface, and a second end portion, which is located toward the second surface, within the substrate.

In an exemplary aspect, the first wiring layer has a first connection electrode that electrically connects the first end portions of the first conductor and the second conductor to each other.

In an exemplary aspect, the second wiring layer has a second connection electrode that electrically connects the second end portions of the second conductor and the third conductor to each other.

In an exemplary aspect, the first end portions of the first conductor and the second conductor are electrically connected to the first connection electrode by a via conductor within the first insulation section.

In an exemplary aspect, the second end portions of the second conductor and the third conductor are electrically connected to the second connection electrode by a via conductor within the second insulation section.

According to some exemplary aspects of the present disclosure, an inductor-embedded circuit board that enables a thinner voltage regulation module is provided.

### BRIEF DESCRIPTION OF DRAWINGS

FIG. 1 is a schematic perspective view of an inductor-embedded circuit board according to a first exemplary embodiment.

FIG. 2 is a schematic exploded perspective view of the inductor-embedded circuit board in FIG. 1.

FIG. 3A is a schematic top view illustrating a component-embedded substrate and some of wiring layers in the inductor-embedded circuit board in FIG. 1.

FIG. 3B is a schematic bottom view illustrating the component-embedded substrate and some of the wiring layers in FIG. 3A.

FIG. 3C is a schematic cross-sectional view taken along line IIIC-IIIC in FIG. 3A and FIG. 3B.

FIG. 4 is a schematic perspective view of an inductor unit cell.

FIG. 5A is a schematic top view of the inductor unit cell in FIG. 4.

FIG. 5B is a schematic cross-sectional view taken along line VB-VB in FIG. 5A.

FIG. 6 illustrates a basic circuit configuration of a voltage regulation module (step-down converter).

FIG. 7A is a schematic process top view illustrating a method for manufacturing inductor unit cells.

FIG. 7B is a schematic process cross-sectional view taken along line VIIB-VIIB shown in FIG. 7A.

FIG. 8A is a schematic process top view illustrating the method for manufacturing the inductor unit cells.

FIG. 8B is a schematic process cross-sectional view taken along line VIIIB-VIIIB shown in FIG. 8A.

FIG. 9A is a schematic process top view illustrating the method for manufacturing the inductor unit cells.

FIG. 9B is a schematic process cross-sectional view taken along line IXB-IXB shown in FIG. 9A.

FIG. 10A is a schematic process top view illustrating the method for manufacturing the inductor unit cells.

FIG. 10B is a schematic process cross-sectional view taken along line XB-XB shown in FIG. 10A.

FIG. 11A is a schematic process top view illustrating the method for manufacturing the inductor unit cells.

FIG. 11B is a schematic process cross-sectional view taken along line XIB-XIB shown in FIG. 11A.

FIG. 12A is a schematic process top view illustrating the method for manufacturing the inductor unit cells.

FIG. 12B is a schematic process cross-sectional view taken along line XIIB-XIIB shown in FIG. 12A.

FIG. 13A is a schematic process top view illustrating the method for manufacturing the inductor unit cells.

FIG. 13B is a schematic process cross-sectional view taken along line XIIIB-XIIIB shown in FIG. 13A.

FIG. 14A is a schematic process top view illustrating the method for manufacturing the inductor unit cells.

FIG. 14B is a schematic process cross-sectional view taken along line XIVB-XIVB shown in FIG. 14A.

FIG. 15A is a schematic process top view illustrating a method for manufacturing the circuit board.

FIG. 15B is a schematic process cross-sectional view taken along line XVB-XVB shown in FIG. 15A.

FIG. 16A is a schematic process top view illustrating the method for manufacturing the circuit board.

FIG. 16B is a schematic process cross-sectional view taken along line XVIB-XVIB shown in FIG. 16A.

FIG. 17A is a schematic process top view illustrating the method for manufacturing the circuit board.

FIG. 17B is a schematic process cross-sectional view taken along line XVIIB-XVIIB shown in FIG. 17A.

FIG. 18A is a schematic process top view illustrating the method for manufacturing the circuit board.

FIG. 18B is a schematic process bottom view corresponding to FIG. 18A.

FIG. 18C is a schematic process cross-sectional view taken along line XVIIIC-XVIIIC shown in FIG. 18A.

FIG. 19A is a schematic process top view illustrating the method for manufacturing the circuit board.

FIG. 19B is a schematic process bottom view corresponding to FIG. 19A.

FIG. 19C is a schematic process cross-sectional view taken along line XIXC-XIXC shown in FIG. 19A.

FIG. 20A is a schematic process top view illustrating the method for manufacturing the circuit board.

FIG. 20B is a schematic process bottom view corresponding to FIG. 20A.

FIG. 20C is a schematic process cross-sectional view taken along line XXC-XXC shown in FIG. 20A.

FIG. 21A is a schematic process top view illustrating the method for manufacturing the circuit board.

FIG. 21B is a schematic process bottom view corresponding to FIG. 21A.

FIG. 21C is a schematic process cross-sectional view taken along line XXIC-XXIC shown in FIG. 21A.

FIG. 22A is a schematic process top view illustrating the method for manufacturing the circuit board.

FIG. 22B is a schematic process bottom view corresponding to FIG. 22A.

FIG. 22C is a schematic process cross-sectional view taken along line XXIIC-XXIIC shown in FIG. 22A.

FIG. 23A is a schematic process top view illustrating the method for manufacturing the circuit board.

FIG. 23B is a schematic process bottom view corresponding to FIG. 23A.

FIG. 23C is a schematic process cross-sectional view taken along line XXIIIC-XXIIIC shown in FIG. 23A.

FIG. 24A is a schematic process top view illustrating the method for manufacturing the circuit board.

FIG. 24B is a schematic process bottom view corresponding to FIG. 24A.

FIG. 24C is a schematic process cross-sectional view taken along line XXIVC-XXIVC shown in FIG. 24A.

FIG. 25A is a schematic top view illustrating a component-embedded substrate and some of wiring layers in an inductor-embedded circuit board according to a second exemplary embodiment.

FIG. 25B is a schematic bottom view illustrating the component-embedded substrate and some of the wiring layers shown in FIG. 25A.

FIG. 25C is a schematic cross-sectional view taken along line XXVC-XXVC in FIG. 25A and FIG. 25B.

FIG. 26A is a schematic top view illustrating a method for manufacturing inductor unit cells.

FIG. 26B is a schematic process cross-sectional view taken along line XXVIB-XXVIB shown in FIG. 26A.

FIG. 27A is a schematic process top view illustrating the method for manufacturing the inductor unit cells.

FIG. 27B is a schematic process cross-sectional view taken along line XXVIIB-XXVIIB shown in FIG. 27A.

FIG. 28A is a schematic process top view illustrating a method for manufacturing the circuit board.

FIG. 28B is a schematic process cross-sectional view taken along line XXVIIIB-XXVIIIB shown in FIG. 28A.

FIG. 29A is a schematic process top view illustrating the method for manufacturing the inductor unit cells.

FIG. 29B is a schematic process cross-sectional view taken along line XXIXB-XXIXB shown in FIG. 29A.

FIG. 30 is a schematic perspective view of a conductor containing section in a circuit board according to a third exemplary embodiment.

FIG. 31A is a schematic top view of the conductor containing section in FIG. 30.

FIG. 31B is a schematic cross-sectional view taken along line XXXIB-XXXIB in FIG. 31A.

FIG. 32A is a schematic top view of Modification 1 of the conductor containing section.

FIG. 32B is a schematic cross-sectional view taken along line XXXIIB-XXXIIB in FIG. 32A.

FIG. 33A is a schematic top view of Modification 2 of the conductor containing section.

FIG. 33B is a schematic cross-sectional view taken along line XXXIIIB-XXXIIIB in FIG. 33A.

FIG. 34A is a schematic top view of Modification 3 of the conductor containing section.

FIG. 34B is a schematic cross-sectional view taken along line XXXIVB-XXXIVB in FIG. 34A.

FIG. 35A is a schematic top view of Modification 4 of the conductor containing section.

FIG. 35B is a schematic cross-sectional view taken along line XXXVB-XXXVB in FIG. 35A.

FIG. 36A is a schematic top view of Modification 5 of the conductor containing section.

FIG. 36B is a schematic cross-sectional view taken along line XXXVIB-XXXVIB in FIG. 36A.

FIG. 37A is a schematic top see-through view of conductor containing sections and second electrodes according to Configuration Example (2).

FIG. 37B is a schematic bottom see-through view of the conductor containing sections and first electrodes according to Configuration Example (2).

FIG. 37C is a schematic top view illustrating a magnetic field occurring in one of first structural bodies.

FIG. 38A illustrates an example of a circuit configuration of a voltage regulation module using a circuit board according to Configuration Example (2).

FIG. 38B illustrates the circuit configuration shown in FIG. 38A in a simplified form.

FIG. 38C illustrates a phase 1 of a circuit shown in FIG. 38B.

FIG. 38D is a schematic graph illustrating waveforms of ripple current in the circuit shown in FIG. 38A.

FIG. 39A is a schematic top see-through view of conductor containing sections and second electrodes according to Configuration Example (3).

FIG. 39B is a schematic bottom see-through view of the conductor containing sections and first electrodes according to Configuration Example (3).

FIG. 40 illustrates an example of a circuit configuration of a voltage regulation module using a circuit board according to Configuration Example (3).

FIG. 41A is a schematic top see-through view of conductor containing sections and second electrodes according to Configuration Example (5).

FIG. 41B is a schematic bottom see-through view of the conductor containing sections and first electrodes according to Configuration Example (5).

FIG. 42A is a schematic process perspective view illustrating a method for manufacturing a first structural body M.

FIG. 42B is a schematic process perspective view illustrating the method for manufacturing the first structural body M.

FIG. 42C is a schematic process perspective view illustrating the method for manufacturing the first structural body M.

FIG. 43A is a schematic process perspective view illustrating a method for manufacturing conductor containing sections.

FIG. 43B is a schematic process perspective view illustrating the method for manufacturing the first structural body M.

FIG. 44A is a schematic top view for explaining an example of a method for designing the first structural body M.

FIG. 44B is a schematic top view for explaining the example of the method for designing the first structural body M.

FIG. 45 is a schematic cross-sectional view illustrating an example of a voltage regulation module according to a fourth exemplary embodiment.

FIG. 46 is a schematic cross-sectional view illustrating an inductor-embedded assembly according to a reference example.

### DETAILED DESCRIPTION OF EMBODIMENTS

### (Underlying Knowledge Forming Basis of Present Disclosure)

As a result of performing extensive studies to make a voltage regulation module thinner, following knowledge has been obtained.

Due to the rapid increase in data traffic in information communication, the electric current required in arithmetic processing devices used in data centers and the like has been increasing. With the increase in electric current, it is necessary to suppress a transient voltage response (voltage fluctuation) of arithmetic processing devices to current variations (load variations).

When a voltage regulation module is disposed at a principal surface (referred to as a “facing surface” hereinafter), of a system board, opposite a principal surface where an arithmetic processing device is disposed, an output end of the voltage regulation module can be disposed close to an input end of the arithmetic processing device. Therefore, the transient voltage response can be suppressed more effectively.

It is desirable that the voltage regulation module disposed at the facing surface be thinner in addition to having embedded therein functional components, such as an inductor.

However, as mentioned above, with regard to the voltage regulation module disclosed in U.S. Patent Application Publication No. 2020/0111597, it may be difficult to reduce the thickness of the module. In U.S. Patent Application Publication No. 2020/0111597, the magnetic core assembly has a conductor extending through a magnetic core in the thickness direction, thereby forming an inductor (see FIG. 46). In such a structure, the thickness of the magnetic core assembly is limited by the height of the conductor within the magnetic core. Moreover, two circuit board assemblies have to be additionally provided above and below the magnetic core assembly. Thus, the module further increases in thickness due to the thicknesses of the two circuit board assemblies as well as a solder-based connection section between the assemblies.

According to an aspect of the disclosure, an inductor-embedded circuit board can be reduced in thickness by dividing the inductor into multiple parts and embedding the parts in a circuit board, and a voltage regulation module can be made thinner by using such an inductor-embedded circuit board.

Embodiments of the present disclosure will be described below with reference to the drawings. The present disclosure is not to be limited to these embodiments. In the drawings, substantially identical members are given the same reference sign. For illustrative purposes, the dimensions of each element in the drawings may be exaggerated, and are not necessarily to scale.

A substrate having a conductor embedded therein will be referred to as “conductor-embedded circuit board” hereinafter. Among conductor-embedded circuit boards, a circuit board in which multiple embedded conductors are connected in series to form an inductor may sometimes be referred to as “inductor-embedded circuit board”. A conductor-embedded circuit board or an inductor-embedded circuit board may sometimes be abbreviated as “circuit board”.

In the following description, terms indicating directions, such as “upper”, “lower”, “right”, “left”, and “side”, are used for convenience of explanation, assuming a normal state of use. However, such terms are not intended to limit the use state or the like of the circuit board according to the present disclosure. Furthermore, in this description, the term “orthogonal” refers to a range within 90°±10°. The term “parallel” refers to a range within, for example, ±5°. Moreover, the shape, direction (orientation), or the like to be described below is not limited only to the described shape or direction, and may include a shape or direction substantially similar to that shape or direction. For example, “rectangular parallelepiped” includes not only a rectangular parallelepiped but also a substantially rectangular parallelepiped.

In each drawing to be described below, an X axis, a Y axis, and a Z axis are schematically shown for reference. The Z axis corresponds to the thickness direction of the inductor-embedded circuit board. An X direction, Y direction, or Z direction simply used in the following description is a direction of the corresponding axis and includes two opposite directions (e.g., −X direction and +X direction).

### First Exemplary Embodiment

### [Overall Configuration of Inductor-Embedded Circuit Board]

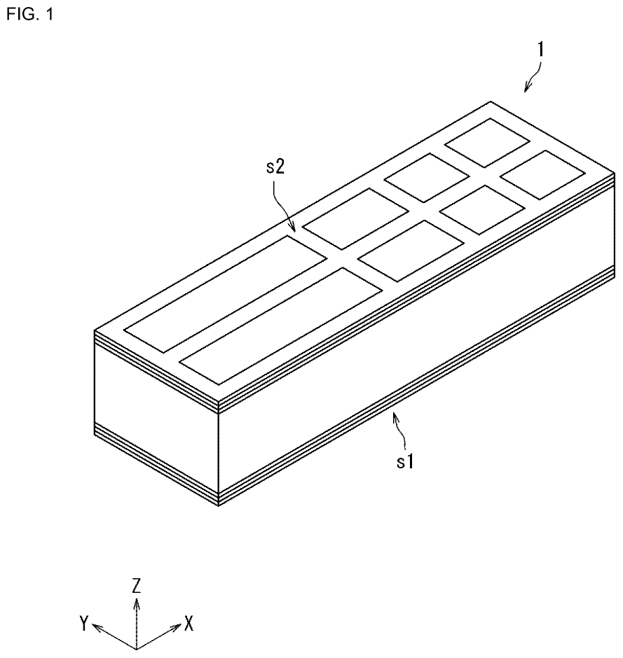

First, an overview of an inductor-embedded circuit board (referred to as “circuit board” hereinafter) according to a first exemplary embodiment of the present disclosure will be described with reference to FIG. 1 to FIG. 5.

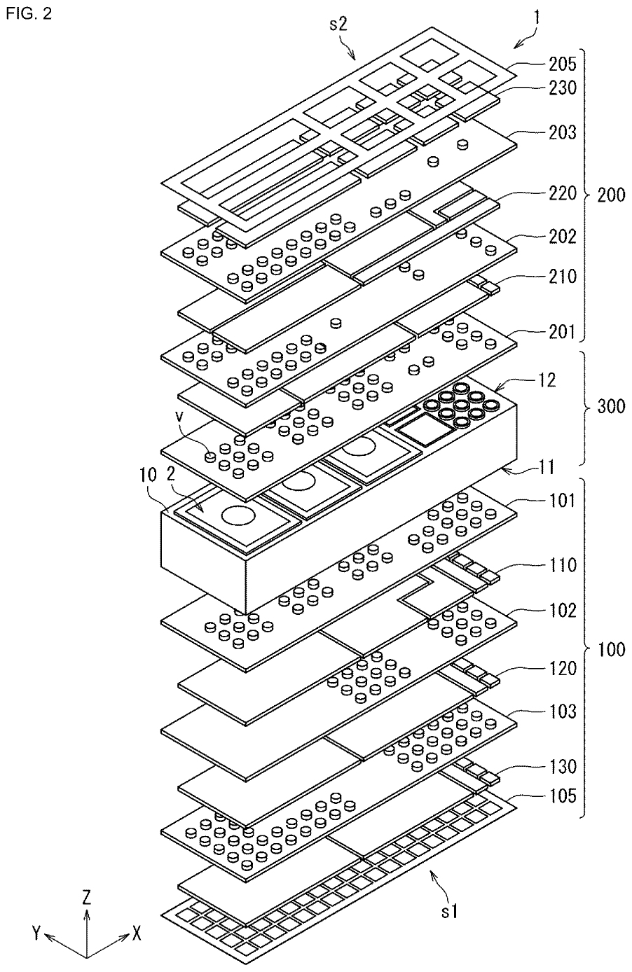

FIG. 1 is a schematic perspective view of the circuit board according to the exemplary embodiment of the present disclosure. FIG. 2 is a schematic exploded perspective view of the circuit board in FIG. 1.

As shown in FIG. 1, a circuit board 1 has, for example, a substantially rectangular parallelepiped shape. The circuit board 1 has a first principal surface s1 and a second principal surface s2 located opposite the first principal surface s1 in the thickness direction (Z direction). For the sake of convenience, in each drawing, the thickness direction of the circuit board 1 is defined as the Z direction, a direction parallel to the long edges of the principal surfaces s1 and s2 of the circuit board 1 is defined as the X direction, and a direction parallel to the short edges is defined as the Y direction.

As shown in FIG. 2, the circuit board 1 includes a first wiring structure 100, a second wiring structure 200, and a component-embedded substrate 300. In the thickness direction (Z direction) of the circuit board 1, the component-embedded substrate 300 is located between the first wiring structure 100 and the second wiring structure 200. In this example, the first wiring structure 100 is located at the first principal surface s1 side of the component-embedded substrate 300, and the second wiring structure 200 is located at the second principal surface s2 side of the component-embedded substrate 300.

The component-embedded substrate 300 includes a substrate 10 (also referred to as “core substrate”) and components, such as an inductor 2 and a two-terminal capacitor, disposed inside the substrate 10. In this description, the components disposed (embedded) inside the substrate 10 may sometimes be collectively referred to as “embedded components”.

The substrate 10 has, for example, a substantially rectangular parallelepiped shape. The substrate 10 has a first surface (in this case, a lower surface) 11 and a second surface (in this case, an upper surface) 12 located opposite the first surface 11 in the Z direction. The first surface 11 is located at the first principal surface s1 side of the circuit board 1, and the second surface 12 is located at the second principal surface s2 side of the circuit board 1.

The embedded components, such as the inductor 2 and the two-terminal capacitor, are disposed within a through-hole provided in the substrate 10.

The first wiring structure 100 is located on the first surface 11 of the substrate 10. The first wiring structure 100 has a multilayer structure in which multiple (in this case, three) insulation layers 101 to 103 and multiple wiring layers 110 to 130 are alternately stacked in the thickness direction (−Z direction). In this case, the insulation layer 101, the wiring layer 110, the insulation layer 102, the wiring layer 120, the insulation layer 103, and the wiring layer 130 are stacked in this order from the substrate 10 side.

The second wiring structure 200 is located on the second surface 12 of the substrate 10. The second wiring structure 200 has a multilayer structure in which multiple (in this case, three) insulation layers 201 to 203 and multiple wiring layers 210 to 230 are alternately stacked in the thickness direction (+Z direction). In this case, the insulation layer 201, the wiring layer 210, the insulation layer 202, the wiring layer 220, the insulation layer 203, and the wiring layer 230 are stacked in this order from the substrate 10 side.

The wiring layers 110 to 130 and 210 to 230 each have an electrode, a wire, a terminal portion, and the like. The insulation layers 101 to 103 and 201 to 203 each have multiple via conductors v disposed therein for electrically connecting electrodes located above and below to each other.

The circuit board 1 may further include solder-resist layers 105 and 205. The solder-resist layer 105 is disposed at the first principal surface s1 side of the first wiring structure 100. The solder-resist layer 205 is disposed at the second principal surface s2 side of the second wiring structure 200. The solder-resist layers 105 and 205 are provided for suppressing solder flow when a component or BGA (ball grid array) is to be mounted onto the circuit board 1 by soldering.

### [Component-Embedded Substrate]

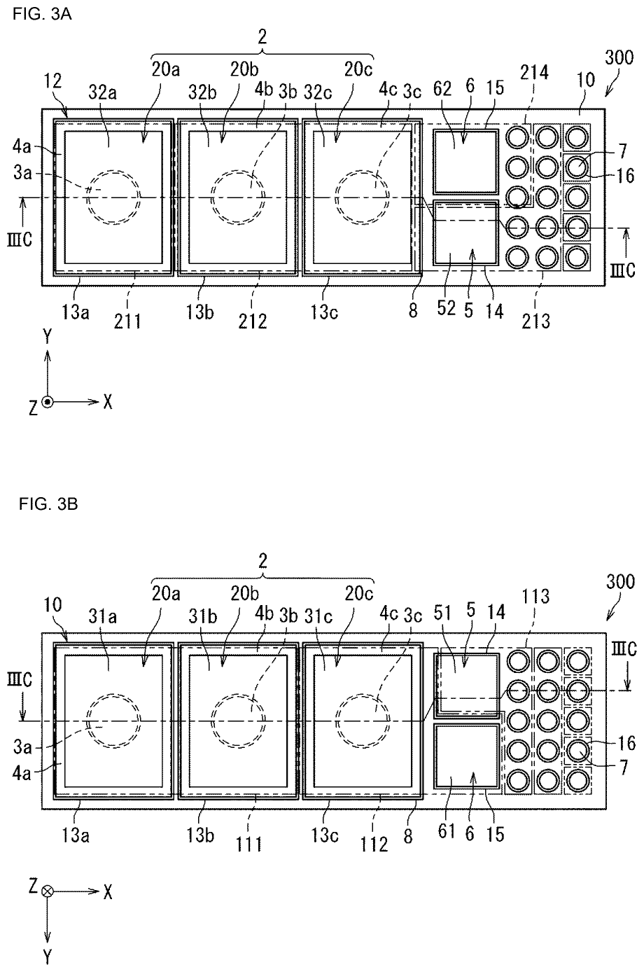

The structure of the component-embedded substrate 300 will be described below in further detail with reference to FIG. 3A to FIG. 3C. FIG. 3A and FIG. 3B are a schematic top view and a schematic bottom view, respectively, illustrating the component-embedded substrate and some of the wiring layers. FIG. 3C is a schematic cross-sectional view taken along line IIIC-IIIC in FIG. 3A and FIG. 3B. In FIG. 3C, the wiring layer 110 located closest to the substrate 10 side in the first wiring structure 100 and the wiring layer 210 located closest to the substrate 10 side in the second wiring structure 200 are shown in addition to the component-embedded substrate 300. In FIG. 3A and FIG. 3B, electrodes within the wiring layers 210 and 110 are indicated by double-dot chain lines to facilitate understanding.

As shown in FIG. 3A to FIG. 3C, the component-embedded substrate 300 includes the substrate 10, the inductor 2, an input capacitor 5, an output capacitor 6, and multiple core through conductors 7. The inductor 2 has three inductor unit cells 20a to 20c.

The inductor unit cells 20a to 20c, the input capacitor 5, the output capacitor 6, and the core through conductors 7 are located (embedded) inside the substrate 10.

As shown in FIG. 3C, the inductor 2 includes multiple (in this case, three) conductors 3a to 3c and multiple (in this case, three) magnetic bodies 4a to 4c. Each of the conductors 3a to 3c extends to penetrate through the corresponding one of the magnetic bodies 4a to 4c in the Z direction.

In this exemplary embodiment, the conductor 3a and the magnetic body 4a form one inductor unit cell 20a. Likewise, the conductor 3b and the magnetic body 4b form the inductor unit cell 20b, and the conductor 3c and the magnetic body 4c form the inductor unit cell 20c. The inductor unit cells 20a to 20c are connected in series, so as to form one inductor. In this description, when multiple inductors are connected in series to function as a single inductor, each of the multiple series-connected inductors is referred to as “inductor unit cell”. In other words, three components described as the inductor unit cells 20a to 20c may individually function as inductors.

In a plan view as viewed in the Z direction (which may simply be referred to as “plan view” hereinafter), the conductors 3a to 3c are spaced apart from one another within the substrate 10. The conductors 3a to 3c extend in the Z direction. In the example shown, the conductors 3a to 3c are arranged in this order in the X direction in plan view.

The magnetic body 4a is located around the conductor 3a to surround the peripheral surface of the conductor 3a. Likewise, the magnetic bodies 4b and 4c are respectively located around the conductors 3b and 3c to surround the peripheral surfaces of the conductors 3b and 3c. Two adjacent magnetic bodies among the magnetic bodies 4a to 4c are isolated from each other by a partition wall of the substrate 10.

In the example shown, end portions (first end portions) at the first surface 11 side of the conductors 3a and 3b are electrically connected to each other by a first connection electrode 111 within the wiring layer 110. Furthermore, end portions (second end portions) at the second surface 12 side of the conductors 3b and 3c are electrically connected to each other by a second connection electrode 212 within the wiring layer 210. Accordingly, the conductors 3a to 3c are connected in series.

In this exemplary embodiment, the inductor unit cells 20a to 20c are connected in series by the first and second connection electrodes 111 and 212, so as to form the inductor 2. By dividing the inductor into three or more (in this case, three) inductor unit cells 20a to 20c and disposing them within the substrate 10, a desired inductance value can be ensured, while the thickness of the substrate 10 required for disposing the inductor 2 can be reduced.

The substrate 10 and each embedded component of the component-embedded substrate 300 will be described below in further detail.

### (Substrate 10)

As shown in FIG. 3C, the substrate 10 has an inductor placement region r1 where the inductor 2 is placed, a capacitor placement region r2 where the capacitors 5 and 6 are placed, and a core-through-conductor placement region r3 where the multiple core through conductors 7 are placed. In this example, the inductor placement region r1, the capacitor placement region r2, and the core-through-conductor placement region r3 are disposed in this order in the X direction.

In the inductor placement region r1, the substrate 10 is provided with through-holes 13a to 13c extending therethrough from the first surface 11 to the second surface 12. Each of the through-holes 13a to 13c is, for example, a quadrilateral prismatic opening. In the example shown, the through-holes 13a to 13c are arranged in the X direction, and two adjacent through-holes are isolated by a partition wall of the substrate 10. The inductor unit cells 20a to 20c are respectively disposed within the through-holes 13a to 13c.

In the capacitor placement region r2, the substrate 10 is provided with two through-holes 14 and 15 extending therethrough from the first surface 11 to the second surface 12. Each of the through-holes 14 and 15 is, for example, a quadrilateral prismatic opening. In the example shown, the through-holes 14 and 15 are arranged in the Y direction, and the through-holes 14 and 15 are isolated by a partition wall of the substrate 10. The input capacitor 5 is disposed within the through-hole 14, and the output capacitor 6 is disposed within the through-hole 15.

In the core-through-conductor placement region r3, the substrate 10 is provided with multiple through-holes 16. In the example shown, 15 cylindrical through-holes 16 are arranged in a matrix in the X direction and the Y direction. The core through conductors 7 are respectively disposed within the through-holes 16. Each core through conductor 7 may function as a connection conductor for electrically connecting a circuit within the first wiring structure 100 and a circuit within the second wiring structure 200 to each other.

### (Inductor Unit Cells 20a to 20c)

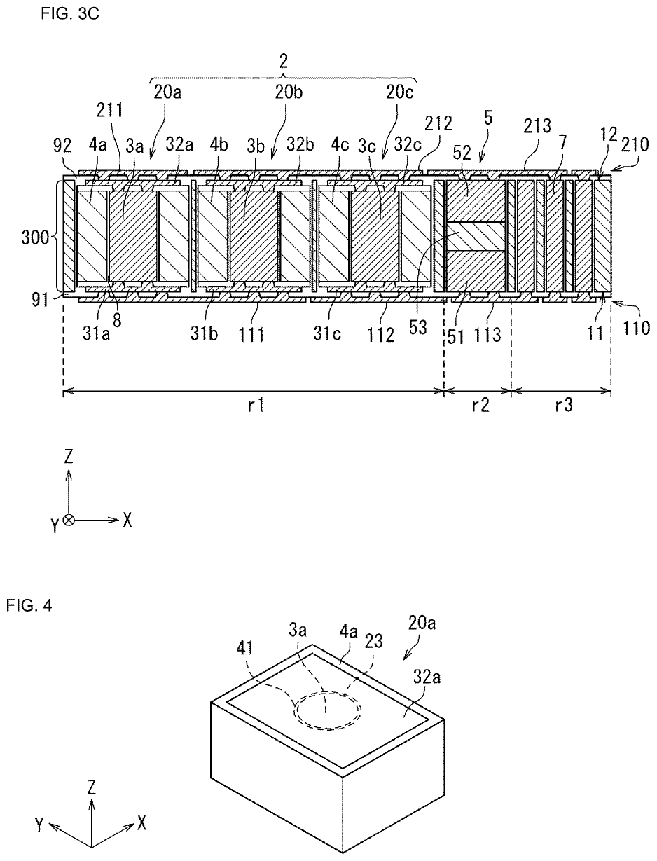

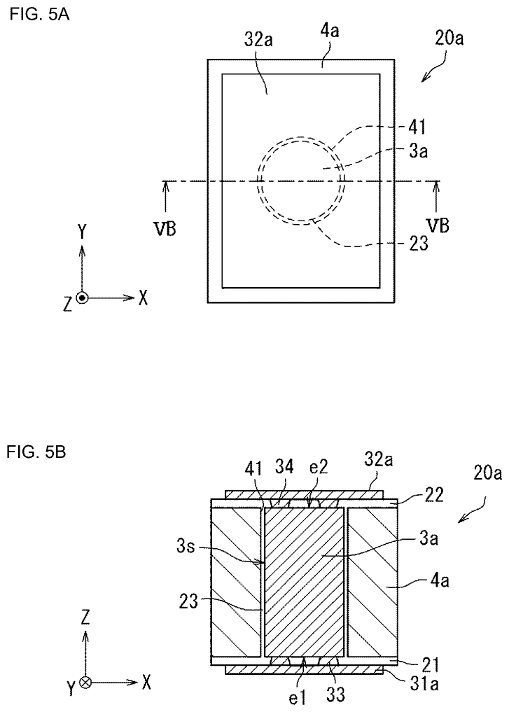

A detailed structure of each inductor unit cell will now be described with reference to FIG. 4 to FIG. 5B. FIG. 4 is a schematic perspective view of the inductor unit cell. FIG. 5A is a schematic top view of the inductor unit cell in FIG. 4. FIG. 5B is a schematic cross-sectional view taken along line VB-VB in FIG. 5A. The following description relates to the inductor unit cell 20a as an example.

The inductor unit cell 20a includes the magnetic body 4a, the conductor 3a extending through the magnetic body 4a, a first electrode 31a electrically connected to a first end portion of the conductor 3a, and a second electrode 32a electrically connected to a second end portion of the conductor 3a.

The magnetic body 4a has a shape corresponding to a through-hole in the substrate 10, and has, for example, a quadrilateral prismatic shape (in this case, a rectangular parallelepiped shape). The magnetic body 4a has a magnetic-body through-hole 41 extending therethrough in the thickness direction (Z direction). The magnetic-body through-hole 41 has, for example, a cylindrical shape. In plan view, the magnetic-body through-hole 41 is disposed substantially at the center of the magnetic body 4a.

The conductor 3a is disposed inside the magnetic-body through-hole 41 and extends in the Z direction. The conductor 3a has a shape corresponding to the shape of the magnetic-body through-hole 41. In this case, the conductor 3a is cylindrical and has a first end surface e1 and a second end surface e2, as well as a peripheral surface 3s located between these end surfaces e1 and e2. The peripheral surface 3s of the conductor 3a is surrounded by the magnetic body 4a. Each of the first end surface e1 and the second end surface e2 is at least partially exposed from the magnetic body 4a. The first end surface e1 is a surface facing downward (in the −Z direction). The first end surface e1 may be substantially flush with the lower surface of the magnetic body 4a. The second end surface e2 is a surface facing upward (in the +Z direction). The second end surface e2 may be substantially flush with the upper surface of the magnetic body 4a.

The inductor unit cell 20a may further include a resin member that seals the conductor 3a within the magnetic-body through-hole 41 of the magnetic body 4a. The resin member includes, for example, an insulation section 23 disposed to fill in a gap between the inner wall of the magnetic-body through-hole 41 and the conductor 3a. The resin member may cover the upper surface and the lower surface of the magnetic body 4a.

The first electrode 31a is disposed on the first end surface e1 of the conductor 3a with a first cell insulation section 21 interposed therebetween. The first electrode 31a is electrically connected to the first end portion of the conductor 3a via at least one (in this case, multiple) via conductor 33 disposed within the first cell insulation section 21. In the example shown, one end portion of the via conductor 33 is connected to the first electrode 31a, and the other end portion is connected to the first end surface e1 of the conductor 3a.

The second electrode 32a is disposed on the second end surface e2 of the conductor 3a with a second cell insulation section 22 interposed therebetween. The second electrode 32a is electrically connected to the second end portion of the conductor 3a via at least one (in this case, multiple) via conductor 34 disposed within the second cell insulation section 22. In the example shown, one end portion of the via conductor 34 is connected to the second electrode 32a, and the other end portion is connected to the second end surface e2 of the conductor 3a.

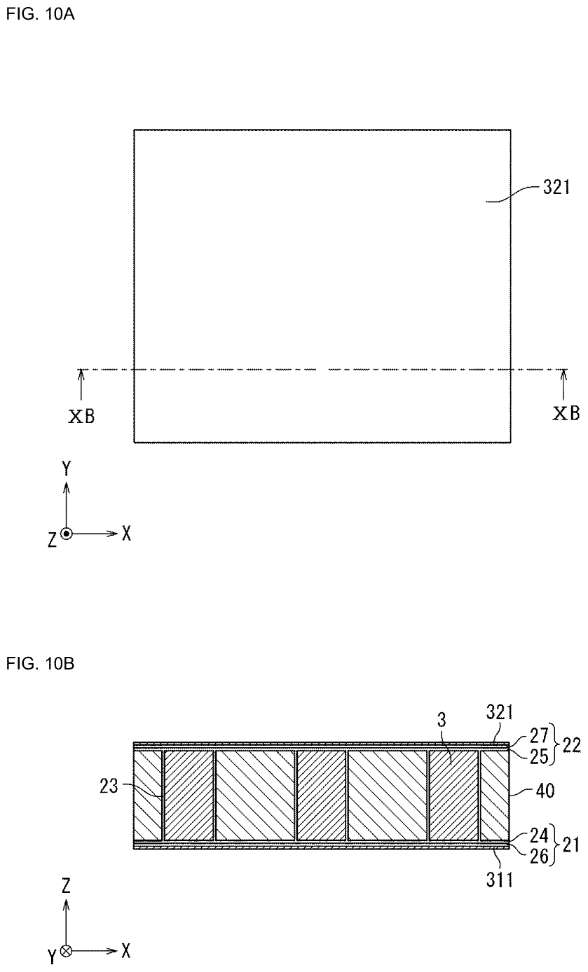

The first cell insulation section 21 may include a portion (i.e., a seal insulation layer 24 shown in FIG. 10B) of the resin member that covers the lower surface of the magnetic body 4a. Likewise, the second cell insulation section 22 may include a portion (i.e., a seal insulation layer 25 shown in FIG. 10B) of the resin member that covers the upper surface of the magnetic body 4a.

In plan view, the first electrode 31a and the second electrode 32a may each have an area larger than that of the corresponding conductor 3a. In the example shown, in plan view, the first electrode 31a overlaps the entire first end surface e1 of the conductor 3a and at least a portion of the magnetic body 4a. The second electrode 32a overlaps the entire second end surface e2 of the conductor 3a and at least a portion of the magnetic body 4a.

Each magnetic body 4a having the rectangular parallelepiped shape has a size of, for example, 2.3 mm (X direction)×3 mm (Y direction)×1.8 mm (Z direction). The magnetic-body through-hole 41 having the cylindrical shape has a diameter of, for example 1.1 mm. Each conductor 3a having the cylindrical shape has a diameter of 1.0 mm and a thickness of 1.8 mm. Each of the first cell insulation section 21 and the second cell insulation section 22 has a thickness of, for example, 30 μm.

The conductors 3a to 3c and the magnetic-body through-holes 41 each have a cylindrical shape in the example shown, but may have a prismatic shape. Moreover, the conductors 3a to 3c and the magnetic-body through-holes 41 do not have to be parallel to the Z direction so long as they extend from the upper surface to the lower surface of the magnetic body 4a.

As shown in FIG. 3A to FIG. 3C, similar to the inductor unit cell 20a, the other inductor unit cells 20b and 20c also include the magnetic bodies 4b and 4c, the conductors 3b and 3c, first electrodes 31b and 31c, and second electrodes 32b and 32c, respectively. The inductor unit cells 20b and 20c each have a structure similar to that of the inductor unit cell 20a described above with reference to FIG. 4 to FIG. 5B. The inductor unit cells 20a to 20c have the same size in this exemplary embodiment, but may have different sizes.

### (Capacitors 5 and 6)

As shown in FIG. 3C, the input capacitor 5 is a two-terminal capacitor that includes a lower electrode 51, an upper electrode 52, and a dielectric body 53. The dielectric body 53 is located between the lower electrode 51 and the upper electrode 52 in the Z direction. The lower electrode 51 is located at the first surface 11 side of the dielectric body 53, and the upper electrode 52 is located at the second surface 12 side of the dielectric body 53. The input capacitor 5 may function as a bypass capacitor on an input power line of the voltage regulation module.

Likewise, the output capacitor 6 is also a two-terminal capacitor that includes a lower electrode 61 (FIG. 3B), an upper electrode 62 (FIG. 3A), and a dielectric body located between the lower electrode 61 and the upper electrode 62 in the Z direction. The lower electrode 61 is located at the first surface 11 side of the dielectric body, and the upper electrode 62 is located at the second surface 12 side of the dielectric body. The output capacitor 6 may function as a bypass capacitor on an output power line of the voltage regulation module.

### (Seal Member 8)

The component-embedded substrate 300 further includes a seal member 8 that seals the substrate 10 having disposed therein the inductor unit cells 20a to 20c, the input capacitor 5, the output capacitor 6, and the core through conductors 7. In the example shown in FIG. 3C, the seal member 8 is disposed in gaps between the inner walls of the through-holes 13a to 13c and 14 to 16 and the components located in the through-holes. The seal member 8 may also be disposed on the first surface 11 of the substrate 10 and on the second surface 12 of the substrate 10.

### [Wiring Layers 110 and 210]

Next, the structure of the wiring layers 110 and 210 respectively disposed at the first surface 11 side and the second surface 12 side of the substrate 10 will be described with reference to FIG. 3A to FIG. 3C.

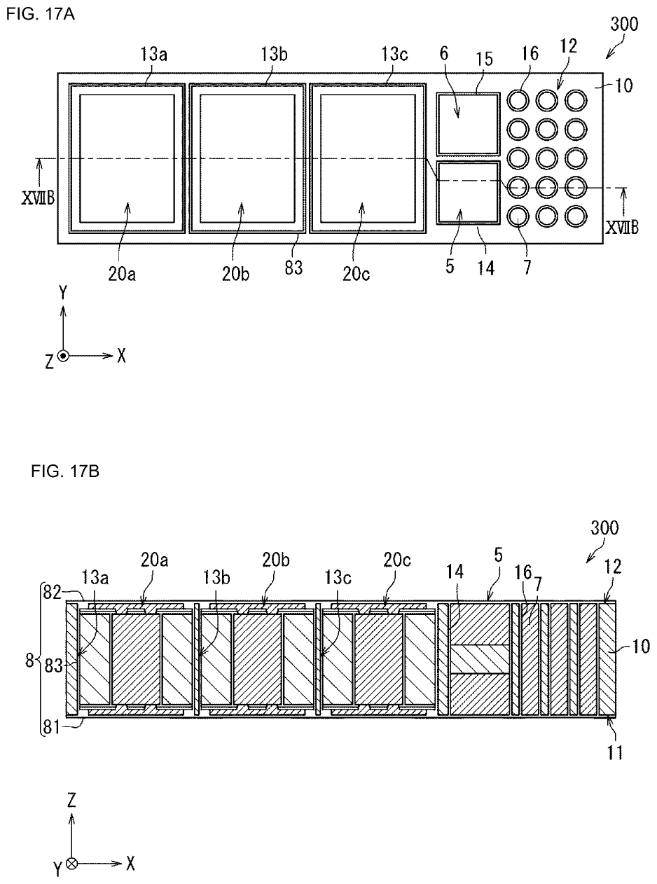

The wiring layer 110 (sometimes referred to as “first wiring layer”) is disposed at the first surface 11 of the substrate 10 via a first insulation section 91. The “first insulation section” is an insulation section located between the wiring layer 110 and the first surface 11 of the substrate 10. In this exemplary embodiment, the first insulation section 91 includes a portion (i.e., a lower insulation layer 81 shown in FIG. 17B) of the seal member 8 of the component-embedded substrate 300, as well as the insulation layer 101 (FIG. 2) located closest to the substrate 10 side in the first wiring structure 100.

The wiring layer 210 (sometimes referred to as “second wiring layer”) is disposed at the second surface 12 of the substrate 10 via a second insulation section 92. The “second insulation section” is an insulation section located between the wiring layer 210 and the second surface 12 of the substrate 10. In this exemplary embodiment, the second insulation section 92 includes a portion (an upper insulation layer 82 shown in FIG. 17B) of the seal member 8 of the component-embedded substrate 300, as well as the insulation layer 201 (FIG. 2) located closest to the substrate 10 side in the second wiring structure 200.

The first insulation section 91 has therein multiple via conductors for electrically connecting the components within the substrate 10 to the electrodes within the wiring layer 110. Likewise, the second insulation section 92 has therein multiple via conductors for electrically connecting the components within the substrate 10 to the electrodes within the wiring layer 210. At least one via conductor may be disposed for one electrode of the corresponding embedded component. In order to increase the connection area, it is preferable that multiple via conductors be disposed for one electrode.

### (Wiring Layer 110)

As shown in FIG. 3B and FIG. 3C, the wiring layer 110 has the first connection electrode 111, a first inductor connection electrode 112 connected to an output end of the inductor, and a first input capacitor connection electrode 113. These electrodes 111 to 113 are spaced apart from one another.

The first connection electrode 111 electrically connects the end portions (first end portions) at the first surface 11 side of the conductors 3a and 3b to each other. In the example shown, the first connection electrode 111 is electrically connected to the first electrode 31a of the inductor unit cell 20a and the first electrode 31b of the inductor unit cell 20b via the via conductors within the first insulation section 91.

The planar shape of the first connection electrode 111 is, for example, rectangular. In plan view, the first connection electrode 111 may entirely overlap the conductors 3a and 3b, preferably, the first electrodes 31a and 31b.

The first inductor connection electrode 112 electrically connects a first end portion of the conductor 3c serving as an output end of the inductor 2 to the lower electrode 61 of the output capacitor 6. In the example shown, the first inductor connection electrode 112 is electrically connected to the first electrode 31c of the inductor unit cell 20c and the lower electrode 61 of the output capacitor 6 via the via conductors within the first insulation section 91.

The first input capacitor connection electrode 113 is electrically connected to the lower electrode 51 of the input capacitor 5 and one or more of the core through conductors 7 via the via conductors within the first insulation section 91.

### (Wiring Layer 210)

As shown in FIG. 3A and FIG. 3C, the wiring layer 210 has a second inductor connection electrode 211 connected to an input end of the inductor, the second connection electrode 212, a second input capacitor connection electrode 213, and an output capacitor connection electrode 214. These electrodes 211 to 214 are spaced apart from one another.

The second inductor connection electrode 211 is electrically connected to a second end portion of the conductor 3a serving as an input end of the inductor 2. In the example shown, the second inductor connection electrode 211 is electrically connected to the second electrode 32a of the inductor unit cell 20a via the corresponding via conductor within the second insulation section 92.

The second connection electrode 212 electrically connects end portions (second end portions) at the second surface 12 side of the conductors 3b and 3c to each other. In the example shown, the second connection electrode 212 is electrically connected to the second electrode 32b of the inductor unit cell 20b and the second electrode 32c of the inductor unit cell 20c via the via conductors within the second insulation section 92.

The planar shape of the second connection electrode 212 is, for example, rectangular. In plan view, the second connection electrode 212 may entirely overlap the conductors 3b and 3c, preferably, the second electrodes 32b and 32c.

The second input capacitor connection electrode 213 is electrically connected to the upper electrode 52 of the input capacitor 5 and one or more of the core through conductors 7 via the via conductors within the second insulation section 92. Accordingly, the upper electrode 52 of the input capacitor 5 can be electrically connected to an input terminal Vin, located at the opposite side with the substrate 10 interposed therebetween, via the one or more core through conductors 7.

The output capacitor connection electrode 214 is electrically connected to the upper electrode 62 of the output capacitor 6 and one or more of the core through conductors 7 via the via conductors within the second insulation section 92. Accordingly, the upper electrode 62 of the output capacitor 6 can be electrically connected to a ground terminal GND, located at the opposite side with the substrate 10 interposed therebetween, via the one or more core through conductors 7.

### [Circuit Configuration of Voltage Regulation Module]

The circuit configuration of the circuit board 1 according to this exemplary embodiment will now be described. The following description relates to an example where the circuit board 1 is applied to a step-down switching regulator (step-down converter).

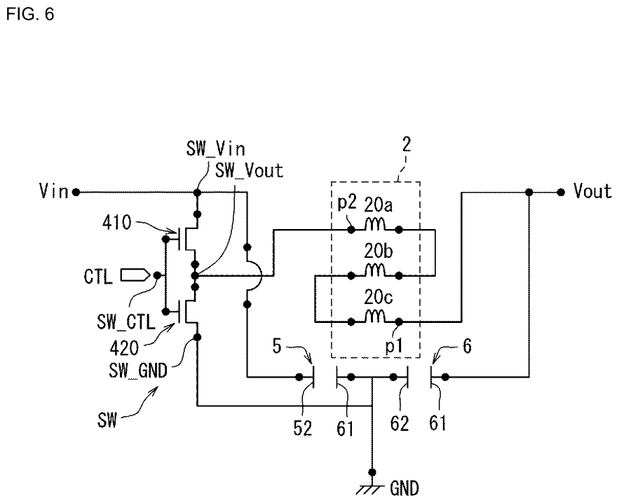

FIG. 6 is a diagram illustrating a basic circuit configuration of the voltage regulation module (step-down converter). The voltage regulation module includes the circuit board 1 according to this exemplary embodiment and a switch element SW.

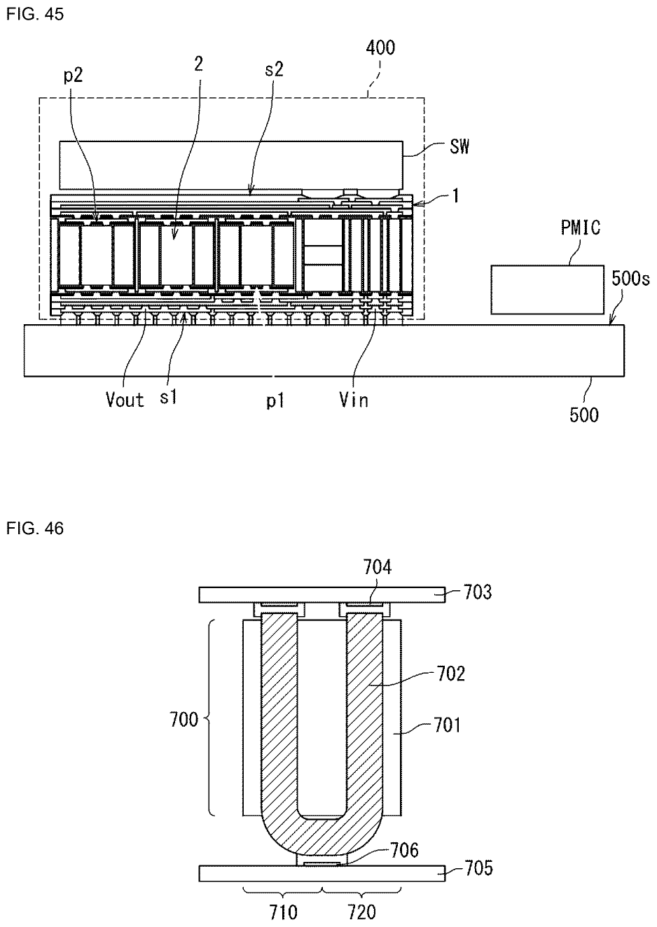

The switch element SW includes MOSFETs 410 and 420, a switch input terminal SW_Vin, a switch output terminal SW_Vout, a switch GND terminal SW_GND, and a switch control terminal SW-CTL. Other switching elements may be used in place of the MOSFETs. The switch element SW is disposed on, for example, the first principal surface of the circuit board 1 (see FIG. 45).

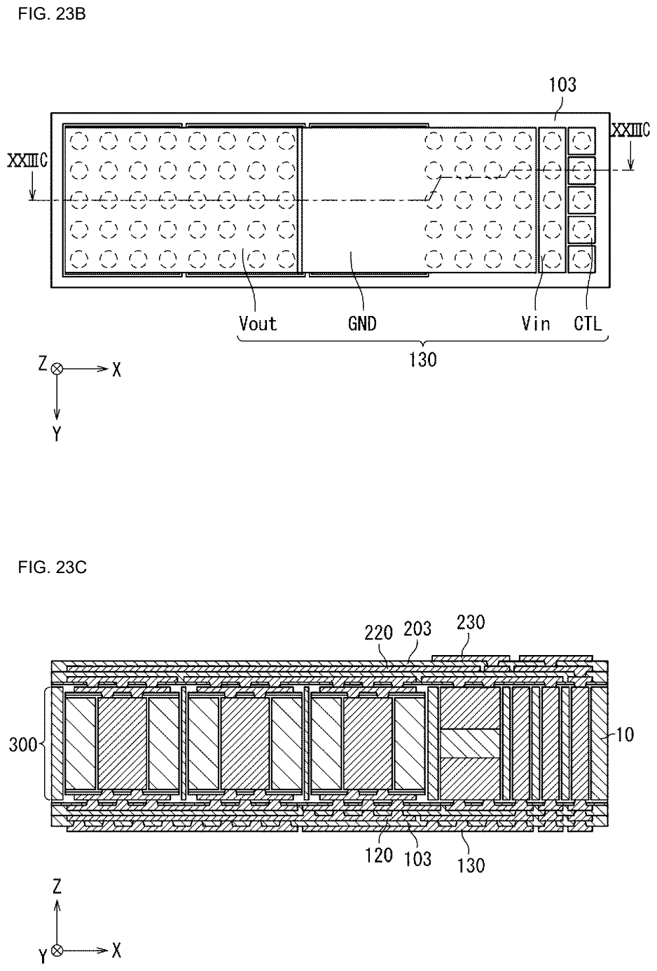

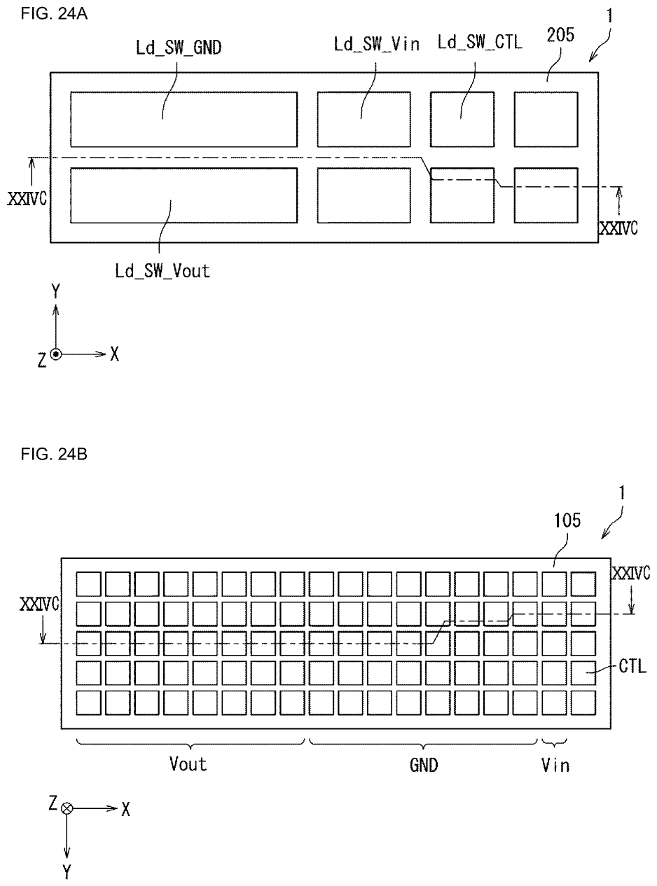

The inductor 2, the input capacitor 5, and the output capacitor 6 constituting the circuit shown in FIG. 6 are embedded in the circuit board 1. For example, the wiring layer 230 located at the uppermost side of the circuit board 1 is provided with a control terminal CTL, the input terminal Vin, an output terminal Vout, and the ground terminal GND (see FIG. 23A). The wiring layer 130 located at the lowermost side of the circuit board 1 is provided with terminal lands for the respective terminals of the switch element SW (see FIG. 23B).

In the circuit shown in FIG. 6, the MOSFET 410 at the high side is connected to the input terminal Vin. The MOSFET 420 at the low side is connected to the GND terminal side of the MOSFET 410. The switch input terminal SW_Vin receives an input voltage from the input terminal Vin.

The inductor 2 is formed by connecting the inductor unit cells 20a to 20c in series in this order. An input end p2 of the inductor 2 is connected to the switch output terminal SW_Vout.

The input capacitor 5 is shunt-connected to the switch input terminal SW_Vin. In this case, the upper electrode 52 of the input capacitor 5 is connected to the switch input terminal SW_Vin, and the lower electrode 51 is connected to the ground terminal GND.

The output capacitor 6 is shunt-connected to the output terminal Vout. In this case, the lower electrode 61 of the output capacitor 6 is connected to the output terminal Vout, and the upper electrode 62 is connected to the ground terminal GND.

According to this circuit, a pulse waveform generated by alternately turning the MOSFETs 410 and 420 on and off in the switch element SW is smoothed by the inductor 2 and the output capacitor 6. Accordingly, a desired output voltage is generated and is output from the output terminal Vout.

### [Material of Each Component]

A magnetic material used as each of the magnetic bodies (magnetized bodies) 4a to 4c of the inductor unit cells 20a to 20c may be a material having magnetic permeability, such as a metallic magnetic material or a ferrite sintered material. The magnetic material is desirably a composite of metallic magnetic powder and an organic material. The reason is that, because the magnetostriction of the metallic magnetic material is smaller than that of the ferrite sintered material, the metallic magnetic material exhibits little characteristic degradation due to external stress when embedded in the substrate 10. Moreover, the composite of the metallic magnetic powder and the organic material improves the direct-current superposition characteristics, facilitates the process for forming the through-holes, and so on. Furthermore, with the use of the organic material, for example, when embedded in the substrate 10, stress applied from the outside can be elastically absorbed, and internal stress applied to the metallic magnetic powder can be reduced. Thus, a decrease in inductance due to magnetostriction can be prevented. The metallic magnetic material is Fe, Co, Ni, or an alloy thereof (e.g., an FeSi-based alloy, such as FeSICr or FeSiAl, an FeCo-based alloy, or an NiFe-based alloy, such as NiFe), or a soft magnetic material, such as an amorphous alloy thereof. The organic material is an organic insulation material composed of, for example, an epoxy-based resin, polyimide, liquid crystal polymer, or bismaleimide.

The conductors 3a to 3c extending through the magnetic bodies 4a to 4c, as well as the core through conductors 7, are each composed of a metallic material with low volume resistivity. The metallic material used is desirably a Cu-based material in view of ease of processing and compatibility with the conductors used in the wiring layers (circuit layers).

The substrate 10, the first and second cell insulation sections 21 and 22, the seal member 8, and the insulation layers 101 to 103 and 201 to 203 constituting a printed circuit board are each composed of, for example, a thermosetting resin and an inorganic filler or a cross fiber of an inorganic material. Examples of the thermosetting resin include an epoxy-based resin, acrylic-based resin, and polyimide. The inorganic filler or the cross fiber of the inorganic material is composed of, for example, SiO₂.

Each of the wiring layers 110 to 130 and 210 to 230 constituting the circuit board 1 is a metallic layer composed of, for example, a Cu-based material. Each of the via conductors disposed within the insulation layers 101 to 103 and 201 to 203 is similarly a metallic conductor composed of a Cu-based material. Among the wiring layers, the wiring layers exposed by the openings in the solder-resist layers 105 and 205 may each have an AuNi coating on the surface layer or may each be given a rustproof treatment for the purpose of corrosion prevention, rust prevention, or better solder wettability.

### [Method for Manufacturing Circuit Board]

A method for manufacturing the circuit board 1 includes the following steps:
(1) a step for preparing components, such as the inductor unit cells and the two-terminal capacitors;
(2) an embedding step for disposing the components, such as the inductor unit cells, inside the substrate; and
(3) a wiring-structure forming step for forming wiring structures at the front and back surfaces of the substrate.

The step (1) for preparing the components includes a step for manufacturing the inductor unit cells. The steps will be sequentially described below.

### (Step for Manufacturing Inductor Unit Cells)

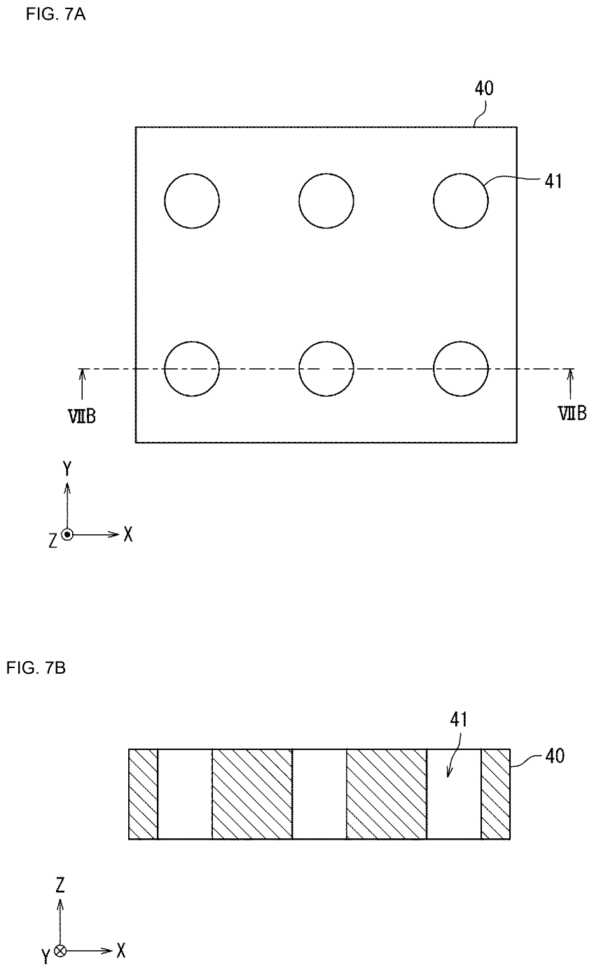

FIG. 7A to FIG. 14A are schematic process top views each illustrating the method for manufacturing the inductor unit cells. FIG. 7B to FIG. 14B are schematic process cross-sectional views taken along line A-A in shown in FIG. 7A to FIG. 14A.

As shown in FIG. 7A and FIG. 7B, a magnetic body block 40 that is to become magnetic bodies (magnetized bodies) of inductor unit cells is formed based on, for example, a pressure molding method. Then, multiple (in this case, six) magnetic-body through-holes 41 are formed in the magnetic body block 40 by drilling or the like. The magnetic-body through-holes 41 are spaced apart from one another in plan view.

In this case, for example, the magnetic body block 40 that is tabular and has a thickness of 1.8 mm is formed by thermal pressing. Then, a drill (with a drill diameter of 1.1 mmφ) is used to form cylindrical magnetic-body through-holes 41 with a diameter of 1.1 mm in the magnetic body block 40. After the magnetic body block 40 is formed, the magnetic body block 40 may be processed to a desired thickness by grinding or the like.

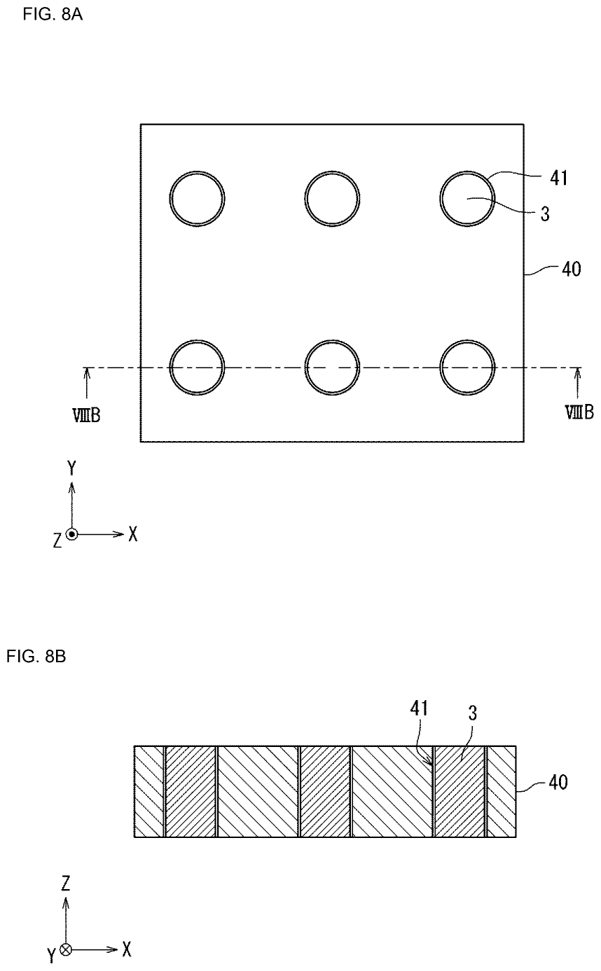

Subsequently, as shown in FIG. 8A and FIG. 8B, a conductor 3 is disposed in each of the magnetic-body through-holes 41 in the magnetic body block 40.

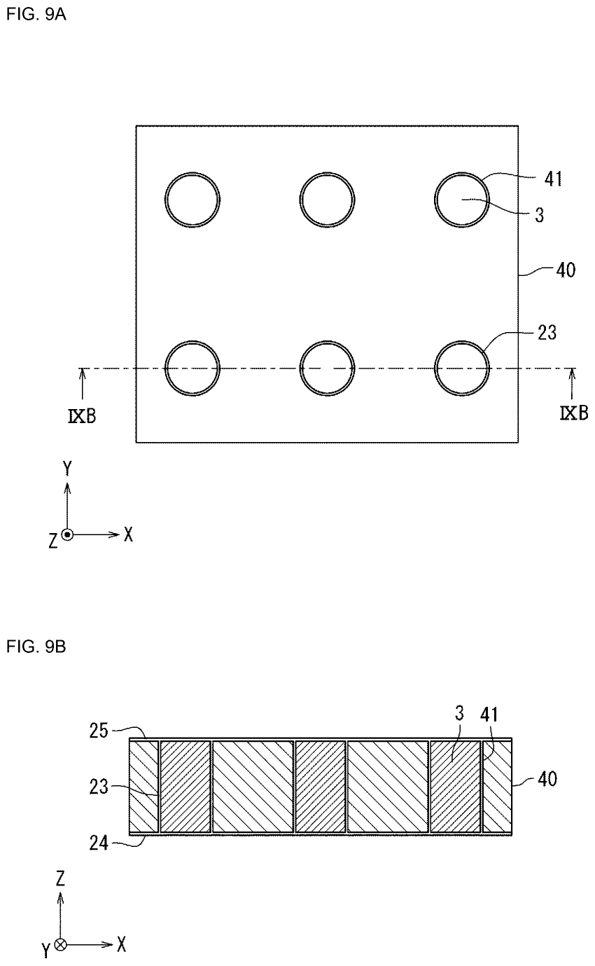

Then, as shown in FIG. 9A and FIG. 9B, by using a resin material, a resin member that seals a gap between the inner wall of each magnetic-body through-hole 41 and the peripheral surface of the corresponding conductor 3 is formed from the upper surface to the lower surface of the magnetic body block 40. The resin material used is a thermosetting resin composed of an epoxy-based material. The resin member includes an insulation section 23 located between the inner wall of the magnetic-body through-hole 41 and the conductor 3, a seal insulation layer 24 that covers the lower surfaces of the magnetic body block 40 and the conductor 3, and a seal insulation layer 25 that covers the upper surfaces of the magnetic body block 40 and the conductor 3. After sealing using the resin material, the thicknesses of the seal insulation layers 24 and 25 may be adjusted by a method such as grinding.

Subsequently, as shown in FIG. 10A and FIG. 10B, an insulation layer 26 is formed on the lower surface of the magnetic body block 40, and a lower conductor layer 311 is subsequently formed thereon. Likewise, an insulation layer 27 is formed on the upper surface of the magnetic body block 40, and a lower conductor layer 321 is subsequently formed thereon. Each of the insulation layers 26 and 27 formed is, for example, a layer composed of a thermosetting resin and an inorganic filler or a cross fiber of an inorganic material. In this description, an insulation section 21 including the insulation layer 26 and the seal insulation layer 24 is referred to as “first cell insulation section”. An insulation section 22 including the insulation layer 27 and the seal insulation layer 25 is referred to as “second cell insulation section”.

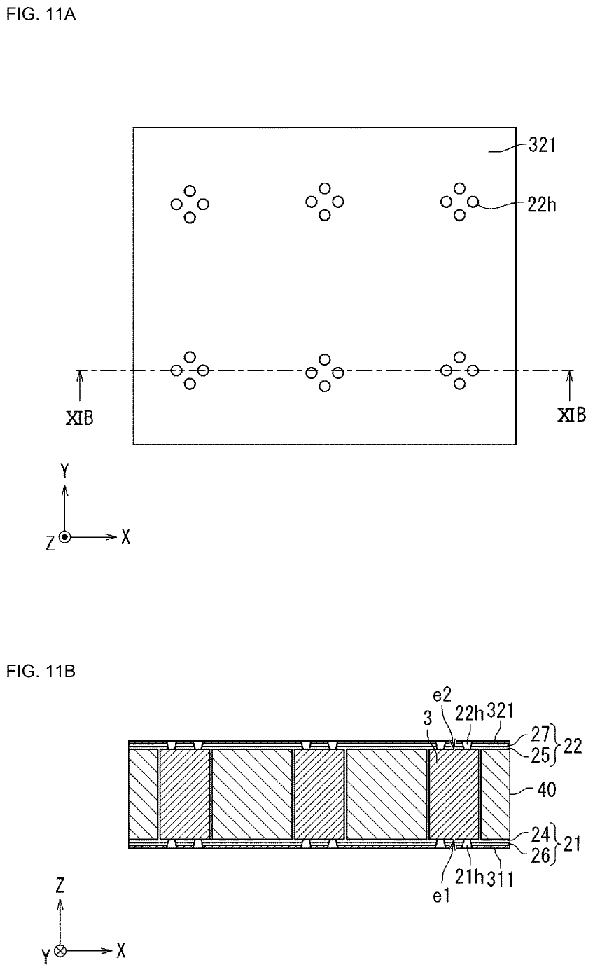

Then, as shown in FIGS. 11A and 11B, the lower conductor layers 311 and 321 partially undergo pattern etching, so that multiple openings are formed. The openings are disposed to overlap the end surfaces e1 and e2 of multiple conductors 3. Then, portions of the first and second cell insulation sections 21 and 22 that are exposed by the openings are removed by laser drilling or the like. Accordingly, via holes 21h that expose the first end surface e1 of each conductor 3 are formed in the first cell insulation section 21 and the lower conductor layer 311 at the lower surface of the magnetic body block 40. Moreover, via holes 22h that expose the second end surface e2 of each conductor 3 are formed in the second cell insulation section 22 and the lower conductor layer 321 at the upper surface of the magnetic body block 40.

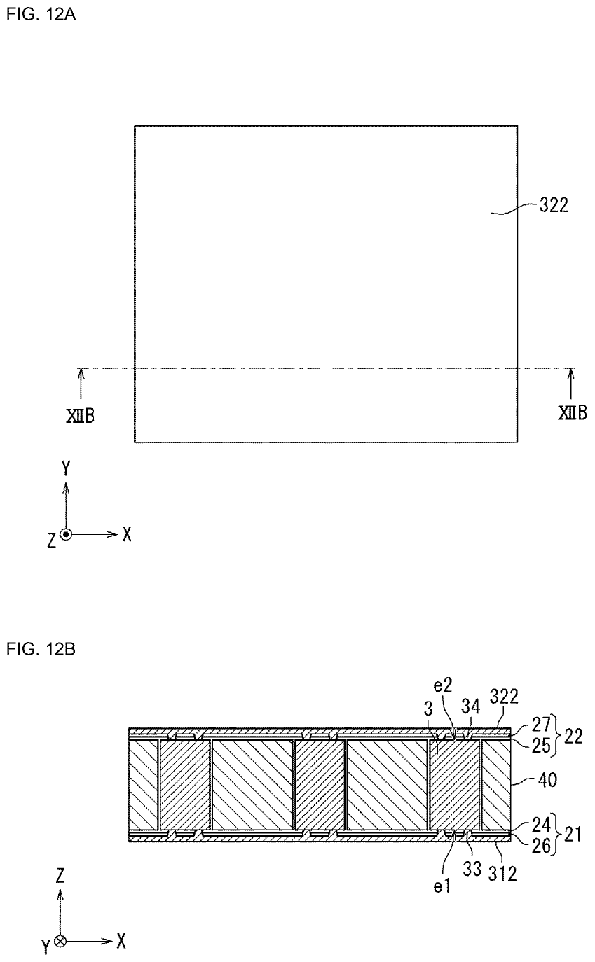

Then, the surface layers of the lower conductor layers 311 and 321 and the surface layers of the portions of the conductors 3 that are exposed by the via holes 21h and 22h undergo electroless plating and electrolytic plating. Consequently, as shown in FIG. 12A and FIG. 12B, via conductors 33 are formed within the via holes 21h, and a conductor layer 312 is formed on the first cell insulation section 21. The conductor layer 312 is electrically connected to the first end surface e1 of each conductor 3 by the via conductors 33. The conductor layer 312 includes the lower conductor layer 311 and a plating layer. Likewise, via conductors 34 are formed within the via holes 22h, and a conductor layer 322 is formed on the second cell insulation section 22. The conductor layer 322 is electrically connected to the second end surface e2 of each conductor 3 by the via conductors 34.

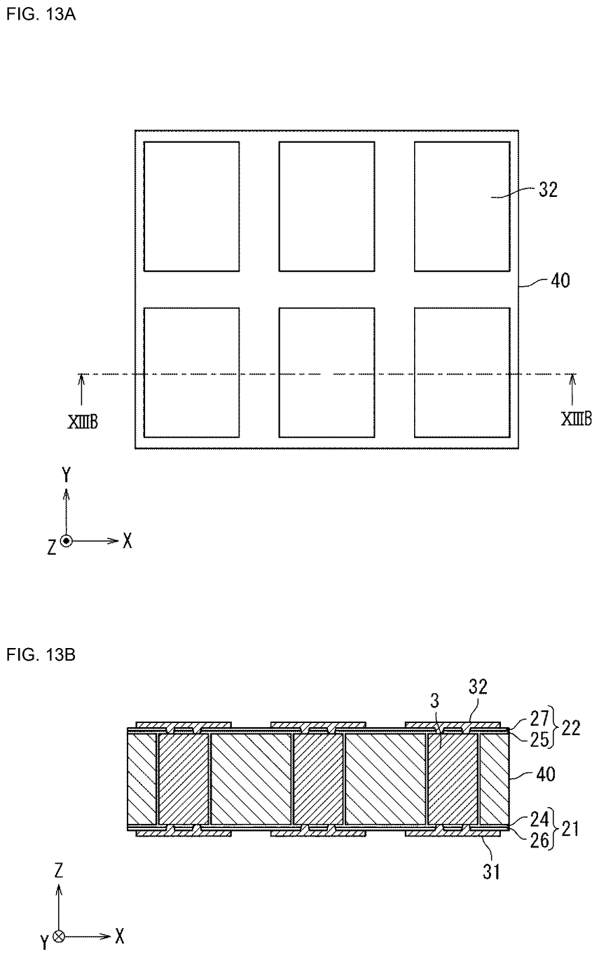

Subsequently, each of the conductor layers 312 and 322 is patterned to a desired shape. Consequently, as shown in FIG. 13A and FIG. 13B, multiple first electrodes 31 spaced apart from each other are formed from the conductor layer 312. Likewise, multiple second electrodes 32 spaced apart from each other are formed from the conductor layer 322. Each of the first electrodes 31 and one of the second electrodes 32 corresponding to the first electrode are opposed to each other with the corresponding one of the conductors 3 interposed therebetween in the Z direction.

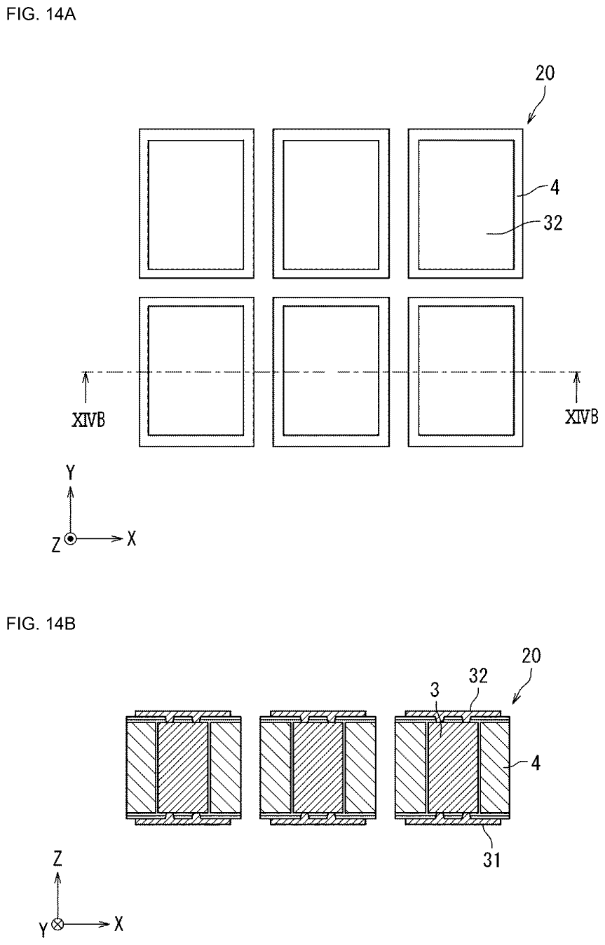

Then, as shown in FIG. 14A and FIG. 14B, the magnetic body block 40 is diced by using, a dicer or the like, so that multiple (in this case, six) inductor unit cells 20 are obtained. Each inductor unit cell 20 has one conductor 3, a magnetic body 4 located therearound, and a first electrode 31 and a second electrode 32 that are electrically connected to the conductor 3. Three of the six inductor unit cells 20 manufactured based on this method are used as the inductor unit cells 20a to 20c to be embedded in the circuit board.

### (Embedding Step)

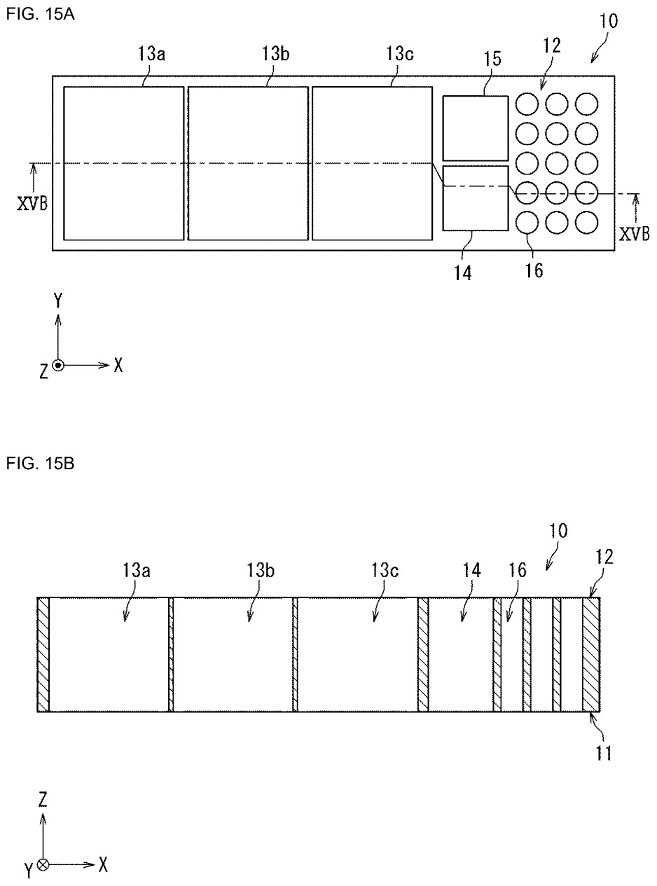

FIG. 15A to FIG. 17A are schematic process top views each illustrating the method for manufacturing the circuit board. FIG. 15B to FIG. 17B are schematic process cross-sectional views taken along line XVB-XVB to line XVIIB-XVIIB, respectively, shown in FIG. 15A to FIG. 17A.

As shown in FIG. 15A and FIG. 15B, the substrate 10 that is plate-shaped and has the first surface 11 and the second surface 12 is prepared. The substrate 10 is composed of, for example, a thermosetting resin and an inorganic filler or a cross fiber of an inorganic material. In the substrate 10, the through-holes (core through-holes) 13a to 13c, 14, and 15 and the multiple through-holes 16 are formed at predetermined locations by drilling or routing.

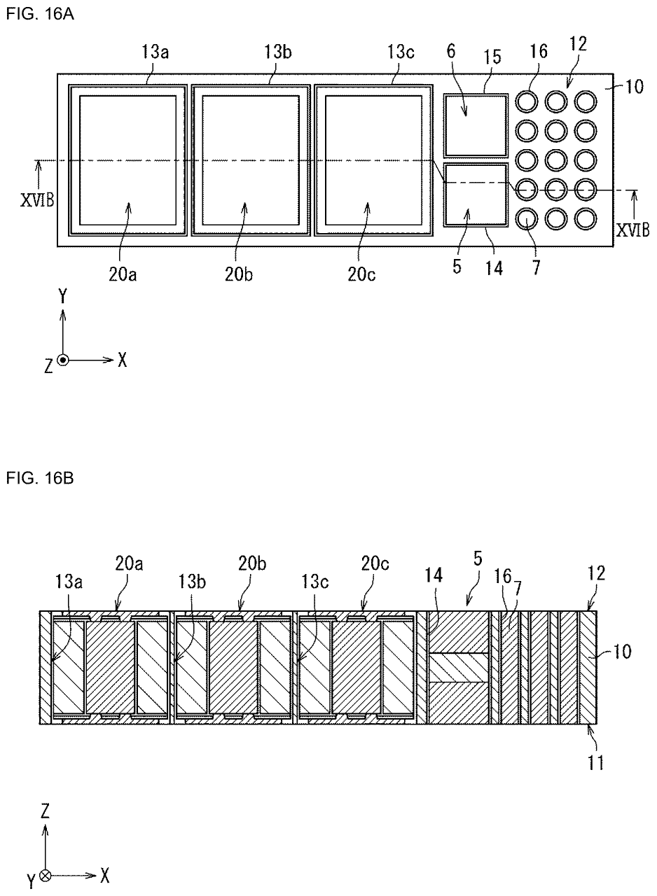

Then, as shown in FIG. 16A and FIG. 16B, the inductor unit cells 20a to 20c are respectively disposed in the through-holes 13a to 13c. Likewise, a two-terminal capacitor that is to become the input capacitor 5 is disposed in the through-hole 14, and a two-terminal capacitor that is to become the output capacitor 6 is disposed in the through-hole 15. The core through conductors 7 are respectively disposed in the multiple through-holes 16.

Subsequently, as shown in FIG. 17A and FIG. 17B, the embedded components, such as the inductor unit cells 20a to 20c, are sealed within the substrate 10 by the seal member 8. As the seal member 8, an insulation layer composed of a thermosetting resin and an inorganic filler or a cross fiber of an inorganic material is formed. The seal member 8 includes the lower insulation layer 81 located on the first surface 11 of the substrate 10 and the upper insulation layer 82 located on the second surface 12. Moreover, the seal member 8 further includes an insulation section 83 disposed to fill in a gap between the inner wall of each of the through-holes 13a to 16 and the peripheral surface of the corresponding embedded component. After the seal member 8 is formed, the thickness of the seal member 8 (i.e., the lower insulation layer 81 and the upper insulation layer 82) may be adjusted by grinding or the like. Accordingly, the component-embedded substrate 300 having embedded therein the inductor unit cells 20a to 20c, the capacitors 5 and 6, and the core through conductors 7 is formed.

### (Wiring-Structure Forming Step)

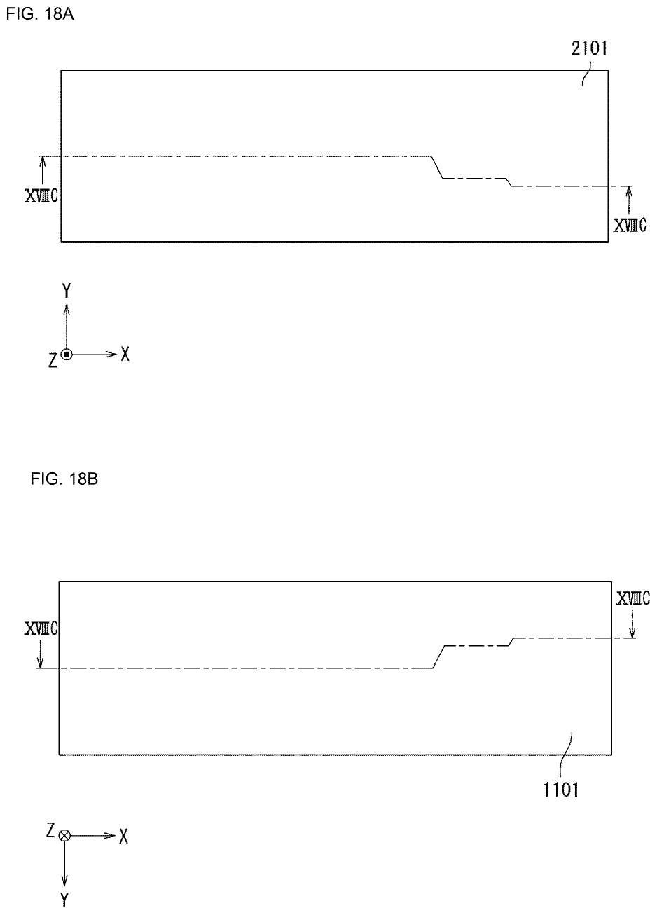

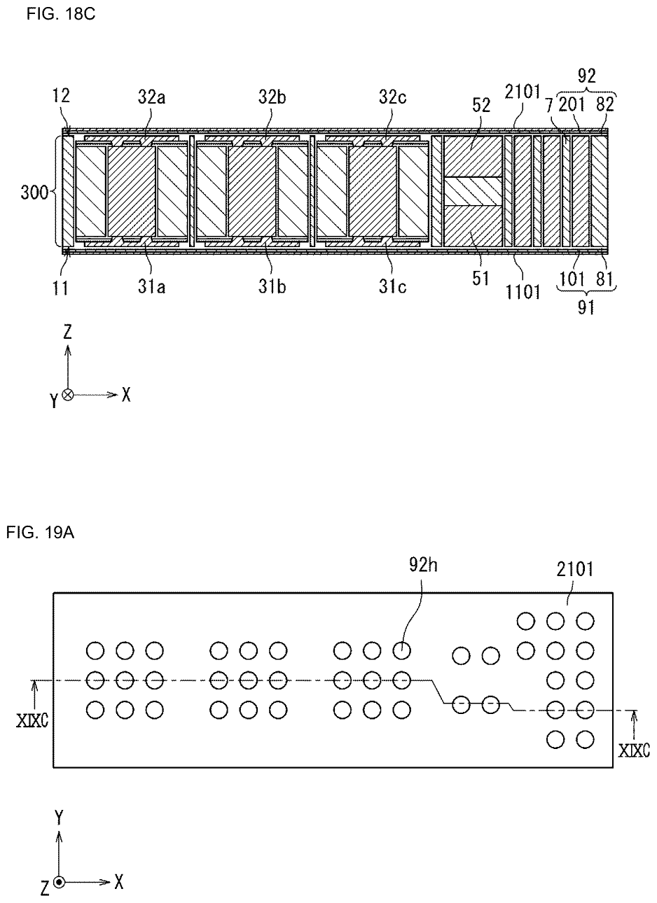

FIG. 18A to FIG. 24A are schematic process top views each illustrating the method for manufacturing the circuit board (wiring-structure forming step). FIG. 18B to FIG. 24B are process bottom views corresponding to FIG. 18A to FIG. 24A, respectively. FIG. 18C to FIG. 24C are schematic process cross-sectional views taken along line XVIIIC-XVIIIC to line XXIVC-XXIVC, respectively, shown in FIG. 18A to FIG. 24A.

A step for forming wiring layers constituting a wiring structure includes, for example, the following steps:
(i) a step for forming an insulation layer and a lower conductor layer;
(ii) a step for forming openings in the lower conductor layer;
(iii) a step for forming via holes by removing portions of the insulation layer that are located within the openings; and
(iv) a step for forming via conductors by forming an upper conductor layer (e.g., a plating layer) within the via holes and above the lower conductor layer, and obtaining a conductor layer electrically connected to electrodes located at opposite sides with the via conductors interposed therebetween; and
(v) a step for obtaining a wiring layer including multiple electrodes, wires, terminal portions, and the like by patterning the conductor layer.
   <Step (i)>

First, as shown in FIG. 18A to FIG. 18C, the insulation layer 101 is formed on the first surface 11 of the component-embedded substrate 300, and a lower conductor layer 1101 composed of Cu foil is subsequently formed. Likewise, the insulation layer 201 is formed on the second surface 12 of the substrate 10, and a lower conductor layer 2101 composed of Cu foil is subsequently formed. Each of the insulation layers 101 and 201 is a layer composed of, for example, a thermosetting resin and an inorganic filler or a cross fiber of an inorganic material.

In this exemplary embodiment, an insulation section (“first insulation section” hereinafter) 91 located between the lower conductor layer 1101 and the electrodes (e.g., the first electrodes 31a to 31c) of the embedded component includes the insulation layer 101 and the lower insulation layer 81. An insulation section (“second insulation section” hereinafter) 92 located between the lower conductor layer 2101 and the electrodes (e.g., the second electrodes 32a to 32c) of the embedded component includes the insulation layer 201 and the upper insulation layer 82.

<Steps (ii) and (iii)>

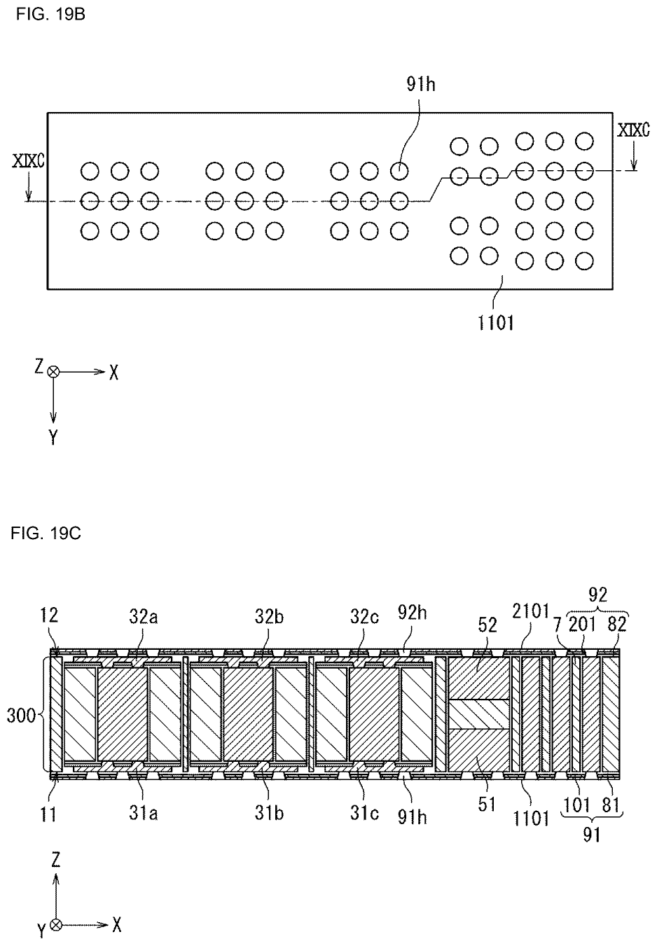

Subsequently, as shown in FIG. 19A to FIG. 19C, pattern-etching is performed on each of the lower conductor layers 1101 and 2101, so that multiple openings are formed (step (ii)). Then, portions of the first and second insulation sections 91 and 92 that are exposed by the openings are removed by laser drilling or the like (step (iii)). Accordingly, multiple via holes 91h are formed in the first insulation section 91 and the lower conductor layer 1101 at the first surface 11 side of the substrate 10. Each via hole 91h exposes a portion of the electrode at the first surface 11 side of the corresponding embedded component. Moreover, multiple via holes 92h are formed in the second insulation section 92 and the lower conductor layer 2101 at the second surface 12 side of the substrate 10. Each via hole 92h exposes a portion of the electrode at the second surface 12 side of the corresponding embedded component.

<Step (iv)>

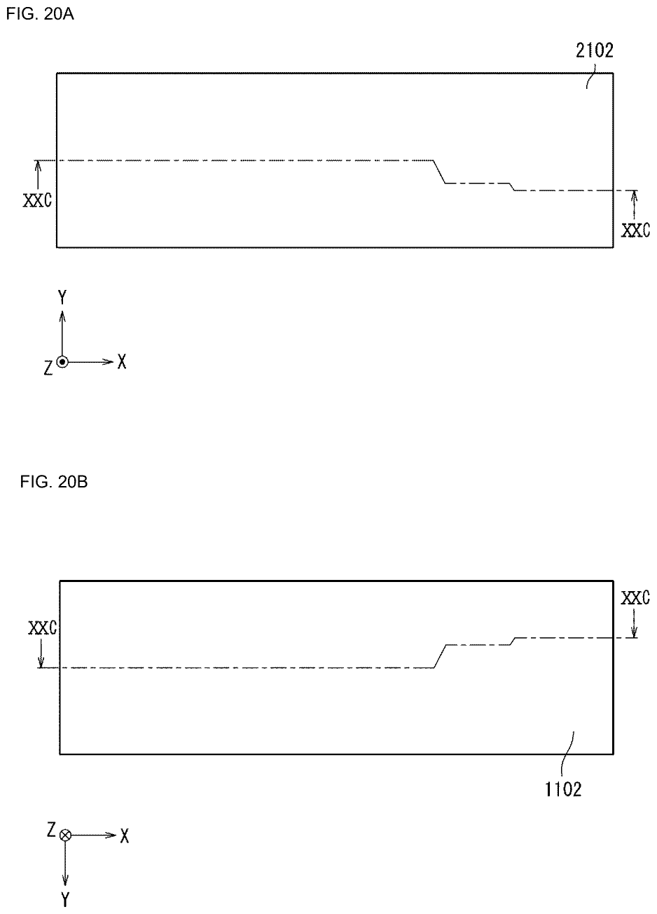

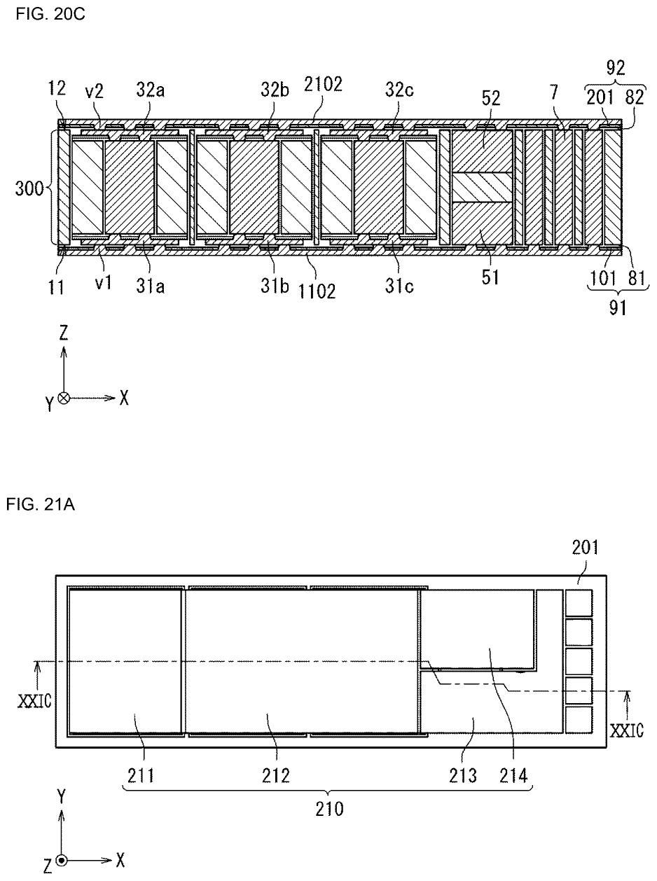

Subsequently, the surface layers of the lower conductor layers 1101 and 2101 and the surface layers of the portions of the electrodes of the embedded components that are exposed by the via holes 91h and 92h undergo electroless plating and electrolytic plating. Consequently, as shown in FIG. 20A to FIG. 20C, multiple via conductors v1 are formed within the via holes 91h, and a conductor layer 1102 is formed on the first insulation section 91. The conductor layer 1102 is electrically connected to the respective embedded components by the via conductors v1. Likewise, multiple via conductors v2 are formed within the via holes 92h, and a conductor layer 2102 is formed on the second insulation section 92. The conductor layer 2102 is electrically connected to the respective embedded components by the via conductors v2.

<Step (v)>

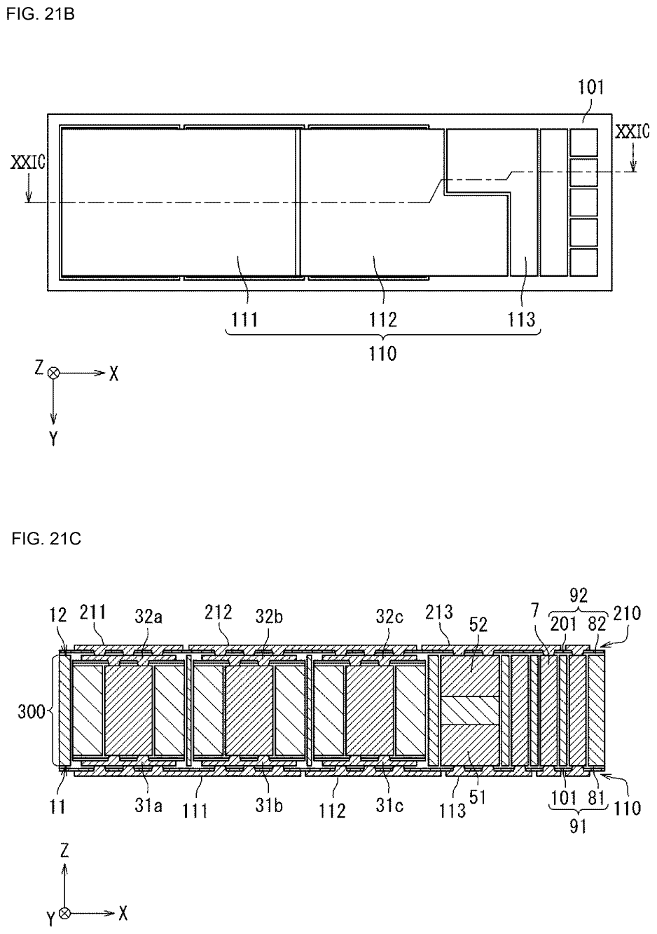

Subsequently, each of the conductor layers 1102 and 2102 is patterned to a desired shape (step (v)). As shown in FIG. 21A to FIG. 21C, by patterning the conductor layer 1102, the wiring layer 110 including multiple electrodes, such as the first connection electrode 111, the first inductor connection electrode 112, and the first input capacitor connection electrode 113, is obtained. Moreover, by patterning the conductor layer 2102, the wiring layer 210 including multiple electrodes, such as the second inductor connection electrode 211, the second connection electrode 212, the second input capacitor connection electrode 213, and the output capacitor connection electrode 214, is obtained.

### <Formation of Wiring Layers 120, 130, 220, and 230>

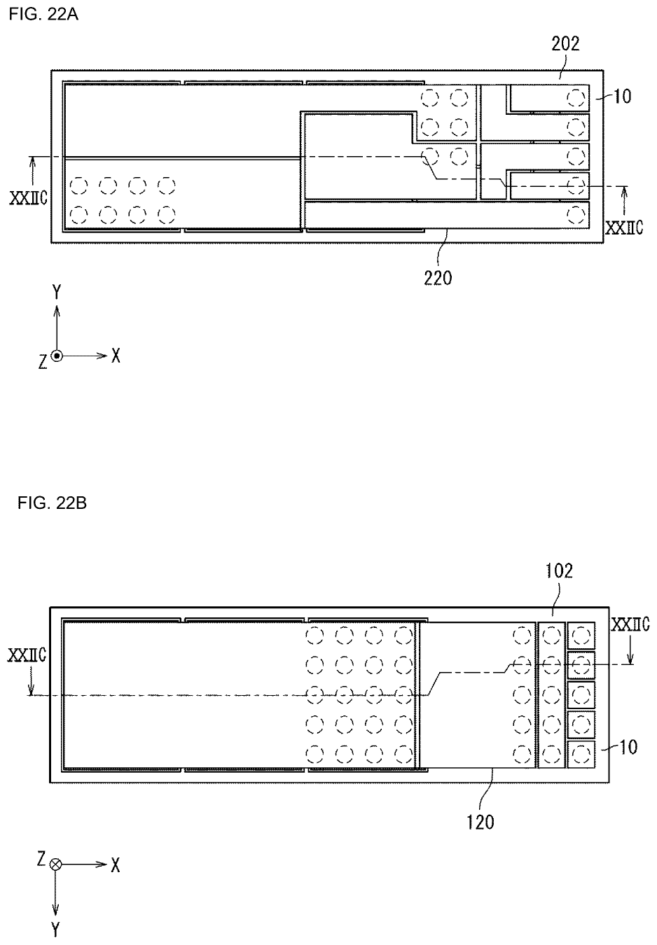

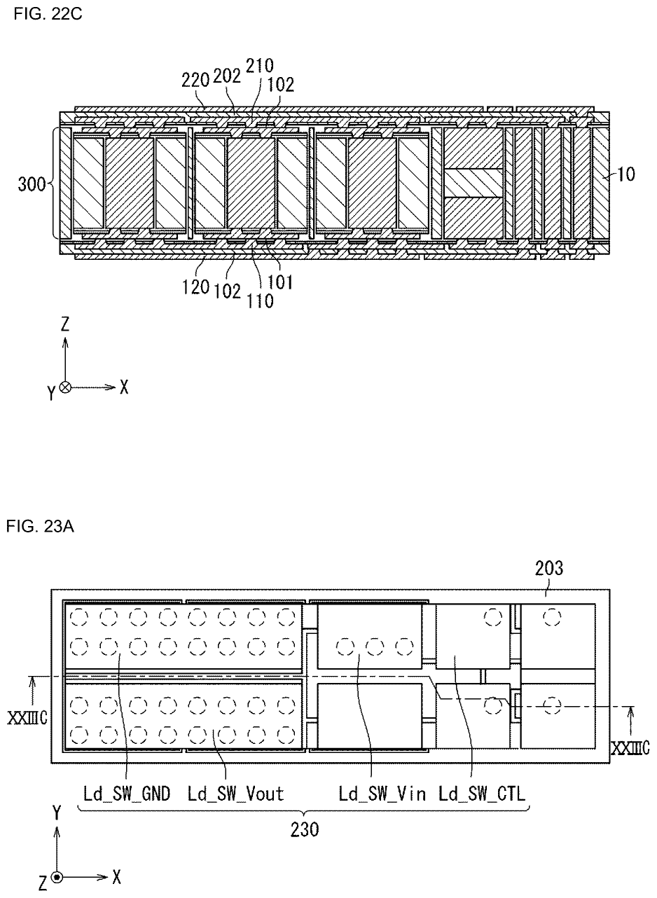

Subsequently, as shown in FIG. 22A and FIG. 22B, by performing steps similar to the aforementioned steps (i) to (v), the wiring layer 120 is formed on the wiring layer 110 via the insulation layer 102, and the wiring layer 220 is formed on the wiring layer 210 via the insulation layer 202. Each of the wiring layers 120 and 220 has multiple electrodes having desired patterns.

Subsequently, as shown in FIG. 23A and FIG. 23B, by performing steps similar to the aforementioned steps (i) to (v), the wiring layer 130 is formed on the wiring layer 120 via the insulation layer 103, and the wiring layer 230 is formed on the wiring layer 220 via the insulation layer 203.

In this exemplary embodiment, as shown in FIG. 23B, the wiring layer 130 has terminal portions, such as the control terminal CTL, the input terminal Vin, the output terminal Vout, and the ground terminal GND. As shown in FIG. 23A, the wiring layer 230 has terminal lands Ld_SW_Vin, Ld_SW_Vout, Ld_SW_GND, and Ld_SW-CTL for the respective terminals (SW_Vin, SW_Vout, SW_GND, and SW-CTL) (see FIG. 6) of the switch element SW.

### <Formation of Solder-Resist Layers>

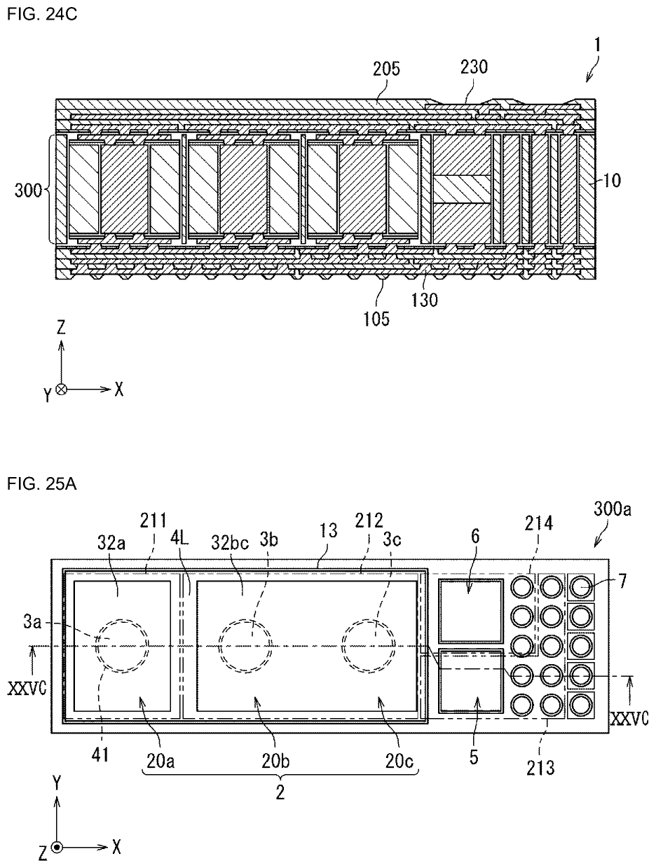

Subsequently, as shown in FIG. 24A and FIG. 24B, the solder-resist layer 105 is formed on the wiring layer 130, and the solder-resist layer 205 is formed on the wiring layer 230. The solder-resist layers 105 and 205 have openings that expose portions that are to become lands in the wiring layers 130 and 230. The surface (conductor surface) of each of the portions of the wiring layers 120 and 230 that are exposed by the openings in the solder-resist layers 105 and 205 may be given NiAu-based anti-corrosion and anti-rust treatments or other surface treatments. The circuit board 1 is manufactured in this manner.

### Technical Effects

First, a magnetic core assembly according to a reference example having embedded therein an inductor (vertical inductor) through which electric current flows in the thickness direction will be described for comparison. FIG. 46 is a schematic cross-sectional view of a magnetic core assembly 700, and illustrates a reference example that is described in U.S. Patent Application Publication No. 2020/0111597. In the magnetic core assembly 700 according to the reference example, a U-shaped conductor 702 is disposed to extend through a magnetic core 701 in the thickness direction, whereby two inductors 710 and 720 are formed. The inductors 710 and 720 are connected in parallel. In order to achieve a desired inductance value with this structure, the conductor 702 is sometimes tall, and the magnetic core assembly 700 is sometimes thick.

In the reference example shown in FIG. 46, the following problems may also occur. The magnetic core assembly 700 is electrically and mechanically connected to upper and lower printed circuit boards 703 and 705 by soldering or the like. In detail, an upper end portion of the conductor 702 is connected to a bonding pad 704 of the printed circuit board 703 by using solder. A lower end portion (bent portion) of the conductor 702 is connected to a bonding pad 706 of the printed circuit board 705 by using solder. With this structure, it is difficult to achieve size reduction due to the bent portion. Moreover, with this structure, the connection between assemblies is sometimes partial (i.e., connection sections between the assemblies are discretely disposed and air gaps exist between the assemblies). As a result, mechanical stress concentrates on the connection sections between the assemblies, possibly resulting in reduced connection reliability.

In contrast, in this exemplary embodiment, the inductor 2 is embedded in the circuit board 1, whereby a voltage regulation module reduced in size and thickness can be formed, as compared with the structure in which printed circuit boards are disposed at opposite sides of an inductor, as shown FIG. 46.

Furthermore, with the circuit board 1 according to this exemplary embodiment, a vertical inductor through which electric current flows in the thickness direction (i.e., a direction perpendicular to the circuit surface) is divided into three or more parts that can be disposed within the substrate 10. The bent portion as in the reference example is not necessary. Accordingly, the component-embedded substrate 300 can be made thinner, while a desired inductance value can be ensured. Therefore, by using the circuit board 1, the voltage regulation module can be made even thinner.

Furthermore, with the circuit board 1 according to this exemplary embodiment, the inductor 2 (inductor unit cells 20a to 20c) is surface-mounted to the wiring layers 110 and 210 via the insulation sections 91 and 92, whereby the mechanical connection stability of the inductor 2 can be significantly improved, as compared with the structure according to the reference example shown in FIG. 46.

In the circuit board 1 according to this exemplary embodiment, the number of inductor unit cells (i.e., the number of conductors 3a to 3c) constituting the inductor 2 is three. Accordingly, one of the input end and the output end of the inductor 2 can be readily connected to an electrode at the first surface 11 side of the substrate 10, and the other one can be readily connected to an electrode at the second surface 12 side. Thus, when the circuit board 1 is applied to a voltage regulation module (see FIG. 45), a path from the switch output terminal SW_Vout to the input end of the inductor 2 and a path from the output end to the output terminal Vout can be shortened. As a result, the electrical resistance of the voltage regulation module can be reduced, so that the efficiency of the voltage regulation module can be enhanced.

Although the circuit board 1 shown includes three inductor unit cells, the number of inductor unit cells is not particularly limited so long as the number is one or more. The number of inductor unit cells is preferably an odd value. With an odd value, the input end and the output end of the inductor 2 can be readily connected to wiring layers located opposite each other with the substrate 10 interposed therebetween. Therefore, when the circuit board 1 is applied to a voltage regulation module, a current path excluding the inductor 2 can be shortened.

In the circuit board 1 according to this exemplary embodiment, the first electrodes 31a to 31c and the second electrodes 32a to 32c (collectively referred to as “inductor electrodes”) of the inductor unit cells 20a to 20c are each disposed to overlap the entire corresponding conductor and at least a portion of the corresponding magnetic body in plan view. Accordingly, multiple via conductors for connecting to the electrodes within the wiring layer 110 or 210 can be disposed on each inductor electrode, so that the connection area can be increased. Thus, the connection resistance can be reduced, whereby the connection reliability can be enhanced.

According to this exemplary embodiment, the inductor electrodes are larger than the conductors in plan view, so that multiple via conductors that connect the first electrodes 31a and 31b and the first connection electrode 111 can be disposed in a wider area than the end surfaces of the conductors 3a and 3b in plan view. In plan view, at least one of the via conductors may be located outside the corresponding conductor 3a or 3b. Likewise, in plan view, multiple via conductors that connect the second electrodes 32b and 32c and the second connection electrode 212 can be disposed in a wider area than the end surfaces of the conductors 3a and 3b. Accordingly, the connection resistance between the inductor unit cells can be reduced, so that the direct-current resistance of the inductor 2 formed of the inductor unit cells 20a to 20c can be reduced.

The circuit board 1 according to this exemplary embodiment includes at least one of the two-terminal capacitors 5 and 6 located inside the substrate 10. At least one of the two-terminal capacitors 5 and 6 and the inductor 2 are connected in parallel in a direction intersecting the Z direction. By using such a circuit board 1, the voltage regulation module can be further reduced in thickness, as compared with a structure in which a capacitor and an inductor are disposed in the thickness direction (e.g., U.S. Patent Application Publication No. 2020/0111597).

A two-terminal capacitor (e.g., the input capacitor 5) in this exemplary embodiment includes the dielectric body 53, the lower electrode 51 located at the first surface 11 side of the dielectric body 53, and the upper electrode 52 located at the second surface 12 side of the dielectric body 53. The lower electrode 51 is electrically connected to a wire within the first wiring layer 110 via a via conductor provided in the first insulation section 91. The upper electrode 52 is electrically connected to a wire within the second wiring layer 210 via a via conductor provided in the second insulation section 92. With this configuration, the connection resistance between each electrode of the two-terminal capacitor and the corresponding wiring layer can be reduced, so that the connection reliability can be enhanced.

The circuit board according to the present disclosure is not limited to the exemplary embodiment shown in FIG. 1 to FIG. 24C, and may be implemented in accordance with any of other various embodiments. For example, one of or each of the input capacitor and the output capacitor does not have to be disposed inside the substrate 10. Moreover, the substrate 10 may have two or more inductors 2 embedded therein. Furthermore, the layout of the embedded components in the substrate 10, the circuit configuration of the circuit board 1, the number of wiring layers in the circuit board 1, the electrode pattern within each wiring layer, and the like are not limited to those in the example shown, and may be selected as appropriate.

Although a single conductor that extends through a magnetic body is disposed in each of the inductor unit cells 20a to 20c in the above exemplary embodiment, two or more conductors that extend through the magnetic body may be disposed within each inductor unit cell. These conductors may be spaced apart, and may be connected in parallel by an inductor electrode. In other words, each inductor unit cell may be formed of two or more parallel-connected inductors.

As mentioned above, the inductor unit cells individually function as inductors. Therefore, by connecting the conductors 3a to 3c in parallel, three inductors can be formed by the conductors 3a to 3c and the magnetic bodies 4a to 4c. In this case, the first electrodes 31a to 31c may all be electrically connected to the first connection electrode 111, and the second electrodes 32a to 32c may all be electrically connected to the second connection electrode 212.

### Second Exemplary Embodiment

A circuit board according to a second exemplary embodiment is different from the circuit board according to the first exemplary embodiment in that the three inductor unit cells are integrally formed. The following description mainly focuses on the differences from the circuit board according to the first exemplary embodiment, and redundant descriptions will be omitted, where appropriate.

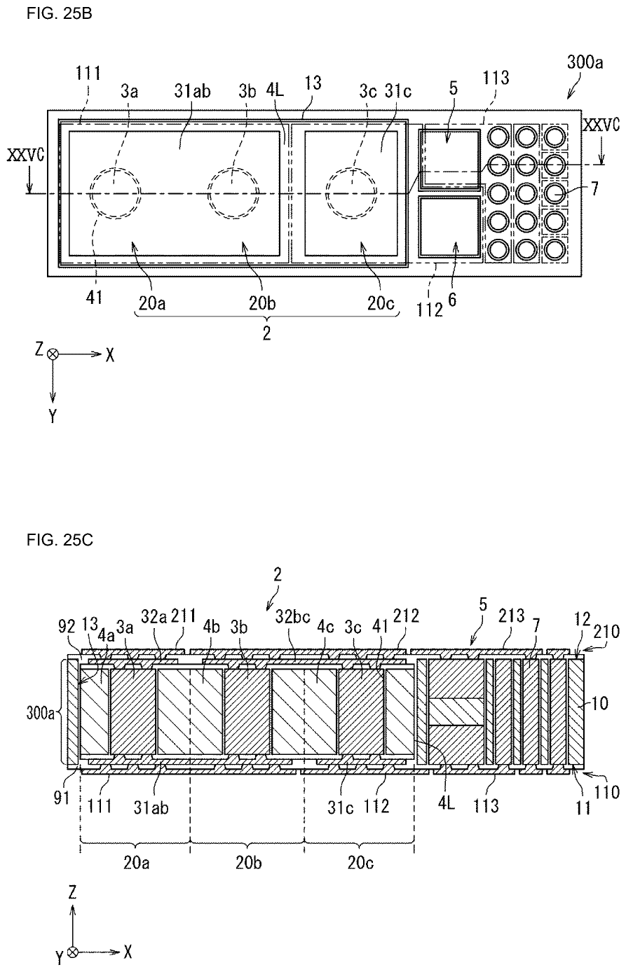

FIG. 25A and FIG. 25B are a schematic top view and a schematic bottom view, respectively, illustrating a component-embedded substrate and some of wiring layers in the circuit board according to this exemplary embodiment. FIG. 25C is a schematic cross-sectional view taken along XXVC-XXVC in FIG. 25A and FIG. 25B. In FIG. 25C, the wiring layer 110 and the wiring layer 210 are also shown. In FIG. 25A and FIG. 25B, electrodes within the wiring layers 210 and 110 are indicated by double-dot chain lines to facilitate understanding.

A component-embedded substrate 300a is different from the component-embedded substrate 300 shown in FIG. 3A to FIG. 3C in that the inductor 2 is disposed as a single component within a single through-hole 13 in the substrate 10. The inductor 2 according to this exemplary embodiment is different from the inductor 2 shown in FIG. 3A to FIG. 3C in that the magnetic bodies 4a to 4c are integrally formed (i.e., connected), the two first electrodes 31a and 31b are integrally formed, and the two second electrodes 32b and 32c are integrally formed.

The inductor 2 includes a magnetic body layer 4L, the conductors 3a to 3c, first electrodes 31ab and 31c, and second electrodes 32a and 32bc.

The magnetic body layer 4L has a rectangular parallelepiped shape that is long in the X direction. The magnetic body layer 4L is provided with three magnetic-body through-holes 41 spaced apart from one another in plan view. The magnetic-body through-holes 41 respectively have conductors 3a to 3c disposed therein. In the magnetic body layer 4L, portions 4a to 4c thereof that are located to surround the peripheral surfaces of the conductors 3a to 3c are to become magnetized bodies of the inductor unit cells 20a to 20c. The magnetic bodies 4a to 4c are continuous (connected), and a partition wall of the substrate 10 is not disposed between adjacent magnetic bodies.

The first electrode 31ab is an electrode obtained by integrally forming the first electrodes 31a and 31b in FIG. 3A to FIG. 3C. The first electrode 31ab is disposed with a distance from the first electrode 31c at the first surface 11 side of the magnetic body layer 4L. The first electrode 31ab is electrically connected to first end portions of the conductors 3a and 3b. The first electrode 31ab is electrically connected to the first connection electrode 111 via the corresponding via conductor within the first insulation section 91.

The second electrode 32bc is an electrode obtained by integrally forming the second electrodes 32b and 32c in FIG. 3A to FIG. 3C. The second electrode 32bc is disposed with a distance from the second electrode 32a at the second surface 12 side of the magnetic body layer 4L. The second electrode 32bc is electrically connected to second end portions of the conductors 3b and 3c. The second electrode 32bc is electrically connected to the second connection electrode 212 via the corresponding via conductor within the second insulation section 92.

In the example shown, the first electrode 31ab entirely overlaps the conductors 3a and 3b in plan view. In plan view, the first electrode 31ab may be slightly smaller than the first connection electrode 111 and be located within the contour of the first connection electrode 111. Similarly, in plan view, the second electrode 32bc entirely overlaps the conductors 3b and 3c. In plan view, the second electrode 32bc may be located within the contour of the second connection electrode 212.

### [Method for Manufacturing Circuit Board]

A method for manufacturing the circuit board 1 according to this exemplary embodiment is similar to the manufacturing method according to the first exemplary embodiment described with reference to FIG. 7A to FIG. 24C. The following description focuses on the differences from the first exemplary embodiment, and redundant descriptions will be omitted.

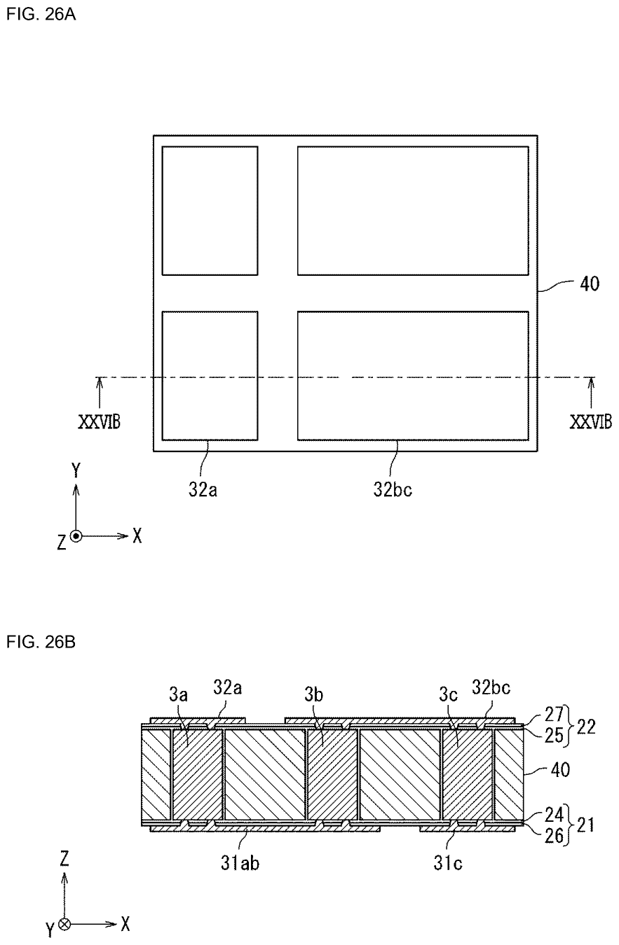

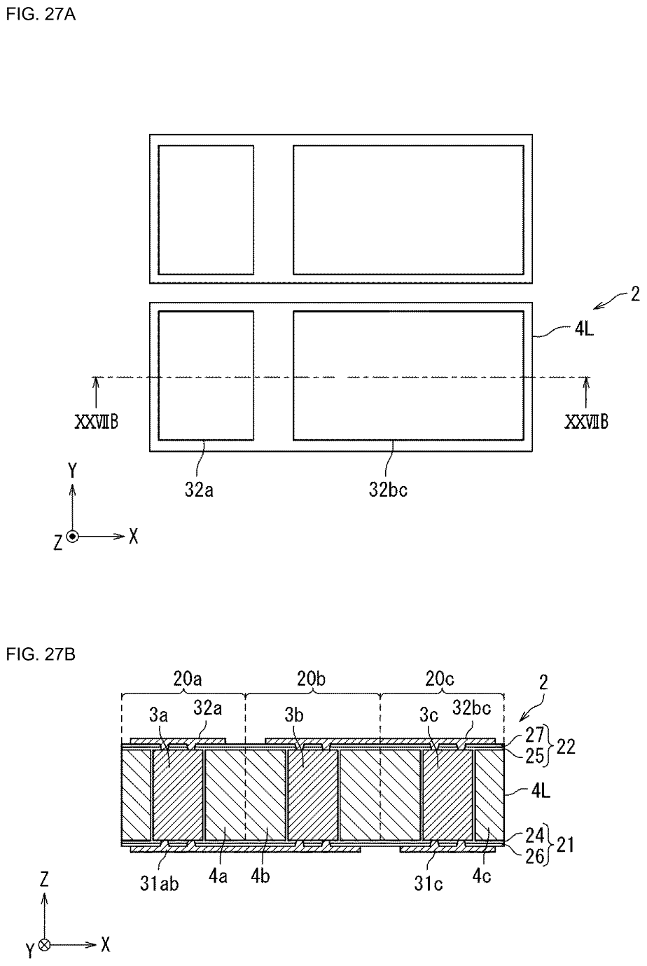

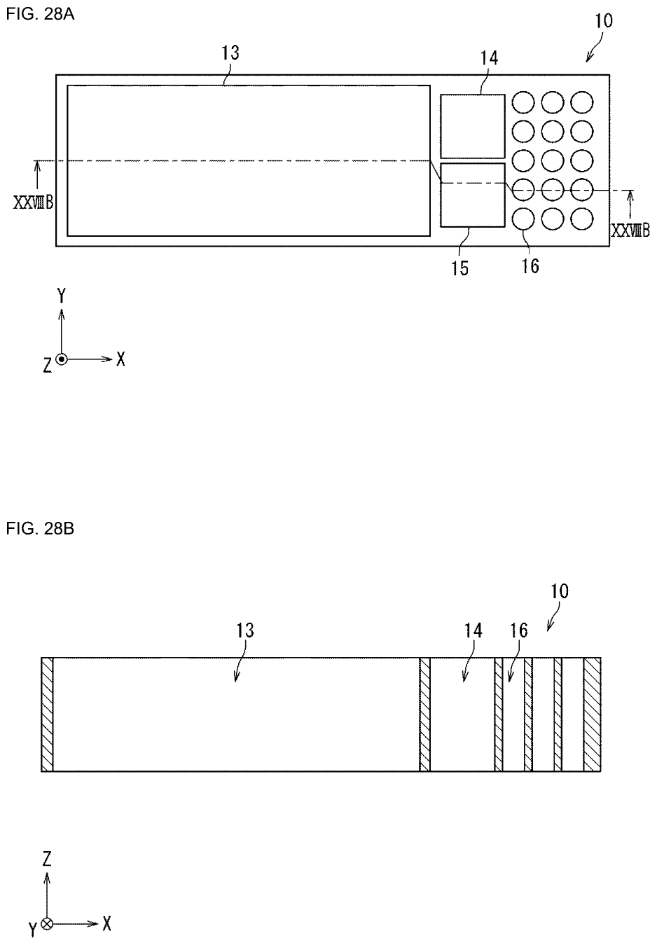

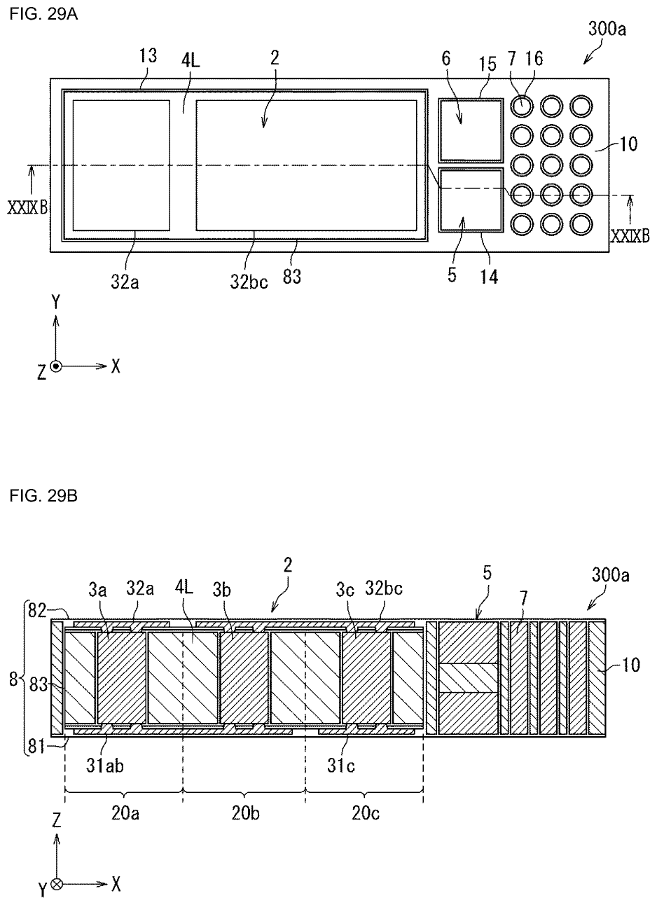

FIG. 26A and FIG. 27A are schematic process top view each illustrating the method for manufacturing the inductor unit cells. FIG. 28A and FIG. 29A are schematic process top view each illustrating the method for manufacturing the circuit board (embedding step). FIG. 26B to FIG. 29B are schematic process cross-sectional views taken along line XXVIB-XXVIB to line XXIXB-XXIXB shown in FIG. 26A to FIG. 29A.

First, based on a method similar to the method described with reference to FIG. 7A to FIG. 12B, the conductor layers 312 and 322 are formed, and the conductor layers 312 and 322 are patterned. In this exemplary embodiment, as shown in FIG. 26A and FIG. 26B, the single first electrode 31ab connected to the conductors 3a and 3b and the first electrode 31c connected to the conductor 3c are formed from the conductor layer 312. Moreover, the second electrode 32a connected to the conductor 3a and the second electrode 32bc connected to the conductors 3b and 3c are formed from the conductor layer 322. Subsequently, as shown in FIG. 27A and FIG. 27B, the magnetic body block 40 is cut. In this case, the magnetic body layer 4L is cut out in such a manner as to include the conductors 3a to 3c and the magnetic bodies 4a to 4c therearound. Accordingly, the inductor 2 including the inductor unit cells 20a to 20c is obtained.

Then, as shown in FIG. 28A and FIG. 28B, the substrate 10 having the single through-hole 13 in the inductor placement region is prepared. Subsequently, as shown in FIG. 29A and FIG. 29B, the inductor 2 obtained based on the above-described method is disposed within the through-hole 13. Predetermined components are also respectively disposed in the through-holes 14 to 16, and are sealed by the seal member 8. Subsequent steps are similar to those in the first exemplary embodiment.

### Technical Effects

In the circuit board 1 according to this exemplary embodiment, the magnetic bodies 4a to 4c of the multiple inductor unit cells 20a to 20c are integrally formed, so that the area of the inductor formation region of the substrate 10 can be reduced. Consequently, the circuit board 1 can be reduced in size.

Furthermore, the first electrodes of the inductor unit cells 20a and 20b are integrally formed, and the second electrodes of the inductor unit cells 20b and 20c are integrally formed, so that the connection resistance between the inductor unit cells can be reduced. Consequently, the direct-current resistance of the inductor 2 can be reduced. As a result, a circuit resistance loss can be further reduced.

Although the three inductor unit cells 20a to 20c are integrally formed in the example shown in FIG. 25A to FIG. 25C, two of the inductor unit cells may be integrally formed. Moreover, three of more inductor unit cells may be integrally formed.

In this exemplary embodiment, each of the inductor unit cells 20a to 20c may have two or more parallel-connected conductors. Furthermore, by connecting the conductors 3a to 3c in parallel, three inductors may be formed from the conductors 3a to 3c and the magnetic bodies 4a to 4c.

### Third Exemplary Embodiment

### (Underlying Knowledge Forming Basis)

It is desirable to reduce the area of a circuit board having embedded therein a component, such as a vertical inductor. The “area of a circuit board” refers to the area when viewed in the thickness direction of the board. For example, when two or more vertical inductors are embedded, the area of the circuit board tends to increase. In particular, when a single vertical inductor is divided into multiple inductor unit cells that are to be embedded, as in the first exemplary embodiment, the area of the circuit board tends to increase if the number of inductor unit cells (i.e., the number of conductors connected in series to form one inductor) increases. Furthermore, when conductors constituting other components, such as a transformer component utilizing magnetic coupling between conductors, are to be embedded in addition to the conductors constituting the inductor, the area of the circuit board may increase.

In view of this, an exemplary aspect provides a configuration that enables further size reduction by suppressing an increase in the area of the circuit board having multiple conductors embedded therein. As a result, new knowledge is obtained in which size reduction of the circuit board can be achieved by disposing multiple conductors spaced apart from each other in a single through-hole provided in a substrate. The following exemplary embodiment is based on this new knowledge.

### [Overall Configuration of Circuit Board]

Similar to the first exemplary embodiment, the circuit board according to this exemplary embodiment includes a first wiring structure, a second wiring structure, and a component-embedded substrate located between these wiring structures. The component-embedded substrate includes at least one conductor containing section between the first wiring structure and the second wiring structure. The “conductor containing section” includes a substrate and multiple conductors disposed within a through-hole in the substrate. The conductors disposed in the through-hole may each be a conductor that forms a component such as an inductor. The substrate provided with the through-hole may be, for example, a substrate (e.g., a magnetic body substrate or a magnetic body layer) disposed inside a core substrate.

### [Configuration of Conductor Containing Section]

An example of the conductor containing section in the circuit board according to this exemplary embodiment will be described below with reference to the drawings. In the following example, the conductor containing section forms an inductor component.

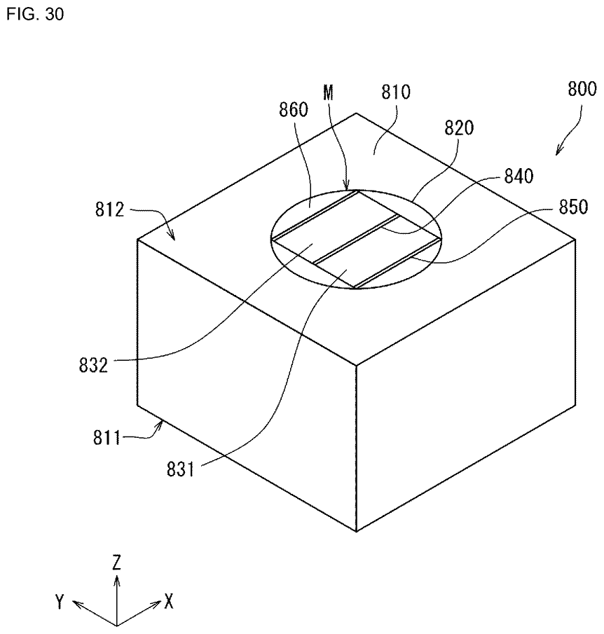

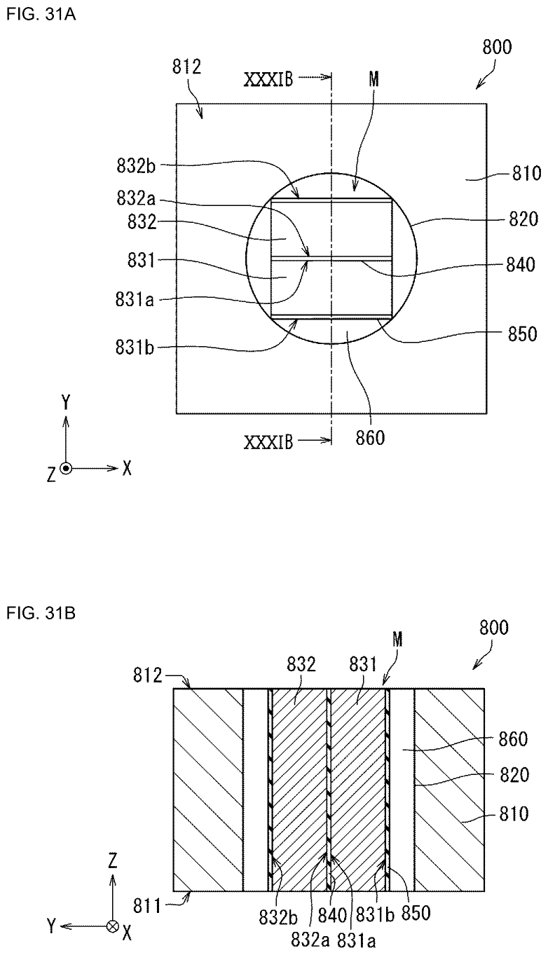

FIG. 30 is a schematic perspective view of the conductor containing section in the circuit board according to the third exemplary embodiment. FIG. 31A is a schematic top view of the conductor containing section in FIG. 30. FIG. 31B is a schematic cross-sectional view taken along line XXXIB-XXXIB in FIG. 31A.

A conductor containing section 800 includes a substrate 810, conductors 831 and 832, and an isolation insulation layer 840. In this example, the substrate 810 is a magnetic body.

The substrate 810 has a first surface 811 and a second surface 812 located opposite the first surface 811 in the thickness direction (Z direction). Although not shown, a first wiring layer is disposed at the first surface 811, and a second wiring layer is disposed at the second surface 812. The substrate 810 has a through-hole 820 extending in the thickness direction. In the example shown, the substrate 810 has, for example, a quadrilateral prismatic shape (in this case, a rectangular parallelepiped shape). The through-hole 820 has, for example, a cylindrical shape.

In a plan view as viewed in the Z direction (sometimes abbreviated as “plan view” hereinafter), the conductors 831 and 832 are spaced apart from each other within the through-hole 820. The conductors 831 and 832 each extend in the Z direction. End portions (first end portions) at the first surface 811 side of the conductors 831 and 832 are electrically connected to corresponding electrodes within the first wiring layer. End portions (second end portions) at the second surface 812 side of the conductors 831 and 832 are electrically connected to corresponding electrodes within the second wiring layer.

In plan view, the isolation insulation layer 840 is located between the conductors 831 and 832. The isolation insulation layer 840 isolates the conductors 831 and 832 from each other within the through-hole 820.

In this description, a structural body M formed of multiple conductors disposed in a single through-hole and an isolation insulation layer for isolating the conductors from each other is referred to as “first structural body”. A detailed structure of the first structural body M will be described later.

An insulation section 860 is disposed between the inner wall of the through-hole 820 and the first structural body M. The insulation section 860 is, for example, a resin member. The insulation section 860 may be disposed to fill in a gap between the inner wall of the through-hole 820 and a side surface of the first structural body M. The insulation section 860 may contain a magnetic material. Accordingly, the inductance of an inductor component using the conductors 831 and 832 in the conductor containing section 800 can be improved.

### (First Structural Body M)

The conductors 831 and 832 of the first structural body M each have a columnar shape extending in the Z direction. The conductors 831 and 832 may each have, for example, a polygonal prismatic shape having a polygonal cross section with an inner angle larger than or equal to 90° and smaller than 180°. In this description, the “cross section of a conductor” refers to a cross section that is orthogonal to the Z direction (i.e., thickness direction of the substrate) in the conductor. Although the conductors 831 and 832 have the same size and the same shape in this example, the conductors 831 and 832 may have different sizes or different shapes (cross-sectional shapes).

In the example shown in FIG. 30 to FIG. 31B, the conductors 831 and 832 each have a quadrilateral prismatic shape having a rectangular cross section. The conductors 831 and 832 are arranged in the Y direction via the isolation insulation layer 840. In this example, the distance between the conductors 831 and 832 is small, and the conductors 831 and 832 are disposed close to each other. The distance between the conductors 831 and 832 (in this case, the length of the isolation insulation layer 840 in the Y direction) is preferably set to a minimum distance at which a sufficient withstand voltage can be ensured with respect to a potential difference occurring between the conductors 831 and 832. Accordingly, the coupling coefficient between the conductors can be increased, and size reduction of the components or the circuit board can be achieved. The distance between the conductors 831 and 832 is, for example, smaller than or equal to 60 μm.

The conductor 831 has a first side surface 831a facing the conductor 832 and a second side surface 831b located opposite the first side surface 831a in the Y direction. Likewise, the conductor 832 has a first side surface 832a facing the conductor 831 and a second side surface 832b located opposite the first side surface 832a in the Y direction. The first side surface 831a of the conductor 831 and the first side surface 832a of the conductor 832 may be adhered to each other by the isolation insulation layer 840.

A side portion of each of the conductors 831 and 832 may at least partially be covered with an insulation layer 850. The “side portion of a conductor” refers to a portion of a conductor surface that is located between an end surface at the first surface side and an end surface at the second surface side. In the example shown, the second side surface 831b of the conductor 831 and the second side surface 832b of the conductor 832 are covered with the insulation layer 850. Side surfaces of the conductors 831 and 832 that extend in the Y direction in plan view do not have to be covered with the insulation layer 850, and may be, for example, directly in contact with the insulation section 860.

In the example shown in FIG. 30 to FIG. 31B, the first structural body M has a quadrilateral prismatic shape. In plan view, the first structural body M has a quadrilateral shape that is slightly smaller than a quadrilateral inscribing a circular opening of the through-hole 820. With this configuration, when the conductor containing section 800 is to be manufactured, the separately-formed first structural body M can be disposed within the through-hole 820 in the substrate 810 more readily.

### Technical Effects

The circuit board according to this exemplary embodiment includes the substrate 810 having the through-hole 820 extending in the thickness direction (Z direction), the conductors 831 and 832 disposed in the through-hole 820 and extending in the Z direction, and the isolation insulation layer 840 that isolates the conductors 831 and 832 from each other within the through-hole 820. With this configuration, the area of the circuit board can be reduced when viewed in the Z direction, as compared with a case where a through-hole is provided for each conductor. Thus, size reduction of the circuit board can be achieved.

In the circuit board according to this exemplary embodiment, the conductors 831 and 832 are electrically isolated from each other. For example, the first end portions of the conductors 831 and 832 may be electrically connected to different electrodes on the first surface 811, and the second end portions of the conductors 831 and 832 may be electrically connected to different electrodes on the second surface 812. Accordingly, the conductors 831 and 832 can serve as portions of components different from each other.

The circuit board according to this exemplary embodiment may include, for example, a first inductor and a second inductor that can operate independently of each other. In this case, the first inductor may include the conductor 831, and the second inductor may include the conductor 832.

The first inductor and the second inductor may be formed of a single conductor containing section 800, or may be formed of multiple conductor containing sections 800, as will be described later. In the case where the first inductor and the second inductor are formed of multiple conductor containing sections 800, the conductors 831 in the multiple conductor containing sections 800 may be connected in series to form the first inductor, and the conductors 832 may be connected in series to form the second inductor. With this configuration, the conductors of the vertical inductors can be disposed in a divided fashion, so that the circuit board can be made thinner. In addition, with two or more conductors 831 and 832 disposed in a single through-hole, the area of the circuit board can be reduced. Consequently, further size reduction of the circuit board can be achieved.

The conductors 831 and 832 may be electrically connected to each other. For example, the first end portions of the conductors 831 and 832 may be connected to each other by an electrode disposed at the first surface 811, and the second end portions of the conductors 831 and 832 may be connected to each other by an electrode disposed at the second surface 812.

### Modification 1

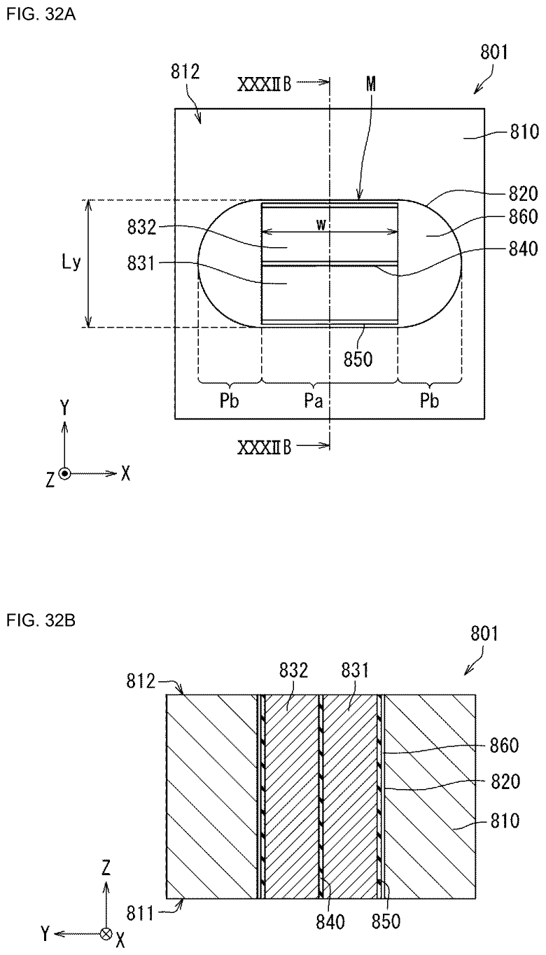

FIG. 32A is a schematic top view of Modification 1 of the conductor containing section. FIG. 32B is a schematic cross-sectional view taken along line XXXIIB-XXXIIB in FIG. 32A.

A conductor containing section 801 according to Modification 1 shown in FIG. 32A and FIG. 32B is different from the conductor containing section 800 shown in FIG. 31A and FIG. 31B in that, in a plan view as viewed in the Z direction, the through-hole 820 is not circular but has a shape that is long in one direction (in this example, the X direction).

In this modification, the opening shape of the through-hole 820 is a track-like shape (oval shape) that is long in the X direction. The “opening shape of the through-hole” refers to a shape when the columnar through-hole is viewed from the Z direction, and is the shape of the opening located in the first surface 811 and the second surface 812 of the substrate 810. The “track-like shape” refers to a shape in which the two short edges of a rectangle are replaced by outward-protruding partial circles or semicircles, as in a racetrack shape, and a shape resembling this shape. Such a through-hole 820 is formed of a quadrilateral prismatic region Pa having a quadrilateral prismatic shape and two partially-circular prismatic regions Pb having a partially-circular prismatic shape and located at the opposite sides of the quadrilateral prismatic region Pa in the Y direction. In plan view, the quadrilateral prismatic region Pa and the partially-circular prismatic regions Pb respectively correspond to a quadrilateral portion located in the middle of the track-like shape and two partially-circular portions located at the opposite sides thereof.

In the example shown in FIG. 32A and FIG. 32B, in plan view, the first structural body M and the through-hole 820 each have a shape that is long in one direction (X direction). In plan view, a maximum length Ly of the through-hole 820 in the transverse direction (Y direction) may be smaller than a maximum length w of the first structural body M in the longitudinal direction. Accordingly, when the conductor containing section 801 is to be manufactured, the first structural body M can be disposed in a predetermined orientation within the through-hole 820. In detail, the first structural body M is disposed in the through-hole 820 in an orientation in which the longitudinal directions of the through-hole 820 and the first structural body M are aligned or substantially aligned in plan view. In this example, the first structural body M is disposed in the through-hole 820 such that the conductors 831 and 832 are arranged in the Y direction (i.e., the conductor 831 is located at the −Y side or the +Y side of the conductor 832).

For example, a first structural body M1 is disposed inside the quadrilateral prismatic region Pa of the through-hole 820. In plan view, the first structural body M may have a rectangular shape that is slightly smaller than the quadrilateral prismatic region Pa of the through-hole 820. The length of the through-hole 820 in the Y direction is at maximum (length Ly) in the quadrilateral prismatic region Pa, and decreases with increasing distance from the quadrilateral prismatic region Pa in the X direction. Therefore, in plan view, the position of the first structural body M in the through-hole 820 is less likely to be displaced from the quadrilateral prismatic region Pa so long as the first structural body M has a shape that is slightly smaller than the quadrilateral prismatic region Pa.

The conductors 831 and 832 may have the same shape and the same size. The first structural body M may be point symmetrical with respect to a point, as a symmetry center, located at the center of the isolation insulation layer 840 in a plan view as viewed in the Z direction. With this configuration, even when the conductors 831 and 832 are vertically inverted (i.e., the conductor 831 is disposed at the +Y side of the conductor 832) by being rotated by 180° from the orientation shown in FIG. 32A, the conductor containing section 801 obtained can have substantially the same structure and function as in FIG. 32A.

In the circuit configuration according to Modification 1, the through-hole 820 has the opening shape that is long in one direction, so that when the first structural body M is to be disposed in the through-hole 820 during the manufacturing process of the conductor containing section 801, the orientation of the first structural body M relative to the through-hole 820 is determined. Therefore, the conductors 831 and 832 can be readily disposed at predetermined positions. As a result, the conductors 831 and 832 can be connected to predetermined electrodes within the wiring layers more reliably. Consequently, the circuit board can be manufactured more readily.

Furthermore, in Modification 1, the conductors 831 and 832 that have a polygonal prismatic shape are disposed in the through-hole 820 having the track-like-shaped opening. Thus, the cross-sectional area of each of the conductors 831 and 832 can be increased, as compared with when the opening is circular. Consequently, the electrical resistance of each of the conductors 831 and 832 can be reduced while an increase in the area of the circuit board can be suppressed.

### Modification 2

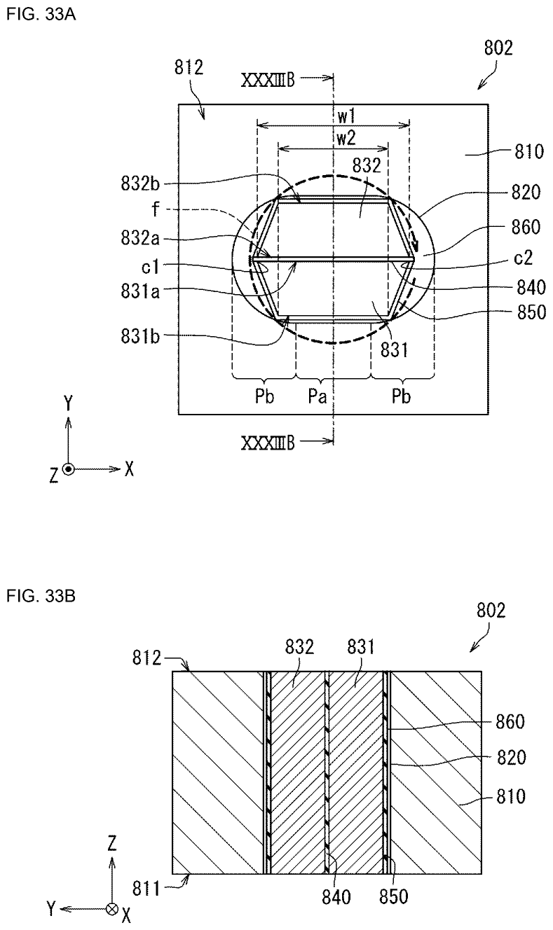

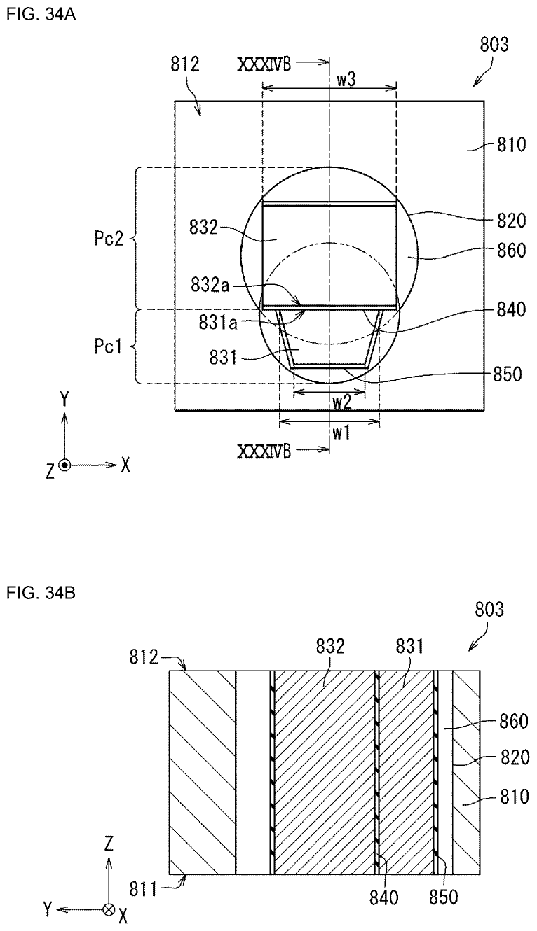

FIG. 33A is a schematic top view of Modification 2 of the conductor containing section. FIG. 33B is a schematic cross-sectional view taken along line XXXIIIB-XXXIIIB in FIG. 33A.

A conductor containing section 802 according to Modification 2 shown in FIG. 33A and FIG. 33B is different from the conductor containing section 801 shown in FIG. 32A and FIG. 32B in terms of the cross-sectional shape of each of the conductors 831 and 832. The opening shape of the through-hole 820 in the conductor containing section 802 is a track-like shape.

In the conductor containing section 802, the conductor 831 is formed such that the width of the conductor 831 in the X direction decreases with increasing distance from the conductor 832 in the Y direction. A width w1, in the X direction, of a portion of the conductor 831 that is closest to the conductor 832 is larger than a width w2, in the X direction, of a portion farthest from the conductor 832. The width w1 is, for example, a length of the first side surface 831a in the X direction, and the width w2 is, for example, a length of the second side surface 831b in the X direction. Similar to the conductor 831, the conductor 832 is formed such that the width of the conductor 832 in the X direction decreases with increasing distance from the conductor 831 in the Y direction.

The conductors 831 and 832 may each have a polygonal prismatic shape (in this case, a quadrilateral prismatic shape). In plan view, each of the conductors 831 and 832 may have a polygonal shape with a first edge located at the isolation insulation layer 840 side and second edges adjacent to the first edge, and angles c1 and c2 between the first and second edges may be acute angles. In the example shown in FIG. 33A and FIG. 33B, each of the conductors 831 and 832 has a trapezoidal shape in plan view, the aforementioned first edge is the lower base of the trapezoid, and the second edges are the legs of the trapezoid. The conductors 831 and 832 form the first structural body M substantially having a hexagonal prismatic shape.

The first structural body M is disposed in the through-hole 820 such that the longitudinal directions of the first structural body M and the through-hole 820 are substantially aligned in plan view. The maximum width w1 of the first structural body M in the X direction is larger than the length of the quadrilateral prismatic region Pa of the through-hole 820 in the X direction. Therefore, as shown in FIG. 33A, in plan view, the first structural body M extends from the quadrilateral prismatic region Pa into the partially-circular prismatic regions Pb at the opposite sides thereof.

A side portion of each of the conductors 831 and 832 may at least partially be covered with the insulation layer 850. In the example shown, side portions excluding the first side surfaces 831a and 832b of the conductors 831 and 832 are entirely covered with the insulation layer 850.

In the circuit board according to Modification 2, at least one of (in this case, each of) the conductors 831 and 832 is formed such that the width in the X direction thereof decreases with increasing distance from the other conductor in the Y direction. Accordingly, a magnetic field f occurring around the conductors 831 and 832 is less likely to be blocked at the corners of the conductors 831 and 832 and can readily rotate.

Furthermore, in the circuit board according to Modification 2, the first structural body M protrudes from the quadrilateral prismatic region Pa and extends to the partially-circular prismatic regions Pb. Therefore, in plan view, the percentage of the area of the first structural body M occupying the through-hole 820 can be increased relative to that in, for example, Modification 1. Hence, while an increase in the area of the circuit board is suppressed, the cross-sectional area of each of the conductors 831 and 832 is increased, so that the electrical resistance can be further reduced. Moreover, since the gap between the inner wall of the through-hole 820 and the first structural body M can be made smaller, the volume of the insulation section 860 filled around the conductors 831 and 832 can be reduced. As a result, the inductance can be further enhanced.

### Modification 3

FIG. 34A is a schematic top view of Modification 3 of the conductor containing section. FIG. 34B is a schematic cross-sectional view taken along line XXXIVB-XXXIVB in FIG. 34A.

A conductor containing section 803 according to Modification 3 shown in FIG. 34A and FIG. 34B is different from the conductor containing sections 800 to 802 described above in that the conductors 831 and 832 have different shapes in plan view. In this modification, the first structural body M and the through-hole 820 each have an asymmetrical shape in plan view.

Similar to the conductor 831 according to Modification 2 shown in FIG. 33A and FIG. 33B, the conductor 831 has a columnar (in this case, quadrilateral prismatic) shape and is formed such that the width thereof in the X direction decreases with increasing distance from the conductor 832. Similar to the conductor 831 shown in FIG. 31A and FIG. 31B, the conductor 832 has a quadrilateral prismatic shape having a rectangular cross section. The cross-sectional area of the conductor 832 is larger than the cross-sectional area of the conductor 831. In the through-hole 820, the first side surface 831a of the conductor 831 and the first side surface 832a of the conductor 832 face each other via the isolation insulation layer 840 in the Y direction. A width w3 (in this case, the length of the first side surface 832a) in the X direction of the conductor 832 is larger than the maximum width w1 (in this case, the length of the first side surface 831a in the X direction) of the conductor 831 in the X direction.

The through-hole 820 has a structure in which two cylindrical holes (referred to as “first hole” and “second hole” hereinafter) extending through the substrate 810 in the Z direction are disposed to partially overlap each other. The through-hole 820 has a first region Pc1 defined by the inner wall of the first hole and a second region Pc2 defined by the inner wall of the second hole.

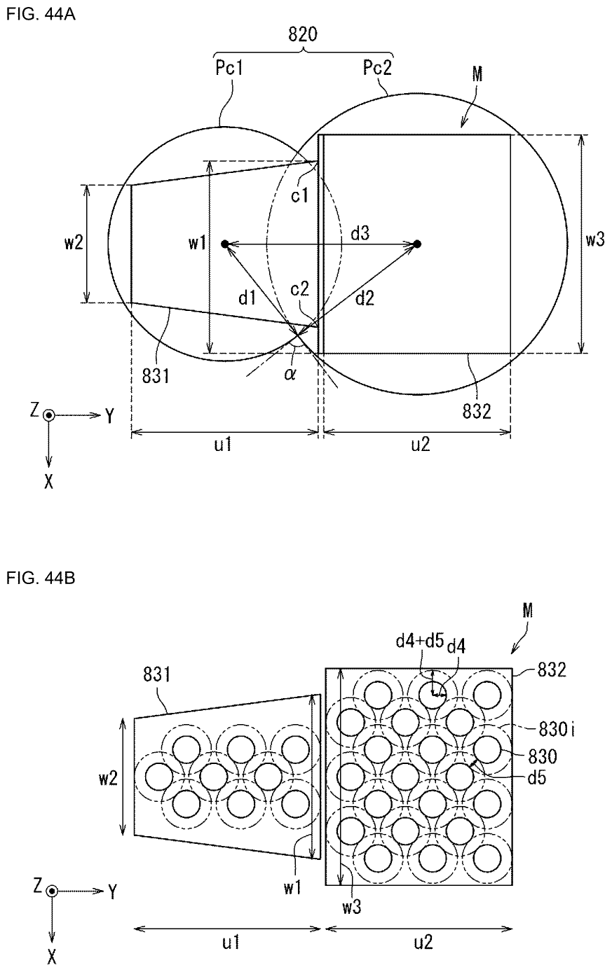

In the example shown in FIG. 34A and FIG. 34B, the second hole has a larger radius than the first hole. In plan view, the area of the second region Pc2 is larger than that of the first region Pc1. The conductor 832 is located, for example, inside the second region Pc2. In plan view, the conductor 832 may have a quadrilateral shape that is slightly smaller than a quadrilateral inscribing the second region Pc2 that is partially-circular. At least a portion of the conductor 831 is located inside the first region Pc1. The conductor 831 may extend from the first region Pc1 to the second region Pc2. A method for designing the through-hole 820 and the conductors 831 and 832 according to this modification will be described later with reference to FIG. 44A.

In the circuit board according to Modification 3, in plan view, the through-hole 820 has an asymmetrical shape, and the first structural body M also has an asymmetrical shape corresponding to the through-hole 820. With this configuration, the orientation of the first structural body M disposed in the through-hole 820 is uniquely determined. Therefore, the conductors 831 and 832 can be readily disposed at predetermined positions. As a result, the conductors 831 and 832 can be connected to predetermined electrodes within the wiring layers more reliably. Consequently, the circuit board can be manufactured more readily.

Furthermore, due to the conductors 831 and 832 having different cross-sectional areas, the circuit board according to Modification 3 is advantageous when the conductors 831 and 832 have different current ratios. For example, by disposing the conductor 832 with the larger cross-sectional area on a line through which the larger electric current flows, the electrical resistance of the line can be further reduced.

Moreover, in Modification 3, the conductor 831 is formed such that the width in the X direction decreases with increasing distance from the conductor 832. Accordingly, a magnetic field occurring around the conductors 831 and 832 is less likely to be blocked by the conductor 831, so that the inductance can be enhanced.

Furthermore, in Modification 3, the through-hole 820 has a structure in which the two cylindrical holes corresponding to the conductors 831 and 832 are disposed to partially overlap each other, and the magnetic field (magnetic flux) occurring around the conductors 831 and 832 can readily travel through the magnetic body (substrate 810). Thus, the inductance can be further enhanced.

### Modification 4

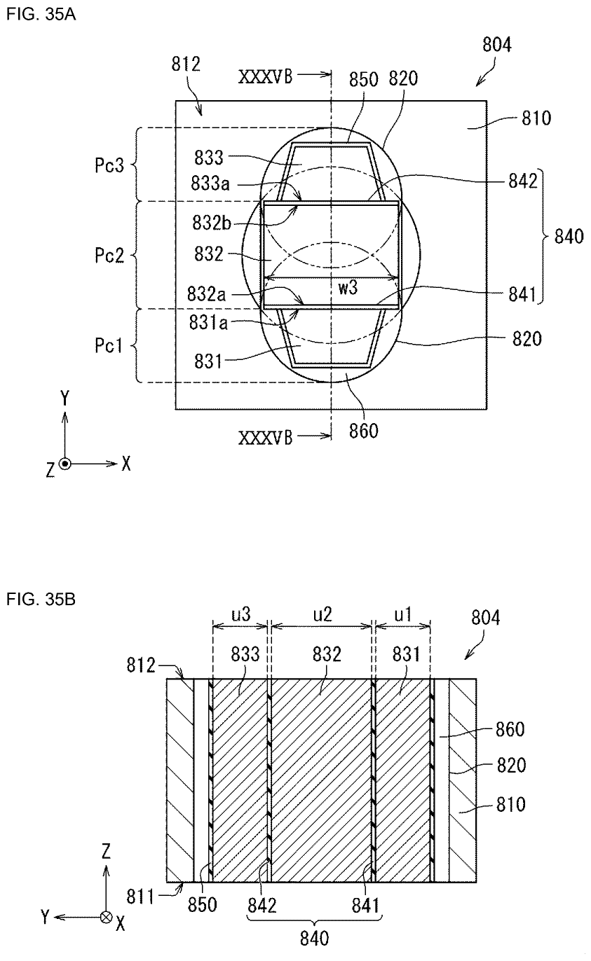

FIG. 35A is a schematic top view of Modification 4 of the conductor containing section. FIG. 35B is a schematic cross-sectional view taken along line XXXVB-XXXVB in FIG. 35A.

A conductor containing section 804 according to Modification 4 shown in FIG. 35A and FIG. 35B is different from the first structural body M according to Modification 3 shown in FIG. 34A and FIG. 34B in being equipped with three conductors 831 to 833 disposed in the through-hole 820 of the substrate 810.

In the conductor containing section 804, the conductor 833 is disposed opposite the conductor 831 across the conductor 832 in the through-hole 820. For example, the conductors 831 to 833 are arranged in this order in the Y direction within the through-hole 820.

The isolation insulation layer 840 includes a first isolation insulation layer 841 located between the conductor 831 and the conductor 832, and a second isolation insulation layer 842 located between the conductor 832 and the conductor 833.

In the example shown, the conductor 833 has a polygonal prismatic shape (in this case, a quadrilateral prismatic shape). Of side surfaces of the conductor 833, a first side surface 833a located at the conductor 832 side faces the second side surface 832b of the conductor 832 in the Y direction via the second isolation insulation layer 842.

The conductor 832 may have a shape similar to that of the conductor 833. As shown in the drawing, the width of the conductor 833 in the X direction may be decrease with increasing distance from the conductor 831. A maximum width of the conductor 833 in the X direction (in this case, the length of the first side surface 833a in the X direction) may be smaller than the width w3 of the conductor 832 in the X direction and, for example, equal to the width of the conductor 831 in the X direction.

A length u2 of the conductor 832 in the Y direction may be larger than lengths u1 and u3 of the conductors 831 and 833 in the Y direction. With this configuration, larger electric current can be made to flow through the conductor 831 having the large cross-sectional area. As an example, the length u2 of the conductor 832 in the Y direction may be 0.8 mm, and the lengths u1 and u3 of the conductors 831 and 833 in the Y direction may be 0.2 mm.

The through-hole 820 has a structure in which three cylindrical holes (referred to as “first hole”, “second hole”, and “third hole”) extending through the substrate 810 in the Z direction are disposed to partially overlap. In this example, the through-hole 820 has a structure in which the first hole is disposed to partially overlap one end portion of the second hole in the Y direction and the third hole is disposed to partially overlap the other end portion of the second hole. The through-hole 820 has the first region Pc1 defined by the inner wall of the first hole, a third region Pc3 defined by the inner wall of the third hole, and the second region Pc2 located between the first region Pc1 and the third region Pc3 and defined by the inner wall of the second hole.

In the example shown in FIG. 35A and FIG. 35B, the radius of the second hole is larger than the radii of the first hole and the third hole. Therefore, a maximum width of the second region Pc2 in the X direction is larger than maximum widths of the first region Pc1 and the third region Pc3 in the X direction. In plan view, the area of the second region Pc2 may be larger than those of the first region Pc1 and the third region Pc3. The conductor 832 is located inside the second region Pc2. At least a portion of the conductor 831 is located inside the first region Pc1, and at least a portion of the conductor 833 is located inside the third region Pc3.

The through-hole 820 and the first structural body M may each have a shape that is long in one direction (in this case, the Y direction). A maximum length of the through-hole 820 in the transverse direction (X direction) may be smaller than a maximum length of the first structural body M in the longitudinal direction (Y direction). Accordingly, when the conductor containing section 804 is to be manufactured, the first structural body M can be disposed in a predetermined orientation within the through-hole 820. In detail, the first structural body M is disposed in the through-hole 820 in an orientation in which the longitudinal directions of the through-hole 820 and the first structural body M are aligned or substantially aligned in plan view.

The conductors 831 and 833 may be disposed symmetrically at opposite sides of the conductor 832, and the first structural body M may be formed to have a point-symmetrical shape in plan view. Accordingly, even when the first structural body M is disposed in the through-hole 820 in a vertically inverted manner from the example shown in FIG. 35A, the conductor containing section 804 with substantially the same structure may be manufactured.

The first structural body M and the through-hole 820 each have a point-symmetrical shape in plan view in FIG. 35A, but may each have an asymmetrical shape. For example, in plan view, the conductors 831 and 833 may have different shapes, sizes, and/or the like.

In the circuit board according to Modification 4, the three conductors 831 to 833 can be disposed within the single through-hole 820, so that further size reduction of the circuit board can be achieved. Moreover, the cross-sectional areas of the conductors 831 to 833, the connection method, the direction of electric current, and/or the like can be designed in accordance with the intended purpose (such as the magnitude of the electric current). Accordingly, the degree of design freedom can be enhanced.

Furthermore, in the circuit board according to Modification 4, the width of each of the conductors 831 and 833 in the X direction decreases with increasing distance from the conductor 832 located in the middle. With this configuration, a magnetic field occurring around the conductors 831 to 833 is less likely to be blocked by the conductors 831 and 833. Moreover, in Modification 4, the through-hole 820 has a structure in which the three cylindrical holes corresponding to the conductors 831 to 833 are disposed to partially overlap, and the magnetic field (magnetic flux) occurring around the conductors 831 to 833 can readily travel through the magnetic body (substrate 810). Thus, the inductance can be further enhanced.

Furthermore, in the circuit board according to Modification 4, in plan view, the conductors 831 and 833 are disposed close to the conductor 832 at one end and the other end, respectively, of the conductor 832 in the Y direction. With this configuration, magnetic coupling can be readily formed between two or three conductors formed of the conductors 831 to 833.

### Modification 5

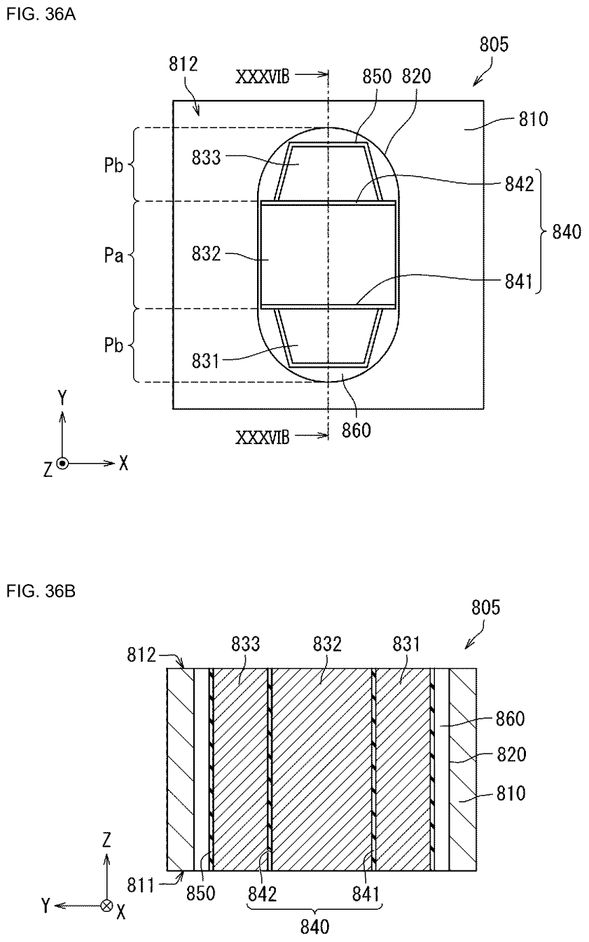

FIG. 36A is a schematic top view of Modification 5 of the conductor containing section. FIG. 36B is a schematic cross-sectional view taken along line XXXVIB-XXXVIB in FIG. 36A.

A conductor containing section 805 according to Modification 5 shown in FIG. 36A and FIG. 36B is different from the conductor containing section 804 according to Modification 4 shown in FIG. 35A and FIG. 35B in that the through-hole 820 in the substrate 810 has a track-like shape that is long in the Y direction.

In the example shown, the conductor 832 is disposed in the quadrilateral prismatic region Pa of the through-hole 820. In plan view, the conductor 831 has a rectangular shape that is slightly smaller than the quadrilateral prismatic region Pa. The conductors 831 and 833 are respectively disposed in the partially-circular prismatic regions Pb of the through-hole 820. The conductors 831 and 833 may at least partially be disposed in the respective partially-circular prismatic regions Pb.

Modification 5 is similar to Modification 4 in that a magnetic field occurring around the conductors 831 to 833 is less likely to be blocked by the conductors 831 and 833.

Furthermore, according to Modification 5, the opening of the through-hole 820 can be made smaller than that in Modification 4. Therefore, the area of the circuit board can be further reduced. Moreover, since the gap between the first structural body M and the inner wall of the through-hole 820 can be made smaller, a substrate 4 serving as a magnetic body and the conductor 831 can be brought closer to each other. Furthermore, because the conductors 831 to 833 are disposed close to one another within the through-hole 820 having the track-like-shaped opening, stronger magnetic coupling can be formed between two or three conductors formed of the conductors 831 to 833.

### [Configuration of Circuit Board]

In the circuit board according to this exemplary embodiment, the number of conductors in each conductor containing section, the connection method of the conductors, the direction of electric current, and/or the like can be freely combined. Such combination examples are indicated in Table 1.

TABLE 1

| | | | | | | | | | | Direction |
|---|---|---|---|---|---|---|---|---|---|---|
| | | | | | | | | | | of magnetic |
| | Number | | Potential of conductor | | | Direction of electric current | | | | field |
| Configuration | of | Electrical | First | Second | Third | Parallel/ | First | Second | Third | Same/ |
| example | conductors | isolation | conductor | conductor | conductor | antiparallel | conductor | conductor | conductor | opposite |
| (1) | 2 | No | V1 | V1 | | — | | | | — |
| | | isolation | | | | | | | | |
| (2) | 2 | 2 | V1 | V2 | | Antiparallel | ↑ | ↓ | | Opposite |
| (3) | 2 | 2 | V1 | V2 | | Parallel | ↑ | ↑ | | Same |
| (4) | 3 | No | V1 | V1 | V1 | — | | | | — |
| | | isolation | | | | | | | | |
| (5) | 3 | 2 | V1 | V1 | V2 | Antiparallel | ↑ | ↑ | ↓ | Opposite |
| (6) | 3 | 2 | V1 | V1 | V2 | Parallel | ↑ | ↑ | ↑ | Same |
| (7) | 3 | 2 | V1 | V2 | V1 | Antiparallel | ↑ | ↓ | ↑ | Opposite |
| (8) | 3 | 2 | V1 | V2 | V1 | Parallel | ↑ | ↑ | ↑ | Same |
| (9) | 3 | 3 | V1 | V2 | V3 | Parallel | ↑ | ↑ | ↑ | Same |
| (10) | 3 | 3 | V1 | V2 | V3 | Antiparallel | ↑ | ↑ | ↓ | Same- |
| | | | | | | | | | | opposite |
| (11) | 3 | 3 | V1 | V2 | V3 | Antiparallel | ↑ | ↓ | ↑ | Same- |
| | | | | | | | | | | opposite |

In Table 1, the “number of conductors” indicates the number of conductors disposed in one through-hole. The “electrical isolation” indicates the number of electrically-isolated conductors disposed in one through-hole. The “potential of conductor” indicates the potential of each of the conductors disposed in one through-hole. The potential varies between conductors that are electrically isolated from each other. The “direction of electric current” indicates the direction of electric current in each of the conductors disposed in one through-hole, and two directions extending in the Z direction are each indicated by an arrow. In Table 1, “parallel” refers to a case where the direction of electric current is the same (i.e., parallel) in all of multiple conductors that are disposed within one through-hole and that are electrically isolated from each other. In contrast, “antiparallel” refers to a case where electric currents flow in opposite directions (antiparallel) through two conductors that are disposed within one through-hole and that are electrically isolated from each other. The “direction of magnetic field” indicates the relationship between the directions of magnetic fields occurring around the respective conductors. The term “same” corresponds to a case where the directions of magnetic fields around the conductors are the same, whereas the term “opposite” corresponds to a case where the directions of magnetic fields around the conductors are opposite (reverse) to each other. In Table 1, when three conductors are arranged in one through-hole, the conductor in the middle in the arrangement direction (e.g., the Y direction) is defined as “second conductor”, and the conductors at the opposite ends are respectively defined as “first conductor” and “third conductor”.

With regard to the conductors according to this exemplary embodiment, one cylindrical conductor (one conductor within each inductor unit cell) in the first exemplary embodiment may be regarded as each of multiple-divided parts in the Z direction. In this case, the “number of conductors” indicates how many physically-divided parts are obtained from one cylindrical conductor in the first exemplary embodiment. Furthermore, the “electrical isolation” indicates how many electrically-divided parts are obtained from one cylindrical conductor in the first exemplary embodiment.

The conductor containing sections 800 to 804 shown in FIG. 30 to FIG. 33B each contain two conductors, and may thus be applied to each of circuit boards according to Configuration Examples (1) to (3). The conductor containing sections 805 and 806 shown in FIG. 34A to FIG. 35B each contain three conductors, and may thus be applied to each of circuit boards according to Configuration Examples (4) to (11).

In the circuit board according to this exemplary embodiment, one or more components (e.g., inductors) can be formed by using a conductor containing section. With regard to the circuit board according to each of Configuration Examples (2), (3), and (5) indicated in Table 1, an example of an inductor configuration using a conductor containing section and an example of a circuit configuration will now be described.

### Configuration Example (2)

### <Inductor Configuration>

The circuit board according to Configuration Example (2) includes, for example, multiple conductor containing sections, multiple first electrodes disposed at the first surface side of the multiple conductor containing sections, and multiple second electrodes disposed at the second surface side. Accordingly, two inductors are formed. In each conductor containing section, electric currents flow in opposite directions (antiparallel) in the Z direction through two conductors disposed within one through-hole.

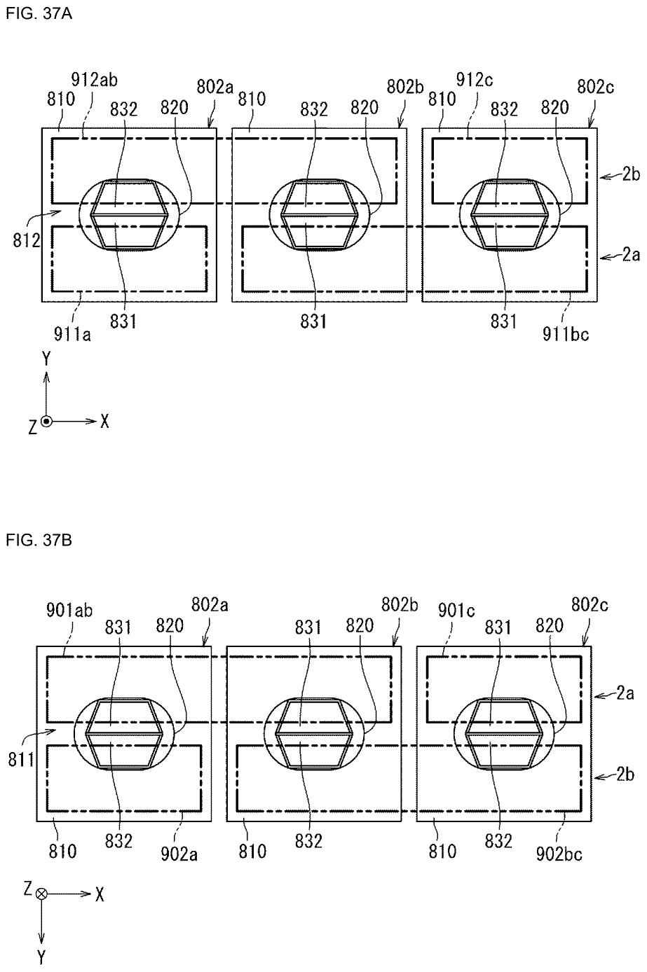

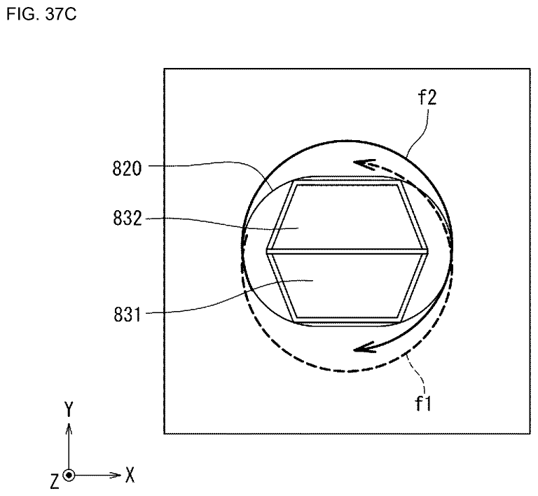

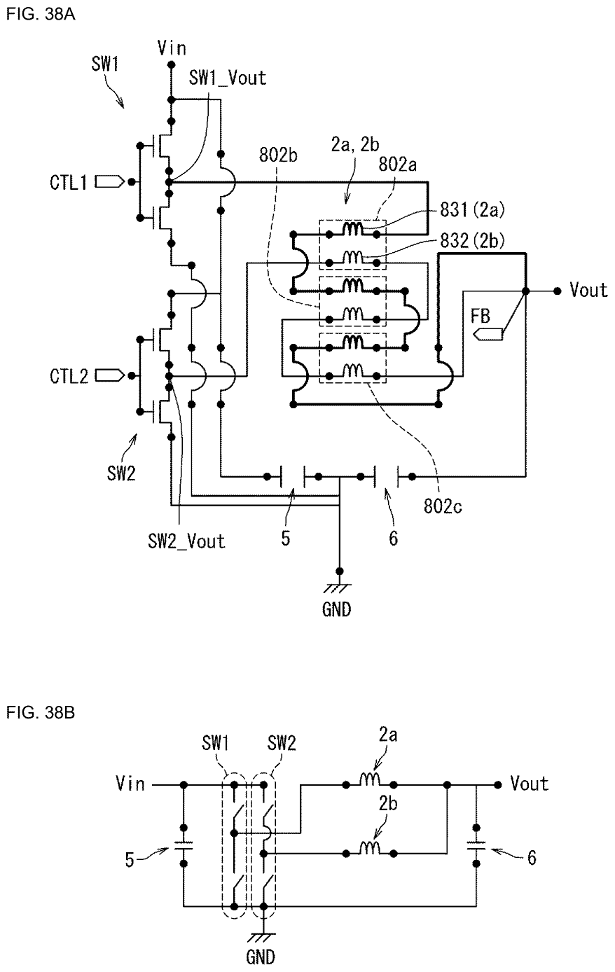

FIG. 37A is a top see-through view schematically illustrating the conductor containing sections and the second electrodes according to Configuration Example (2). FIG. 37B is a bottom see-through view schematically illustrating the conductor containing sections and the first electrodes according to Configuration Example (2). In order to facilitate understanding, the first electrodes and the second electrodes are indicated by double-dot chain lines.

In FIG. 37A and FIG. 37B, multiple (in this case, three) conductor containing sections 802a to 802c are arranged in the circuit board in this order in the X direction. In each of the conductor containing sections 802a to 802c, two conductors 831 and 832 are disposed within the through-hole 820. The conductor 832 is located at the +Y side of the conductor 831.

In this example, each of the conductor containing sections 802a to 802c has a configuration similar to that of the conductor containing section 802 shown in FIG. 33A and FIG. 33B. The configuration of each of these conductor containing sections is not limited to the example shown, and may be, for example, any of those of the conductor containing sections 800 to 804 shown in FIG. 30 to FIG. 33B.

Multiple (in this case, four) first electrodes 901ab, 901c, 902a, and 902bc are provided at the first surface 811 side of the conductor containing sections 802a to 802c. The first electrodes may be disposed within the first wiring layer 110 (FIG. 2) located closest to the first surface 811 in the first wiring structure 100 (FIG. 2). Multiple (in this case, four) second electrodes 911a, 911bc, 912ab, and 912c are provided at the second surface 812 side of the conductor containing sections 802a to 802c. The second electrodes may be disposed within the second wiring layer 210 (FIG. 2) located closest to the second surface 812 in the second wiring structure 200 (FIG. 2).

In each of the conductor containing sections 802a to 802c, the end portions (first end portions) at the first surface 811 side of the conductors 831 and 832 are electrically connected to the corresponding first electrodes, and the end portions (second end portions) at the second surface 812 side are electrically connected to the corresponding second electrodes. The respective end portions of the conductors 831 and 832 may be electrically connected to the corresponding first electrodes or second electrodes via, for example, via conductors. Another electrode (i.e., an electrode corresponding to the electrode 31 or 32 in the above exemplary embodiment) may be interposed between an end portion of each conductor and the corresponding first electrode or second electrode.

In this configuration example, the conductors 831 in the conductor containing sections 802a to 802c are connected in series to form a single inductor 2a. Moreover, the conductors 832 in the conductor containing sections 802a to 802c are connected in series to form a single inductor 2b.

The inductor 2a includes the conductors 831 in the conductor containing sections 802a to 802c, the first electrodes 901ab and 901c, and the second electrodes 911a and 911bc. The second end portion of the conductor 831 in the conductor containing section 802a is connected to the second electrode 911a, and is electrically connected to a predetermined terminal via the second electrode 911a. The first end portions of the conductors 831 in the conductor containing sections 802a and 802b are electrically connected to each other by the first electrode 901ab. The second end portions of the conductors 831 in the conductor containing sections 802b and 802c are electrically connected to each other by the second electrode 911bc. The first end portion of the conductor 831 in the conductor containing section 802c is connected to the first electrode 901c, and is electrically connected to a predetermined terminal via the first electrode 901c.

The inductor 2b includes the conductors 832 in the conductor containing sections 802a to 802c, the first electrodes 902a and 902bc, and the second electrodes 912ab and 912c. The first end portion of the conductor 832 in the conductor containing section 802a is connected to the first electrode 902a, and is electrically connected to a predetermined terminal via the first electrode 902a. The second end portions of the conductors 832 in the conductor containing sections 802a and 802b are electrically connected to each other by the second electrode 912ab. The first end portions of the conductors 832 in the conductor containing sections 802b and 802c are electrically connected to each other by the first electrode 902bc. The second end portion of the conductor 832 in the conductor containing section 802c is connected to the second electrode 912c, and is electrically connected to a predetermined terminal via the second electrode 912c.

In this specification, an electrode that electrically connects two conductors disposed in different through-holes 820 may sometimes be referred to as “connection electrode”. In the example shown, the first electrodes 901ab and 902bc and the second electrodes 911bc and 912ab function as connection electrodes.

In the circuit board according to Configuration Example (2), the conductors 831 and 832 are electrically isolated from each other. With such a configuration, the conductors 831 and 832 can respectively form different components (in this case, the inductors 2a and 2b). Thus, a larger number of components can be embedded while an increase in the area of the circuit board can be suppressed. Furthermore, similar to the first exemplary embodiment, the inductors (vertical inductors) 2a and 2b can be formed by connecting the conductors in the multiple (in this case, three) conductor containing sections 802a to 802c in series. In other words, the conductor containing sections 802a to 802c may function as inductor unit cells. With this configuration, the circuit board can be made thinner.

Furthermore, in the circuit board according to Configuration Example (2), the conductors 831 and 832 are connected to the corresponding electrodes such that the directions of electric currents are antiparallel. Thus, the directions of magnetic fields generated by the conductors 831 and 832 are opposite (reverse) to each other.

FIG. 37C is a schematic enlarged top view illustrating magnetic fields occurring around the conductors 831 and 832. Magnetic fields f1 and f2 shown respectively correspond to a case where electric current flows through the conductor 831 in the +Z direction (i.e., from the first end portion toward the second end portion) and a case where electric current flows through the conductor 832 in the −Z direction (i.e., from the second end portion toward the first end portion). As shown in FIG. 37C, in each conductor containing section, the magnetic field f1 generated around the conductor 831 and the magnetic field f2 generated around the conductor 832 occur in opposite directions (reverse directions) to cancel out each other. As a result, magnetic saturation is less likely to occur. Therefore, deterioration in the inductor characteristics of the inductors formed of the conductors 831 and 832 due to magnetic saturation can be suppressed.

When the conductors 831 and 832 are disposed close to each other within the through-hole 820, the two magnetic fields f1 and f2 become closer to each other so as to cancel out each other more effectively. The amounts of electric currents flowing through the conductors 831 and 832 may be substantially equal to each other. Accordingly, magnetic saturation can be suppressed more effectively.

### <Circuit Configuration>

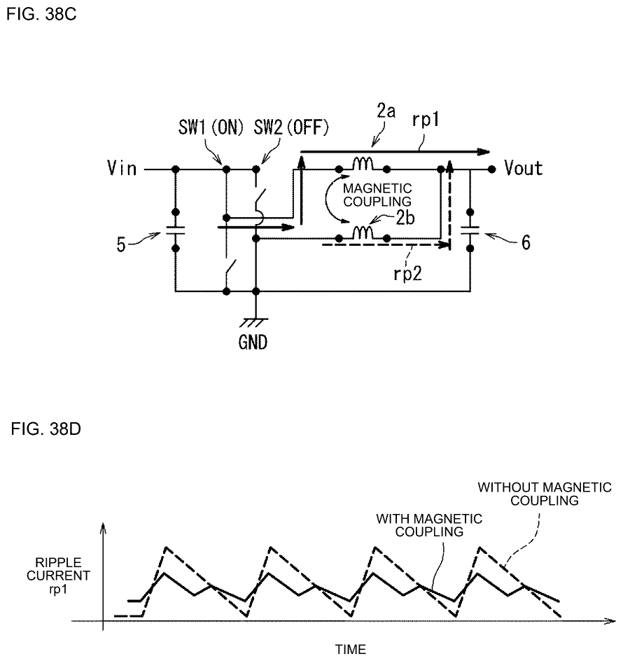

FIG. 38A illustrates an example of a circuit configuration of a voltage regulation module (step-down DC-DC converter) using the circuit board according to Configuration Example (2). FIG. 38B illustrates the circuit configuration shown in FIG. 38A in a simplified form. The voltage regulation module shown in FIG. 38A and FIG. 38B is a DC-DC converter having a plurality of phases (multiple phases).

The DC-DC converter shown in FIG. 38A and FIG. 38B includes the circuit board according to Configuration Example (2) and two switch elements SW1 and SW2. This module has a phase 1 in which the switch element SW1 is turned on and the switch element SW2 is turned off, and a phase 2 in which the switch element SW2 is turned on and the switch element SW1 is turned off.

The inductors 2a and 2b, the input capacitor 5, and the output capacitor 6 constituting a circuit are embedded in the circuit board (component-embedded substrate). The capacitors 5 and 6 may each have a structure similar to that in the first exemplary embodiment described above. Terminal portions, such as the control terminal CTL, the input terminal Vin, the output terminal Vout, and the ground terminal GND, are provided at, for example, the first wiring structure (see FIG. 23A). Terminal lands for terminals (such as SW1_CTL, SW2_CTL, SW1_Vout, SW2_Vout, and SW_GND) of the switch elements SW1 and SW2 are provided at, for example, the second wiring structure (see FIG. 23B).

The inductor 2a is connected between the SW1_Vout terminal of the switch element SW1 and the output terminal Vout. The inductor 2b is connected between the SW2_Vout terminal of the switch element SW2 and the output terminal Vout. For example, each of the inductors 2a and 2b has the structure shown in FIG. 37A and FIG. 37B. In each of the conductor containing sections 802a to 802c, the direction of an electric current flowing through the conductor 831 constituting the inductor 2a and the direction of an electric current flowing through the conductor 832 constituting the inductor 2b are opposite (antiparallel) to each other.

Two conductors in each conductor containing section are preferably disposed close to each other to an extent that magnetic coupling may occur. The reason for this will be described with reference to FIG. 38C and FIG. 38D. FIG. 38C illustrates the phase 1 of the DC-DC converter shown in FIG. 38A and FIG. 38B. FIG. 38D is a schematic graph illustrating waveforms of ripple current occurring in the phase 1 of the DC-DC converter.

As shown in FIG. 38C, in the phase 1, when a ripple current rp1 is generated in the inductor 2a connected to the switch element SW1 in the ON mode, a ripple current rp2 caused by the ripple current rp1 flows through the switch element SW2 via magnetic coupling. These ripple currents rp1 and rp2 occur to reduce the current amplitudes of each other. As a result, as shown in FIG. 38D, by utilizing magnetic coupling, the current amplitudes of the ripple currents rp1 and rp2 occurring in each phase can be suppressed, as compared with a case where magnetic coupling is not utilized.

In a normal DC-DC converter, the inductance value has to be increased to suppress a ripple current to a predetermined value or lower (e.g., to about 30% of the load current). In contrast, the DC-DC converter shown in FIG. 38A can suppress the ripple current as shown in FIG. 38D, so that the inductance value can be set to a lower value. As a result, the inductors 2a and 2b can be further reduced in size.

### Configuration Example (3)

### <Inductor Configuration>

A circuit board according to Configuration Example (3) includes, for example, multiple conductor containing sections, multiple first electrodes, and multiple second electrodes. Accordingly, two inductors are formed. In each conductor containing section, electric currents flow in the same direction in the Z direction through two conductors disposed within one through-hole.

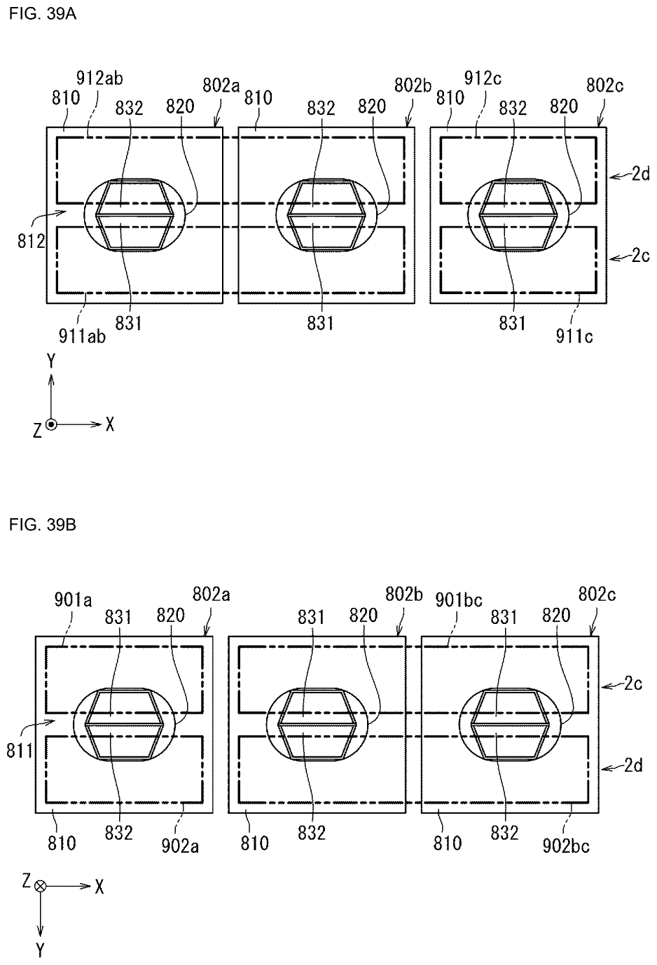

FIG. 39A is a top see-through view schematically illustrating the conductor containing sections and the second electrodes according to Configuration Example (3). FIG. 39B is a bottom see-through view schematically illustrating the conductor containing sections and the first electrodes according to Configuration Example (3). In order to facilitate understanding, the first electrodes and the second electrodes are indicated by double-dot chain lines. The following description mainly focuses on the differences from Configuration Example (2), and redundant descriptions will be omitted, where appropriate.

In the example shown, multiple (in this case, four) first electrodes 901a, 901bc, 902a, and 902bc are provided at the first surface 811 side of the conductor containing sections 802a to 802c. Multiple (in this case, four) second electrodes 911ab, 911c, 912ab, and 912c are provided at the second surface 812 side of the conductor containing sections 802a to 802c.

In this configuration example, the conductors 831 in the conductor containing sections 802a to 802c are connected in series to form a single inductor 2c. Moreover, the conductors 832 in the conductor containing sections 802a to 802c are connected in series to form a single inductor 2d.

The inductor 2c includes the conductors 831 in the conductor containing sections 802a to 802c, the first electrodes 901a and 901bc, and the second electrodes 911ab and 911c. The first end portion of the conductor 831 in the conductor containing section 802a is electrically connected to a predetermined terminal via the first electrode 901a. The second end portions of the conductors 831 in the conductor containing sections 802a and 802b are electrically connected to each other by the second electrode 911ab. The first end portions of the conductors 831 in the conductor containing sections 802b and 802c are electrically connected to each other by the first electrode 901bc. The second end portion of the conductor 831 in the conductor containing section 802c is electrically connected to a predetermined terminal via the second electrode 911c. The inductor 2d has a structure similar to that of the inductor 2b according to Configuration Example (2).

In the circuit board according to Configuration Example (3), the conductors 831 and 832 are electrically isolated from each other, so that the conductors 831 and 832 can respectively form different components (in this case, the inductors 2c and 2d).

In the circuit board according to Configuration Example (3), the conductors 831 and 832 are connected to corresponding electrodes such that the directions of electric currents are parallel. With such a configuration, the directions (orientations) of magnetic fields generated by the conductors 831 and 832 are the same, so that the magnetic fields can reinforce each other. Consequently, the characteristics of the inductors formed of the conductors 831 and 832 can be enhanced.

### <Circuit Configuration>

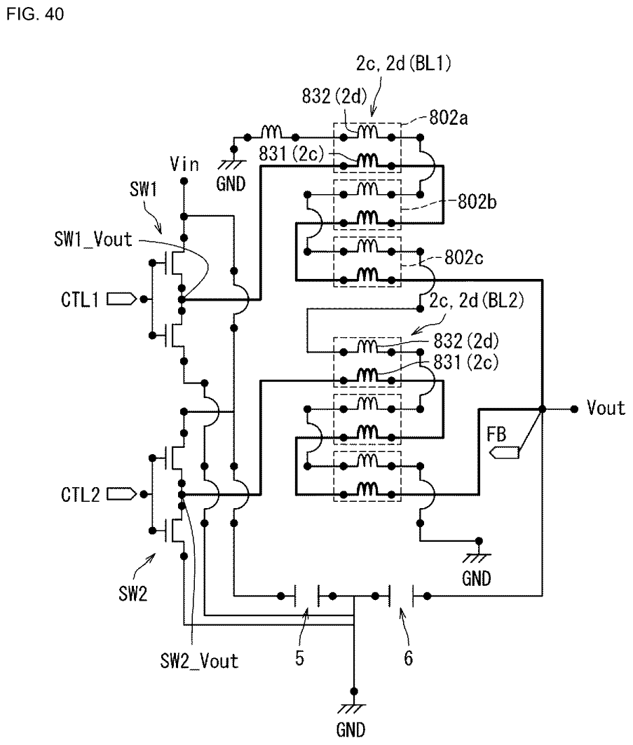

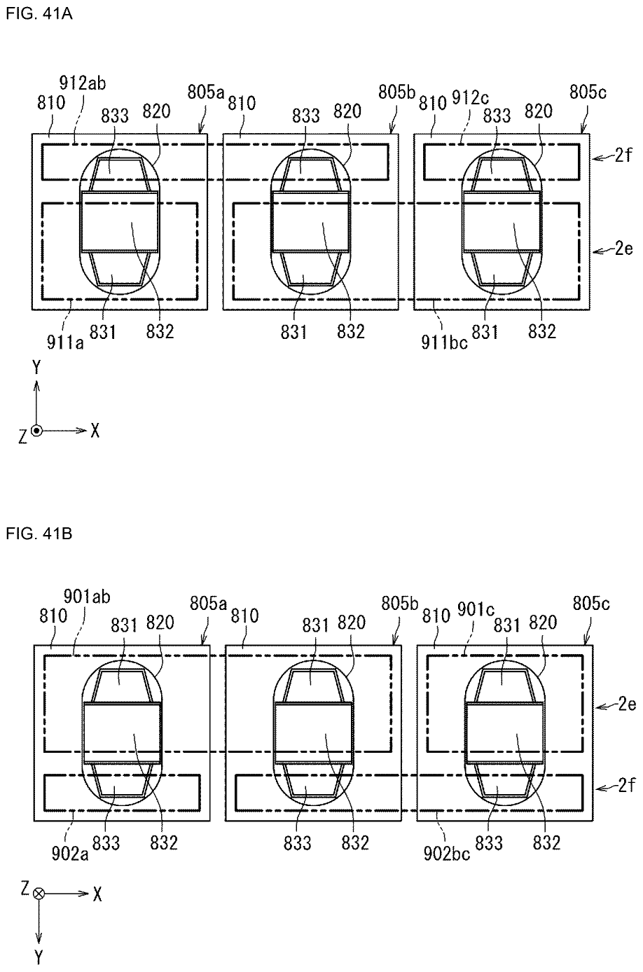

FIG. 40 illustrates an example of a circuit configuration of a voltage regulation module (step-down DC-DC converter) using the circuit board according to Configuration Example (3). The DC-DC converter shown in FIG. 40 is a multiphase DC-DC converter including the two switch elements SW1 and SW2.

In this example, the circuit board has embedded therein two sets of inductors 2c and 2d (referred to as “inductor block BL1” and “inductor block BL2” hereinafter). The inductor 2c in the inductor block BL1 is connected between the SW1_Vout terminal of the switch element SW1 and the output terminal Vout. The inductor 2c in the inductor block BL2 is connected between the SW2_Vout terminal of the switch element SW2 and the output terminal Vout. The inductors 2d in the inductor blocks BL1 and BL2 are connected in series between the ground terminals GND.

The inductors 2c and 2d in each of the inductor blocks BL1 and BL2 has the structure shown in FIG. 39A and FIG. 3B. In each of the conductor containing sections 802a to 802c, electric currents flow in the same direction (parallel) through the conductor 831 constituting the inductor 2c and the conductor 832 constituting the inductor 2d.

In the DC-DC converter shown in FIG. 40, a configuration called a trans-inductor-voltage regulator (TLVR) is embedded in the circuit board, so that the load transient response characteristics can be improved. When the two conductors 831 and 832 in each of the conductor containing sections 802a to 802c are disposed close to each other, the conductors 831 and 832 are magnetically coupled to each other more securely, so that the load transient response characteristics can be further enhanced.

The above-described technical effects will be described in further detail. In a multiphase power source in the related art, an increase or decrease in the load current of an inductor is detected based on a change in FB voltage at an FB terminal. A control IC is configured to correct an excess or deficiency due to an increase or decrease in electric current by controlling a duty ratio (i.e., a ratio between ON time and OFF time) of a signal applied to control terminals CTL1 and CTL. In other words, feedback control is performed via the control IC.

In contrast, in the circuit shown in FIG. 40, in the phase 1 in which one of the switch elements (e.g., the switch element SW1) is turned on, an increase or decrease in the load current of the inductor 2c connected to the switch element SW1 (i.e., the inductor 2c in the inductor block BL1) is detected by the inductor 2d. Thus, an electric current equivalent to an amount that has increased or decreased from the inductor 2c in the inductor block BL2 is supplied via magnetic coupling. Accordingly, an excess or deficiency of the electric current can be corrected. By causing the inductors 2c in the inductor blocks BL1 and BL2 to operate in conjunction with each other in this manner, a fast transient voltage response can be achieved. With this circuit configuration, an excess or deficiency due to an increase or decrease in electric current can be corrected (fed back) prior to the feedback control performed via the control IC, thereby enabling faster operation.

### Configuration Example (5)

### <Inductor Configuration>

A circuit board according to Configuration Example (5) includes, for example, multiple conductor containing sections, multiple first electrodes, and multiple second electrodes. Accordingly, two inductors are formed. In each conductor containing section, three conductors are disposed within each through-hole. Electric currents flow through two of the conductors and the remaining one conductor in opposite directions (antiparallel) in the Z direction.

FIG. 41A is a top see-through view schematically illustrating the conductor containing sections and the second electrodes according to Configuration Example (5). FIG. 41B is a bottom see-through view schematically illustrating the conductor containing sections and the first electrodes according to Configuration Example (5). In order to facilitate understanding, the first electrodes and the second electrodes are indicated by double-dot chain lines. The following description mainly focuses on the differences from Configuration Example (2), and redundant descriptions will be omitted, where appropriate.

In FIG. 41A and FIG. 41B, the circuit board has multiple (in this case, three) conductor containing sections 805a to 805c arranged in this order in the X direction. In each of the conductor containing sections 802a to 802c, the conductor 832 is located between the conductors 831 and 833 in the Y direction.

In this example, each of the conductor containing sections 805a to 805c has a configuration similar to that of the conductor containing section 805 shown in FIG. 36A and FIG. 36B. The configuration of each of these conductor containing sections is not limited to the example shown, and, for example, may be that of the conductor containing section 804 shown in FIG. 35A and FIG. 35B.

This example is similar to Configuration Example (2) in that the circuit board is provided with the first electrodes 901ab, 901c, 902a, and 902bc and the second electrodes 911a, 911bc, 912ab, and 912c. The conductors 831 and 832 in each conductor containing section are connected to the same electrode, and are connected so as to have the same potential. The conductor 833 in each conductor containing section is connected to an electrode different from that of the other conductors 831 and 832, and is connected so as to have a different potential.

In this configuration example, the conductors 831 and 832 in the conductor containing sections 802a to 802c are connected in series to form a single inductor 2e. The conductors 833 in the conductor containing sections 802a to 802c are connected in series to form a single inductor 2f.

In the inductor 2e, the first electrodes 901ab and 901c and the second electrodes 911a and 911bc are disposed to electrically connect the conductors 831 and 832 in the respective conductor containing sections, and to connect conductor sections formed of the conductors 831 and 832 in the conductor containing sections 802a to 802c in series, similarly to the first inductor 2a according to Configuration Example (2). The inductor 2f is similar to the inductor 2b according to Configuration Example (2) in that the first electrodes 902a and 902bc and the second electrodes 912ab and 912c are disposed to connect the conductors 833 in the conductor containing sections 802a to 802c in series.

In the circuit board according to Configuration Example (5), the conductors 831 and 833 are disposed close to the conductor 832 within each through-hole 820, and are connected to corresponding electrodes such that the directions of electric currents are antiparallel. Accordingly, the direction of magnetic field occurring due to the conductors 831 and 833 and the direction of magnetic field occurring due to the conductor 832 are opposite to each other. Therefore, magnetic saturation is less likely to occur, so that deterioration in the inductor characteristics due to magnetic saturation can be suppressed.

### Other Configuration Examples

### Configuration Example (1)

The conductors 831 and 832 are electrically isolated from each other in Configuration Examples (2) and (3), but may be electrically connected to each other. For example, the first end portions of the conductors 831 and 832 may be electrically connected by a first electrode, and the second end portions may be electrically connected by a second electrode (Configuration Example (1)). In Configuration Example (1), the potentials of these conductors and the directions of electric currents are the same.

### Configuration Example (4)

Although the conductors 831 to 833 in each conductor containing section are electrically isolated into two parts in Configuration Example (5), these three conductors do not have to be electrically isolated. For example, the first end portions of the three conductors may be electrically connected by a first electrode, and the second end portions may be electrically connected by a second electrode (Configuration Example (4)). In Configuration Example (4), the potentials of these conductors and the directions of electric currents are the same.

### Configuration Example (6)

In Configuration Example (5), the conductors 831 to 833 in each conductor containing section are electrically isolated into two parts, and the two directions of electric currents (i.e., the direction of an electric current flowing through the conductors 831 and 832 and the direction of an electric current flowing through the conductor 833) are antiparallel. Alternatively, these directions of electric currents may be parallel (Configuration Example (6)).

### Configuration Examples (7) and (8)

In Configuration Example (5), of the conductors 831 to 833 in each conductor containing section, the conductors 831 and 832 have the same potential V1, and the conductor 833 has a potential V2 different therefrom. Alternatively, the conductors 831 and 833 may have the same potential V1, and the conductor 832 in the middle may have the different potential V2. In this case, the direction of an electric current in the conductors 831 and 833 and the direction of an electric current in the conductor 832 may be antiparallel (Configuration Example (7)), or may be parallel (Configuration Example (8)).

### Configuration Examples (9) to (11)

The conductors 831 and 833 in each conductor containing section may be electrically isolated from one another (i.e., into three parts). In this case, the directions of electric currents in the conductors 831 and 833 may all be identical (parallel) (Configuration Example (9)). Alternatively, the electric current may flow in the same direction through the conductors 831 and 832, and the electric current may flow through the conductor 833 in the opposite direction (antiparallel) to the conductors 831 and 832 (Configuration Example (10)). As a further alternative, the electric current may flow in the same direction through the conductors 831 and 833 at the opposite ends, and the electric current may flow through the middle conductor 832 in the opposite direction (antiparallel) to the conductors 831 and 832 (Configuration Example (11)). In Configuration Examples (10) and (11), the directions of magnetic fields occurring due to two conductors of the three electrically independent conductors 831 to 833 are the same, whereas the direction of a magnetic field occurring due to the remaining one conductor is opposite to the above (mixture of same and reverse directions).

The configuration of the circuit board according to this exemplary embodiment is not limited to the configuration described above. The number of conductors in Table 1 is two or three, but may be four or more. Furthermore, although FIG. 37A to FIG. 41B each illustrate an example where three conductor containing sections are provided, the circuit board according to this exemplary embodiment is not particularly limited in terms of the number of conductor containing sections, so long as it includes at least one conductor containing section. Moreover, the circuit board according to this exemplary embodiment may have a mixture of conductor containing sections having different configurations (e.g., different numbers of conductors or different shapes).

The positions, shapes, cross-sectional areas, electrode positions, shapes, and so on of the conductors 831 and 833 are not limited to the examples shown, and may be appropriately set in accordance with the design of the circuit board. The conductors 831 and 833 each have a quadrilateral prismatic shape in FIG. 30 to FIG. 41B, but may have another polygonal prismatic shape. Moreover, each conductor may have a columnar shape other than a polygonal prismatic shape, such as a cylindrical shape, a semi-cylindrical shape, an elliptic cylindrical shape, or a semi-elliptic cylindrical shape. For example, the conductors 831 and 832 have the same cross-sectional area in the examples shown in FIG. 30 to FIG. 33B, but may have cross-sectional areas different from each other. The conductors 831 and 833 have the same cross-sectional area and the same shape in the examples shown in FIG. 35A to FIG. 36B, but may have cross-sectional areas and shapes different from each other. In plan view, the conductors 831 and 832 are disposed symmetrically with the conductor 832 interposed therebetween, but may be asymmetrical to each other.

The configuration of the DC-DC converter using the circuit board according to this exemplary embodiment is also not limited to the configurations shown in FIG. 38A and FIG. 40. The circuit board according to Configuration Example (2) used in FIG. 38A may be replaced by another configuration in which the directions of electric currents in two conductors within each through-hole are parallel. The circuit board according to Configuration Example (3) used in FIG. 40 may be replaced by another configuration in which the directions of electric currents in two conductors within each through-hole are antiparallel. The circuit configuration, the number of switch elements, and so on are also not limited to the examples shown. Moreover, the DC-DC converter shown in FIG. 6 may be formed by using the circuit board according to Configuration Example (1) or (4).

Furthermore, although the above description relates to conductor containing sections constituting inductors as an example, the conductor containing sections may form components other than inductors.

### [Method for Manufacturing Conductor Containing Section]

A method for manufacturing a conductor containing section according to this exemplary embodiment will now be described. The following description relates to an example of manufacturing the first structural body M having the conductor 831 having a rectangular cross-sectional shape and the conductor 832 having a trapezoidal cross-sectional shape, similar to the conductor containing section 803 shown in FIG. 34A and FIG. 34B.

### (Manufacturing of First Structural Body M)

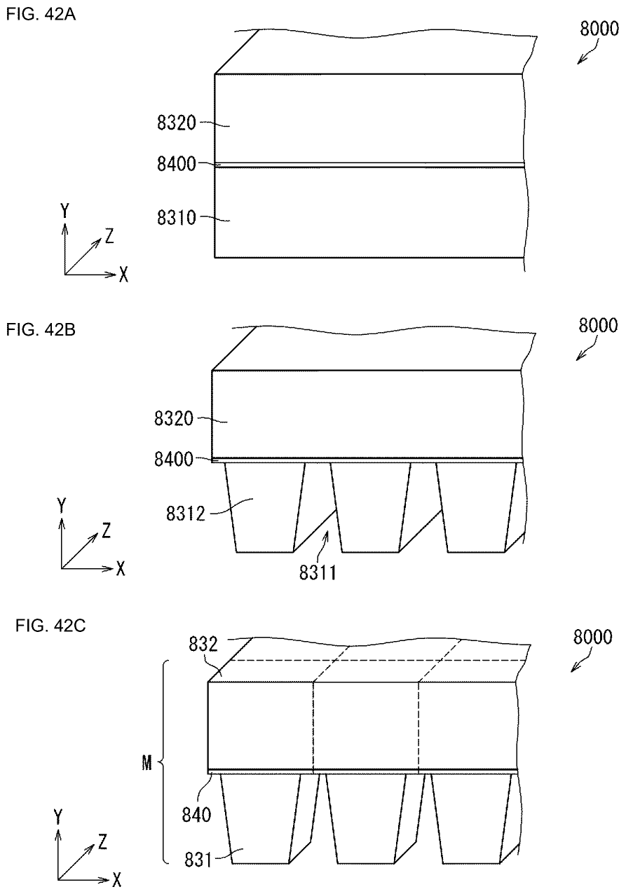

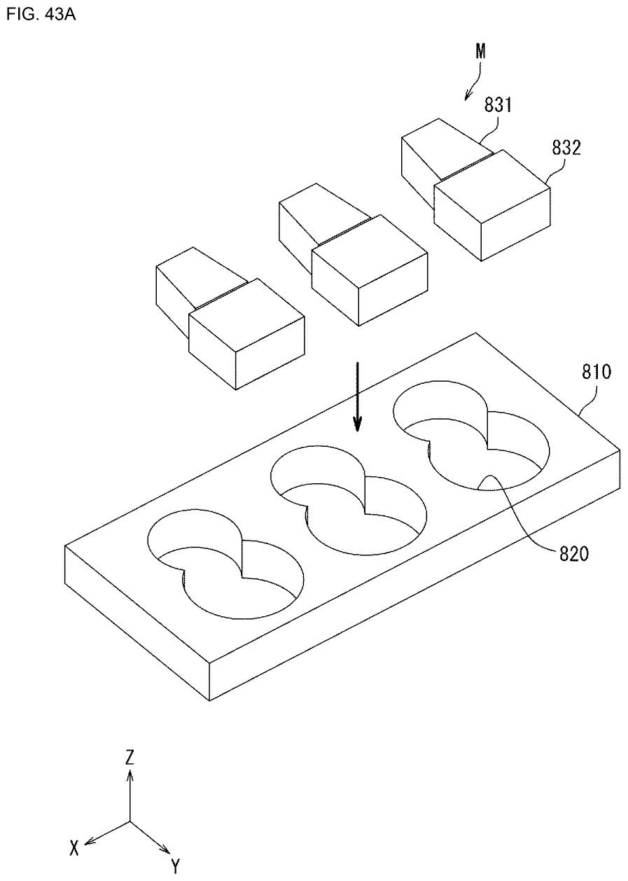

FIG. 42A to FIG. 42E are schematic process perspective views illustrating a method for manufacturing the first structural body M. First, as shown in FIG. 42A, a first metal foil (e.g., copper foil) 8310 that is to become the conductor 831 and a second metal foil (e.g., copper foil) 8320 that is to become the conductor 832 are laminated via an adhesive layer (e.g., an adhesive sheet) 8400 that is to become the isolation insulation layer 840, thereby forming a multilayer body 8000. Subsequently, as shown in FIG. 42B, processing (etching) is performed on the first metal foil 8310 and/or the second metal foil 8320. In this case, multiple grooves 8311 extending in one direction (Z direction in this drawing) are formed in the first metal foil 8310, thereby dividing the first metal foil 8310 into multiple portions 8312. Each portion 8312 has a quadrilateral prismatic shape with a trapezoidal cross-sectional shape. Although not shown, an insulation film that is to become the insulation layer 850 may be formed on each of the upper surface and the lower surface of the processed multilayer body 8000. Subsequently, as shown in FIG. 42C, the multilayer body 8000 is cut in a direction intersecting (in this case, orthogonal to) the upper surface of the multilayer body 8000. Accordingly, multiple first structural bodies M are obtained.

### (Manufacturing of Conductor Containing Section)

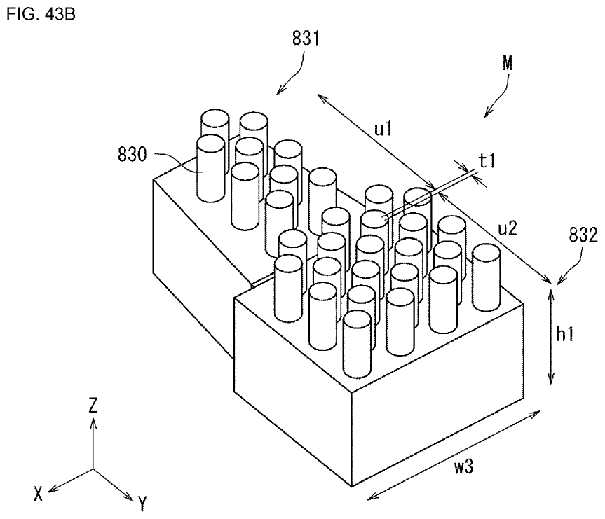

FIG. 43A is a schematic process perspective view illustrating a conductor-containing-section manufacturing method. As shown in FIG. 43A, the substrate (e.g., a magnetic body) 810 having the through-holes 820 is prepared. The width of the substrate 810 in the X direction is, for example, 4.0 mm, and the width in the Y direction is, for example, 3.0 mm. Each through-hole 820 is obtained by, for example, forming a cylindrical through-hole (first hole) with a radius d1 and a cylindrical through-hole (second hole) with a radius d2 by drilling such that the through-holes partially overlap each other. In this example, the substrate 810 has multiple (in this case, three) through-holes 820 that are arranged with a distance (e.g., 0.75 mm) therebetween in the X direction.

Then, the first structural bodies M manufactured based on the above-described method are inserted into the respective through-holes 820 in the substrate 810. Subsequently, the first structural bodies M are sealed. In this case, a resin member that is to become the insulation section 860 is formed in a gap between each first structural body M and the corresponding through-hole 820, and seal insulation layers that cover the lower surface and the upper surface of each conductor are formed. Then, via holes are formed in the seal insulation layers, and via conductors are formed within the via holes.

FIG. 43B is a perspective view illustrating the first structural body M having the via conductors formed therein. In FIG. 43B, the seal insulation layers are not shown.

As shown in FIG. 43B, multiple via conductors 830 spaced apart from each other are formed at a first end surface and a second end surface of each of the conductors 831 and 832. The first end surface and the second end surface of each of the conductors 831 and 832 are surfaces located at the first surface 811 side and the second surface 812 side (see FIG. 34B), respectively, of the substrate 810. A thickness h1 of the conductors 831 and 832 in the Z direction is determined in accordance with the thickness of the substrate 810, and is, for example, 0.8 mm. A width t1 of the isolation insulation layer 840 is adjusted in accordance with the thickness of the adhesive layer 8400 shown in FIG. 42A, and is, for example, 0.015 mm.

Subsequently, where necessary, electrodes (corresponding to the electrodes 31 and 32 according to the above-described exemplary embodiments) may be formed on the via conductors. Each conductor may be provided with an electrode. Each conductor containing section is manufactured in this manner.

The substrate 810 having three conductor containing sections formed therein may be disposed in an opening of the core substrate 10 (see FIG. 3A). Alternatively, the substrate 810 may be disposed in the opening of the core substrate after being divided into parts for the respective conductor containing sections. A component-embedded substrate is obtained in this manner. Subsequently, similar to the exemplary embodiments described above, wiring structures are formed at opposite surfaces of the component-embedded substrate, so that a circuit board may be manufactured.

### (Designing Method)

FIG. 44A and FIG. 44B are diagrams for explaining an example of a method for designing the first structural body M, and are schematic top views of the first structural body M.

The lengths of the conductors 831 and 832 in the X direction and the Y direction are designed such that magnetic fields of the conductors 831 and 832 are readily generated, and that the cross-sectional areas are large. The following description with reference to FIG. 44A relates to the relationship between the lengths of the conductors 831 and 832 in the X direction and the Y direction and the opening shape of the through-hole 820.

In the example shown in FIG. 44A, the through-hole 820 has a structure in which the first cylindrical hole with the radius d1 and the second cylindrical hole with the radius d2 are disposed to partially overlap. The first region Pc1 defined by the inner wall of the first hole and the second region Pc2 defined by the inner wall of the second hole communicate with each other. In plan view, for example, the radii d1 and d2 and a distance d3 between the center of the first hole and the center of the second hole are set to satisfy the following relationship:

$${( d 3 )}^{2} \leq {( d 1 )}^{2} + {( d 2 )}^{2}$$

Accordingly, in plan view, an angle α formed between a tangential line of the inner wall of the first hole and a tangential line of the inner wall of the second hole is not an acute angle at a point where the inner wall of the first hole and the inner wall of the second hole intersect, so that the magnetic resistance can be reduced, whereby magnetic coupling between the conductors 831 and 832 can be enhanced. In this example, the radius d2 is larger than the radius d1 (d2>d1). The radius d1 is, for example, 0.5 mm, and the radius d2 is, for example, 0.65 mm.

In plan view, the conductor 832 has a polygonal shape that is slightly smaller than a polygon inscribing the second region Pc2 that is partially-circular. The polygon is, for example, an n-gon (where n is four or larger). Accordingly, the conductor 832 can be disposed inside the second region Pc2 of the through-hole 820.

In FIG. 44A, the conductor 832 is, for example, rectangular in plan view. The length u2 of the conductor 832 in the Y direction is adjusted in accordance with the thickness of the second metal foil 8320 (FIG. 42A), and is, for example, 0.8 mm. The width w3 of the conductor 832 in the X direction is adjusted by etching, and is, for example, 1.0 mm.

In plan view, the conductor 831 has a polygonal shape having two apexes located close to the −Y edge (i.e., the edge closest to the first region Pc1) of the conductor 832. The polygon is, for example, n-gon (where n is four or larger). Of the apexes of the polygon of the conductor 831 in plan view, the apexes located farthest from the conductor 832 may be located slightly within points on the circular arc of the first region Pc1 that is partially-circular. Accordingly, the cross-sectional area of the conductor 831 can be increased, while the conductor 832 is disposed inside the second region Pc2.

In FIG. 44A, the conductor 831 has a trapezoidal shape with the lower base at the conductor 832 side in plan view, and two apexes at opposite sides of the lower base of the trapezoid are located slightly within the points on the circular arc of the first region Pc1 that is partially-circular. The length u1 of the conductor 831 in the Y direction is adjusted in accordance with the thickness of the first metal foil 8310 (FIG. 42A), and is, for example, 0.8 mm. The widths w1 and w2 of the conductor 831 in the X direction may be adjusted by etching. The width w1 (i.e., the length of the lower base of the trapezoid) is, for example, 0.7 mm. The width w2 (i.e., the length of the upper base of the trapezoid) is, for example, 0.5 mm. Base angles at opposite ends of the lower base of the trapezoid may be adjusted to desired angles (acute angles) in accordance with an etching method and an etching condition. The lengths u1 and u2 are equal to each other in this example but may be different from each other.

The following description with reference to FIG. 44B relates to an example of the size and layout of the via conductors 830. In this case, one end portion of each via conductor 830 is connected to an end surface (i.e., the first end surface or the second end surface) of the corresponding conductor 831 or 832. Each via conductor 830 has a cylindrical shape with a radius d4, and extends in the Z direction away from the end surface of the corresponding conductor 831 or 832. Adjacent via conductors 830 are disposed with at least a distance d5 therebetween. As an example, in plan view, the positions and the number of via conductors 830 may be determined by arranging concentric circles, each including a circle with the radius d4 and an imaginary circle 830i with a radius d4+d5, on the end surface of each of the conductors 831 and 832. Accordingly, multiple via conductors 830 can be disposed more densely at the first end surface of each of the conductors 831 and 832 while ensuring a predetermined distance (i.e., the distance d5). The radius d4 of each cylindrical via conductor 830 is, for example, 0.0575 mm. The distance d5 is, for example, 0.05 mm.

In the above-described method, the first structural body M including the multiple conductors 831 and 832 isolated by the isolation insulation layer 840 is disposed in each through-hole 820 of the substrate 810. By disposing the separately-manufactured first structural body M in each through-hole of the substrate 810, the multiple conductors 831 and 832 can be disposed more readily with a predetermined distance therebetween in the through-hole 820. Moreover, the distance between the conductors 831 and 832, the positional relationship between the conductors 831 and 832, and the like can be readily controlled.

In the above-described method, the through-hole 820 and the first structural body M may have a planar shape that is long in one direction or may have an asymmetrical shape. Accordingly, the multiple conductors 831 and 832 can be disposed more readily in a predetermined orientation in the through-hole 820. This is advantageous in that the structure and steps for positioning are not necessary.

The method for manufacturing the circuit board according to this exemplary embodiment is not limited to the above-described method. For example, multiple columnar conductors (e.g., cylindrical Cu pins) each with its peripheral surface covered by an insulation layer may be prepared, and these conductors may be disposed in each through-hole of the substrate. Subsequently, a region of the through-hole where the multiple conductors are not disposed may be filled with resin or the like.

### Fourth Exemplary Embodiment

A fourth exemplary embodiment relates to a voltage regulation module equipped with an inductor-embedded circuit board. The following description relates to an example where the circuit board 1 shown in FIG. 1 and FIG. 2 is used as the inductor-embedded circuit board.

FIG. 45 is a schematic cross-sectional view illustrating an example of a voltage regulation module 400 according to the fourth exemplary embodiment. The voltage regulation module 400 is, for example, a step-down converter having the circuit configuration described above with reference to FIG. 6.

The voltage regulation module 400 is disposed on, for example, a principal surface 500s of a system board (motherboard) 500. A power management IC (PMIC) may further be disposed on the principal surface 500s. Although not shown, an arithmetic processing device may be disposed at the opposite principal surface of the system board 500.

The voltage regulation module 400 includes the circuit board 1 having an inductor embedded therein, and the switch element SW.

The circuit board 1 is the same as the circuit board 1 according to any of the above-described exemplary embodiments. The circuit board 1 has embedded therein the inductor 2 and a two-terminal capacitor (such as an input capacitor and an output capacitor). In the circuit board 1, the first principal surface s1 where terminal portions, such as the input terminal Vin and the output terminal Vout, are disposed is disposed to face the principal surface 500s of the system board 500.

The switch element SW is disposed on the second principal surface s2 of the circuit board 1. The switch element SW includes high side and low side MOSFETs and multiple terminals (see FIG. 6). Each terminal of the switch element SW is connected to a corresponding land at the second principal surface s2 of the circuit board 1.

In the voltage regulation module 400 according to this exemplary embodiment, components, such as the inductor 2 and the two-terminal capacitor, are disposed in parallel within the circuit board 1. Moreover, the inductor 2 is divided into multiple parts that are embedded within the circuit board 1. Therefore, the voltage regulation module 400 can be reduced in thickness.

In the voltage regulation module 400 according to this exemplary embodiment, an output end p1 of the inductor 2 is located at the first principal surface s1 side. Thus, a path between the output end p1 of the inductor 2 and the output terminal Vout can be shortened. Moreover, since the input end p2 of the inductor 2 is located at the second principal surface s2 side, a path between the input end p2 of the inductor 2 and the switch output terminal SW_Vout of the switch element SW can be shortened. Thus, the electrical resistance from the switch output terminal SW_Vout of the switch element SW to the output terminal Vout can be further reduced. Accordingly, a more efficient voltage regulation module 400 can be provided.

The configuration, layout, and so on of the voltage regulation module according to this exemplary embodiment are not limited to those in the example shown in FIG. 45. The circuit board used may be any of the circuit boards exemplified in the first exemplary embodiment to the third exemplary embodiment. The voltage regulation module according to this exemplary embodiment may be configured such that the inductor embedded in the circuit board according to this exemplary embodiment is connected between the output terminal of the switch element and the output terminal of the module. Furthermore, although the inductor-embedded circuit board is applied to a step-down converter in this exemplary embodiment, the inductor-embedded circuit board may be applied to another regulator, such as a step-up or step-up/step-down converter.

The present disclosure is not limited to the above-described exemplary embodiments, and design modifications are possible so long as they do not depart from the scope of the present disclosure. Furthermore, by appropriately combining components in any embodiment from the various exemplified embodiments (including modifications), technical effects that the respective embodiments have can be exhibited.

### REFERENCE SIGNS LIST

1 circuit board (inductor-embedded circuit board)
2, 2a to 2f inductor
3, 3a to 3c conductor
4, 4a to 4c magnetic body
4L magnetic body layer
5 input capacitor
6 output capacitor
7, 71 to 73 core through conductor
8 seal member
10 substrate (core substrate)
11 first surface
12 second surface
13a to 13c, 14 to 16 through-hole (core through-hole)
20, 20a to 20c inductor unit cell
21 first cell insulation section
22 second cell insulation section
23 insulation section
24, 25 seal insulation layer
31, 31a to 31c, 31ab first electrode
32, 32a to 32c, 32bc second electrode
41 magnetic-body through-hole
51, 61 lower electrode
52, 62 upper electrode
53 dielectric body
81 lower insulation layer
82 upper insulation layer
83 insulation section
91 first insulation section
92 second insulation section
100 first wiring structure
101 to 103, 201 to 203 insulation layer
105, 205 solder-resist layer
110, 120, 130, 210, 220, 230 wiring layer
111 first connection electrode
112 first inductor connection electrode
113 first input capacitor connection electrode
200 second wiring structure
211 second inductor connection electrode
212 second connection electrode
213 second input capacitor connection electrode
214 output capacitor connection electrode
300, 300a component-embedded substrate
400 voltage regulation module
410, 420 MOSFET
500 system board
800 to 805, 802a to 802c, 805a to 805c conductor containing section
811 first surface
812 second surface
810 substrate
820 through-hole
830 via conductor
831 to 833 conductor
831a, 832a, 833a first side surface
831b, 832b second side surface
840 isolation insulation layer
841 first isolation insulation layer
842 second isolation insulation layer
850 insulation layer
860 insulation section
901a, 901ab, 901bc, 901c, 902a, 902bc first electrode
911a, 911ab, 911bc, 911c, 912ab, 912c second electrode
M first structural body
CTL control terminal
e1 first end surface
e2 second end surface
r1 inductor placement region
r2 capacitor placement region
r3 core-through-conductor placement region
SW, SW1, SW2 switch element

1. An inductor-embedded circuit board comprising:
a substrate having a first surface and a second surface that is opposite the first surface in a thickness direction of the substrate;
a first wiring layer on the first surface of the substrate with a first insulation section between the first wiring layer and the first surface of the substrate;
a second wiring layer on the second surface of the substrate with a second insulation section between the second wiring layer and the second surface; and
an inductor that is embedded inside the substrate,
wherein the inductor includes:
at least a first conductor, a second conductor, and a third conductor within the substrate, the first conductor, the second conductor, and the third conductor being spaced apart from one another in a plan view in the thickness direction,
a first magnetic body surrounding a peripheral surface of the first conductor,
a second magnetic body surrounding a peripheral surface of the second conductor, and
a third magnetic body surrounding a peripheral surface of the third conductor,
wherein a first end portion of the first conductor, a first end portion of the second conductor, and a first end portion of the third conductor are within the substrate and towards the first surface, a second end portion of the first conductor, a second end portion of the second conductor, and a second end portion of the third conductor are within the substrate and towards the second surface,
wherein the first wiring layer includes a first connection electrode configured to electrically connect the first end portion of the first conductor to the first end portion of the second conductor,
wherein the second wiring layer includes a second connection electrode configured to electrically connect the second end portion of the second conductor to the second portion of the third conductor,
wherein the first end portion of the first conductor and the first end portion of the second conductor are electrically connected to the first connection electrode by one or more first via conductors within the first insulation section, and
wherein the second end portion of the second conductor and the second end portion of the third conductor are electrically connected to the second connection electrode by one or more second via conductors within the second insulation section.

2. The inductor-embedded circuit board according to claim 1,
wherein the first conductor, the second conductor, and the third conductor are connected in series,
wherein a first end of the inductor is connected to a first wire within the first wiring layer by the one or more first via conductors within the first insulation section, and
wherein a second end of the inductor is connected to a second wire within the second wiring layer by the one or more second via conductors within the second insulation section.

3. The inductor-embedded circuit board according to claim 1,
wherein the substrate includes a first electrode of the inductor that is electrically connected to the first end portion of the first conductor, and
wherein the first electrode overlaps an entirety of the first conductor and at least a part of the first magnetic body in the plan view.

4. The inductor-embedded circuit board according to claim 3,
wherein the first electrode of the first conductor is electrically connected to the first connection electrode by a plurality of via conductors within the first insulation section, and
wherein at least one of the plurality of via conductors is outside the first conductor in the plan view.

5. The inductor-embedded circuit board according to claim 1, further comprising:
at least one two-terminal capacitor that is embedded inside the substrate,
wherein the at least one two-terminal capacitor and the inductor are disposed with the substrate in parallel.

6. The inductor-embedded circuit board according to claim 5, wherein the at least one two-terminal capacitor includes:
a dielectric body,
a first electrode towards a first surface of the dielectric body, and
a second electrode towards a second surface of the dielectric body,
wherein the first electrode is electrically connected to a wire within the first wiring layer by the one or more first via conductors in the first insulation section, and
wherein the second electrode is electrically connected to a wire within the second wiring layer by the one or more second via conductors in the second insulation section.

7. The inductor-embedded circuit board according to claim 1, wherein the first magnetic body, the second magnetic body, and the third magnetic body are integrally formed with each other.

8. The inductor-embedded circuit board according to claim 7, wherein the inductor includes, inside the substrate:
a first electrode electrically connected to the first end portion of the first conductor,
a second electrode electrically connected to the first end portion of the second conductor,
a third electrode electrically connected to the second end portion of the second conductor, and
a fourth electrode electrically connected to the second end portion of the third conductor,
wherein the first electrode and the second electrode are integrally formed with each other, and
wherein the third electrode and the fourth electrode are integrally formed with each other.

9. A voltage regulation module comprising:
a circuit board with an inductor that is embedded in the circuit board;
an input terminal and an output terminal; and
a switch element connected between the input terminal and the inductor,
wherein the circuit board comprises:
a substrate having a first surface and a second surface that is opposite the first surface in a thickness direction of the substrate;
a first wiring layer on the first surface of the substrate with a first insulation section between the first wiring layer and the first surface of the substrate;
a second wiring layer on the second surface of the substrate with a second insulation section between the second wiring layer and the second surface; and
the inductor that is embedded inside the substrate,
wherein the inductor includes:
at least a first conductor, a second conductor, and a third conductor within the substrate, the first conductor, the second conductor, and the third conductor being spaced apart from one another in a plan view that is viewed in the thickness direction and each extending in the thickness direction,
a first magnetic body surrounding a peripheral surface of the first conductor,
a second magnetic body surrounding a peripheral surface of the second conductor, and
a third magnetic body surrounding a peripheral surface of the third conductor,
wherein a first end portion of the first conductor, a first end portion of the second conductor, and a first end portion of the third conductor are within the substrate and towards the first surface,
wherein a second end portion of the first conductor, a second end portion of the second conductor, and a second end portion of the third conductor are within the substrate and towards the second surface,
wherein the first wiring layer includes a first connection electrode configured to electrically connect the first end portion of the first conductor to the first end portion of the second conductor,
wherein the second wiring layer includes a second connection electrode configured to electrically connect the second end portion of the second conductor to second portion of the third conductor,
wherein the first end portion of the first conductor and the first end portion of the second conductor are electrically connected to the first connection electrode by one or more first via conductors within the first insulation section, and
wherein the second end portion of the second conductor and the second end portion of the third conductor are electrically connected to the second connection electrode by one or more second via conductors within the second insulation section.

10. The voltage regulation module according to claim 9, wherein the circuit board includes:
a first principal surface that is toward the first surface of the substrate, and
a second principal surface that is toward the second surface of the substrate and where the input terminal and the output terminal are disposed, and
wherein the switch element is disposed on the first principal surface.

11. An inductor-embedded circuit board, comprising:
a substrate having a first surface and a second surface that is opposite the first surface in a thickness direction of the substrate;
a first wiring layer on the first surface of the substrate with a first insulation section between the first wiring layer and the first surface of the substrate;
a second wiring layer on the second surface of the substrate with a second insulation section between the second wiring layer and the second surface; and
an inductor that is embedded inside the substrate,
wherein the inductor includes:
a plurality of conductors that are embedded within the substrate, the plurality of conductors being spaced apart from one another in a plan view that is viewed in the thickness direction, and
a plurality of magnetic bodies respectively surrounding peripheral surfaces of the plurality of conductors,
wherein the plurality of conductors are electronically connected in series by one or more first via conductors in the first insulation section, one or more second via connectors in the second insulation section, one or more first wires in the first wiring layer, and one or more second wires in the second wiring layer.

12. The inductor-embedded circuit board according to claim 11,
wherein a first end of the inductor is connected to a first wire within the first wiring layer by a first via conductor within the first insulation section, and
wherein a second end of the inductor is connected to a second wire within the second wiring layer by a second via conductors within the second insulation section.

13. The inductor-embedded circuit board according to claim 11,
wherein the substrate includes a first electrode of the inductor that is electrically connected to a first end portion of a first conductor in the inductor, and
wherein the first electrode is configured to overlap an entirety of the first conductor and at least a part of the first magnetic body in the plan view.

14. The inductor-embedded circuit board according to claim 13,
wherein the first electrode of the first conductor is electrically connected to a first connection electrode in the first wiring layer by a plurality of via conductors within the first insulation section, and
wherein at least one of the plurality of via conductors is outside the first conductor in the plan view.

15. The inductor-embedded circuit board according to claim 11, further comprising:
at least one two-terminal capacitor that is embedded inside the substrate,
wherein the at least one two-terminal capacitor and the inductor are disposed with the substrate in parallel.

16. The inductor-embedded circuit board according to claim 15,
wherein the at least one two-terminal capacitor includes:
a dielectric body,
a first electrode toward a first surface of the dielectric body, and
a second electrode toward a second surface of the dielectric body,
wherein the first electrode is electrically connected to a wire within the first wiring layer by one or more first via conductors in the first insulation section, and
wherein the second electrode is electrically connected to a wire within the second wiring layer by one or more second via conductors in the second insulation section.

17. The inductor-embedded circuit board according to claim 11, wherein the plurality of magnetic bodies are integrally formed.

18. The inductor-embedded circuit board according to claim 17, wherein the inductor includes, inside the substrate:
a first electrode electrically connected to a first end portion of a first conductor in the inductor,
a second electrode electrically connected to a first end portion of a second conductor,
a third electrode electrically connected to a second end portion of the second conductor, and
a fourth electrode electrically connected to a second end portion of a third conductor,
wherein the first electrode and the second electrode are integrally formed, and
wherein the third electrode and the fourth electrode are integrally formed.
